(19) United States
(12) Patent Application Publication
(10) Pub. No.: US 2025/0159869 A1
(43) Pub. Date: May 15, 2025

(54) SEMICONDUCTOR DEVICE, MEMORY DEVICE, AND ELECTRONIC DEVICE

(71) Applicant: SEMICONDUCTOR ENERGY LABORATORY CO., LTD., Atsugi-shi, Kanagawa-ken (JP)

(72) Inventors: Hajime KIMURA, Atsusgi, Kanagawa (JP); Shunpei YAMAZAKI, setagaya, Tokyo (JP)

(21) Appl. No.: 18/838,504

(22) PCT Filed: Feb. 10, 2023
(86) PCT No.: PCT/IB2023/051188

§ 371 Date: Aug. 14, 2024

(30) Foreign Application Priority Data
Feb. 25, 2022 (JP) 2022-028096

(51) Int. Cl. H10B 12/00

(52) U.S. Cl. CPC H10B 12/482

(57) ABSTRACT

A semiconductor device with high memory density is used. In the semiconductor device, a first memory layer and a second memory layer are sequentially stacked. Each of the first and second memory layers includes second to sixth insulators, an oxide, and first to fourth conductors. In each of the first and second memory layers, the second insulator and the oxide are sequentially stacked over a first insulator. The first and second conductors are located over the first and second insulators and the oxides in different regions. The third insulator is located over the first and second conductors and the first insulator, and the fourth insulator is located over the third insulator. The fifth insulator is located over the oxide and a side surface of the fourth insulator, and the third conductor is located over the fifth insulator. The sixth insulator is located over the second conductor and the side surface of the fourth insulator, and the fourth conductor is located over the sixth insulator. The fourth conductor of the first memory layer overlaps with the second insulator and the oxide of the second memory layer.

### TECHNICAL FIELD

One embodiment of the present invention relates to a semiconductor device, a memory device, and an electronic device.

Note that one embodiment of the present invention is not limited to the above technical field. The technical field of the invention disclosed in this specification and the like relates to an object, an operation method, or a manufacturing method. Alternatively, one embodiment of the present invention relates to a process, a machine, manufacture, or a composition of matter. Therefore, specific examples of the technical field of one embodiment of the present invention disclosed in this specification include a semiconductor device, a display apparatus, a liquid crystal display apparatus, a light-emitting apparatus, a power storage device, an image capturing device, a memory device, a signal processing device, a sensor, a processor, an electronic device, a system, a driving method thereof, a manufacturing method thereof, and a testing method thereof.

### BACKGROUND ART

In recent years, the amount of data subjected to processing has been increasing, which makes a demand for a memory device having a higher memory capacity. To increase memory capacity per unit area, stacking memory cells as in the case of a 3D NAND memory device or the like is effective (see Patent Document 1 to Patent Document 3). Stacking memory cells can increase memory capacity per unit area in accordance with the number of stacked memory cells.

### REFERENCES

### Patent Documents

[Patent Document 1] United States Patent Application Publication No. 2011/0065270
[Patent Document 2] United States Patent Application Publication No. 2016/0149004
[Patent Document 3] United States Patent Application Publication No. 2013/0069052

### SUMMARY OF THE INVENTION

### Problems to be Solved by the Invention

An object of one embodiment of the present invention is to provide a semiconductor device with high memory capacity. Another object of one embodiment of the present invention is to provide a semiconductor device with high memory density. Another object of one embodiment of the present invention is to provide a novel semiconductor device or the like. Another object of one embodiment of the present invention is to provide a memory device including the above semiconductor device. Another object of one embodiment of the present invention is to provide an electronic device including the memory device. Another object of one embodiment of the present invention is to provide a novel memory device or a novel electronic device.

Note that the objects of one embodiment of the present invention are not limited to the objects listed above. The objects listed above do not preclude the existence of other objects. Note that the other objects are objects that are not described in this section and will be described below. The objects that are not described in this section are derived from the description of the specification, the drawings, and the like and can be extracted as appropriate from the description by those skilled in the art. One embodiment of the present invention achieves at least one of the above objects and the other objects. Note that one embodiment of the present invention does not necessarily achieve all of the objects listed above and the other objects.

### Means for Solving the Problems

(1)

One embodiment of the present invention is a semiconductor device including a first memory layer and a second memory layer. The second memory layer is located over the first memory layer. Each of the first memory layer and the second memory layer includes a first insulator, a second insulator, a third insulator, a fourth insulator, a fifth insulator, a sixth insulator, an oxide, a first conductor, a second conductor, a third conductor, and a fourth conductor. The oxide contains one or two or more selected from indium, zinc, and an element M. Note that the element M is one or more kinds selected from gallium, aluminum, silicon, boron, yttrium, tin, copper, vanadium, beryllium, titanium, iron, nickel, germanium, zirconium, molybdenum, lanthanum, cerium, neodymium, hafnium, tantalum, tungsten, cobalt, and magnesium.

In each of the first memory layer and the second memory layer, the second insulator is located over the first insulator, and the oxide is located over the second insulator. The first conductor is located over the first insulator, the second insulator, and the oxide; and the second conductor is located over the first insulator, the second insulator, and the oxide. The third insulator is located over the first conductor, the second conductor, and the first insulator; and the fourth insulator is located over the third insulator. The fourth insulator includes a first opening reaching the oxide, in a region not overlapping with the first conductor, the second conductor, or the third insulator. The fifth insulator is located over the oxide and a side surface of the fourth insulator in the first opening, and the third conductor is located over the fifth insulator. The fourth insulator includes a second opening reaching the second conductor, in a region not overlapping with the second insulator or the oxide. The sixth insulator is located over the second conductor and the side surface of the fourth insulator in the second opening, and the fourth conductor is located over the sixth insulator.

The fourth conductor of the first memory layer overlaps with the second insulator of the second memory layer and the oxide of the second memory layer.

(2)

Alternatively, one embodiment of the present invention in (1) described above may have a structure in which the fifth insulator and the sixth insulator include the same insulating material, and the third conductor and the fourth conductor include the same conductive material.

(3)

Alternatively, one embodiment of the present invention is a semiconductor device that includes a first memory layer and a second memory layer and has a different structure from (1) described above. The second memory layer is located over the first memory layer. Each of the first memory layer and the second memory layer includes a first insulator, a second insulator, a third insulator, a fourth insulator, a fifth insulator, a sixth insulator, an oxide, a first conductor, a second conductor, a third conductor, and a fourth conductor. The oxide contains one or two or more selected from indium, zinc, and an element M. Note that the element M is one or more kinds selected from gallium, aluminum, silicon, boron, yttrium, tin, copper, vanadium, beryllium, titanium, iron, nickel, germanium, zirconium, molybdenum, lanthanum, cerium, neodymium, hafnium, tantalum, tungsten, cobalt, and magnesium.

In each of the first memory layer and the second memory layer, the second insulator is located over the first insulator, and the oxide is located over the second insulator. The first conductor is located over the oxide, and the second conductor is located over the oxide. The third insulator is located over the first conductor, the second conductor, and the first insulator; and the fourth insulator is located over the third insulator. The fourth insulator includes a first opening reaching the oxide, in a region not overlapping with the first conductor, the second conductor, or the third insulator. The fifth insulator is located over the oxide and a side surface of the fourth insulator in the first opening, and the third conductor is located over the fifth insulator. The fourth insulator includes a second opening reaching the second conductor, in a region overlapping with the second insulator and the oxide. The sixth insulator is located over the second conductor and the side surface of the fourth insulator in the second opening, and the fourth conductor is located over the sixth insulator.

The fourth conductor of the first memory layer overlaps with the second insulator of the second memory layer and the oxide of the second memory layer.

(4)

Alternatively, one embodiment of the present invention in (3) described above may have a structure in which the fifth insulator and the sixth insulator include the same insulating material, and the third conductor and the fourth conductor include the same conductive material.

(5)

Alternatively, one embodiment of the present invention is a memory device including the semiconductor device according to any one of (1) to (4) described above and a driver circuit.

(6)

Alternatively, one embodiment of the present invention is an electronic device including the memory device according to (5) described above and a housing.

### Effect of the Invention

According to one embodiment of the present invention, a semiconductor device with high memory capacity can be provided. According to another embodiment of the present invention, a semiconductor device with high memory density can be provided. According to another embodiment of the present invention, a novel semiconductor device or the like can be provided. According to another embodiment of the present invention, a memory device including the above semiconductor device can be provided. According to another embodiment of the present invention, an electronic device including the memory device can be provided. According to another embodiment of the present invention, a novel memory device or a novel electronic device can be provided.

Note that the effects of one embodiment of the present invention are not limited to the effects listed above. The effects listed above do not preclude the presence of other effects. Note that the other effects are effects that are not described in this section and will be described below. The effects that are not described in this section can be derived from the description of the specification, the drawings, and the like and can be extracted as appropriate from the description by those skilled in the art. Note that one embodiment of the present invention has at least one of the effects listed above and the other effects. Accordingly, depending on the case, one embodiment of the present invention does not have the effects listed above.

### BRIEF DESCRIPTION OF THE DRAWINGS

FIG. 1 is a circuit diagram illustrating a structure example of a semiconductor device.

FIG. 2 is a schematic cross-sectional view illustrating a structure example of a semiconductor device.

FIG. 3 is a schematic perspective view illustrating a structure example of a semiconductor device.

FIG. 4 is a schematic cross-sectional view illustrating a structure example of a semiconductor device.

FIG. 5 is a layout diagram illustrating a structure example of a semiconductor device.

FIG. 6A is a schematic plan view illustrating a structure example of a semiconductor device, and FIG. 6B to FIG. 6D are schematic cross-sectional views illustrating the structure example of the semiconductor device.

FIG. 7A is a schematic plan view illustrating an example of a method for manufacturing a semiconductor device, and FIG. 7B to FIG. 7D are schematic cross-sectional views illustrating the example of the method for manufacturing a semiconductor device.

FIG. 8A is a schematic plan view illustrating an example of a method for manufacturing a semiconductor device, and FIG. 8B to FIG. 8D are schematic cross-sectional views illustrating the example of the method for manufacturing a semiconductor device.

FIG. 9A is a schematic plan view illustrating an example of a method for manufacturing a semiconductor device, and FIG. 9B to FIG. 9D are schematic cross-sectional views illustrating the example of the method for manufacturing a semiconductor device.

FIG. 10A is a schematic plan view illustrating an example of a method for manufacturing a semiconductor device, and FIG. 10B to FIG. 10D are schematic cross-sectional views illustrating the example of the method for manufacturing a semiconductor device.

FIG. 11A is a schematic plan view illustrating an example of a method for manufacturing a semiconductor device, and FIG. 11B to FIG. 11D are schematic cross-sectional views illustrating the example of the method for manufacturing a semiconductor device.

FIG. 12A is a schematic plan view illustrating an example of a method for manufacturing a semiconductor device, and FIG. 12B to FIG. 12D are schematic cross-sectional views illustrating the example of the method for manufacturing a semiconductor device.

FIG. 13A is a schematic plan view illustrating an example of a method for manufacturing a semiconductor device, and FIG. 13B to FIG. 13D are schematic cross-sectional views illustrating the example of the method for manufacturing a semiconductor device.

FIG. 14A is a schematic plan view illustrating an example of a method for manufacturing a semiconductor device, and FIG. 14B to FIG. 14D are schematic cross-sectional views illustrating the example of the method for manufacturing a semiconductor device.

FIG. 15A is a schematic plan view illustrating an example of a method for manufacturing a semiconductor device, and FIG. 15B to FIG. 15D are schematic cross-sectional views illustrating the example of the method for manufacturing a semiconductor device.

FIG. 16A is a schematic plan view illustrating an example of a method for manufacturing a semiconductor device, and FIG. 16B to FIG. 16D are schematic cross-sectional views illustrating the example of the method for manufacturing a semiconductor device.

FIG. 17A is a schematic plan view illustrating an example of a method for manufacturing a semiconductor device, and FIG. 17B to FIG. 17D are schematic cross-sectional views illustrating the example of the method for manufacturing a semiconductor device.

FIG. 18A is a schematic plan view illustrating an example of a method for manufacturing a semiconductor device, and FIG. 18B to FIG. 18D are schematic cross-sectional views illustrating the example of the method for manufacturing a semiconductor device.

FIG. 19A is a schematic plan view illustrating an example of a method for manufacturing a semiconductor device, and FIG. 19B to FIG. 19D are schematic cross-sectional views illustrating the example of the method for manufacturing a semiconductor device.

FIG. 20A is a schematic plan view illustrating an example of a method for manufacturing a semiconductor device, and FIG. 20B to FIG. 20D are schematic cross-sectional views illustrating the example of the method for manufacturing a semiconductor device.

FIG. 21A is a schematic plan view illustrating an example of a method for manufacturing a semiconductor device, and FIG. 21B to FIG. 21D are schematic cross-sectional views illustrating the example of the method for manufacturing a semiconductor device.

FIG. 22 is a schematic cross-sectional view illustrating a structure example of a semiconductor device.

FIG. 23 is a schematic perspective view illustrating a structure example of a semiconductor device.

FIG. 24 is a schematic cross-sectional view illustrating a structure example of a semiconductor device.

FIG. 25A is a schematic plan view illustrating an example of a method for manufacturing a semiconductor device, and FIG. 25B to FIG. 25D are schematic cross-sectional views illustrating the example of the method for manufacturing a semiconductor device.

FIG. 26A is a schematic plan view illustrating an example of a method for manufacturing a semiconductor device, and FIG. 26B to FIG. 26D are schematic cross-sectional views illustrating the example of the method for manufacturing a semiconductor device.

FIG. 27A is a schematic plan view illustrating an example of a method for manufacturing a semiconductor device, and FIG. 27B to FIG. 27D are schematic cross-sectional views illustrating the example of the method for manufacturing a semiconductor device.

FIG. 28A is a schematic plan view illustrating an example of a method for manufacturing a semiconductor device, and FIG. 28B to FIG. 28D are schematic cross-sectional views illustrating the example of the method for manufacturing a semiconductor device.

FIG. 29A is a schematic plan view illustrating an example of a method for manufacturing a semiconductor device, and FIG. 29B to FIG. 29D are schematic cross-sectional views illustrating the example of the method for manufacturing a semiconductor device.

FIG. 30A is a schematic plan view illustrating an example of a method for manufacturing a semiconductor device, and FIG. 30B to FIG. 30D are schematic cross-sectional views illustrating the example of the method for manufacturing a semiconductor device.

FIG. 31A is a schematic plan view illustrating an example of a method for manufacturing a semiconductor device, and FIG. 31B to FIG. 31D are schematic cross-sectional views illustrating the example of the method for manufacturing a semiconductor device.

FIG. 32A is a schematic perspective view illustrating a structure example of a memory device, and FIG. 32B is a block diagram illustrating a structure example of a semiconductor device.

FIG. 33 is a block diagram illustrating a structure example of a memory device.

FIG. 34 is a schematic cross-sectional view illustrating a structure example of a memory device.

FIG. 35A is a schematic perspective view illustrating an example of a semiconductor wafer, FIG. 35B is a schematic perspective view illustrating an example of a chip, and FIG. 35C and FIG. 35D are schematic perspective views illustrating examples of electronic components.

FIG. 36 is a block diagram illustrating a CPU.

FIG. 37A to FIG. 37J are perspective views illustrating examples of electronic devices.

FIG. 38A, FIG. 38B, and FIG. 38D are perspective views illustrating a structure example of an electronic device, and FIG. 38C is a diagram illustrating an example of parts of the electronic device.

FIG. 39A to FIG. 39E are schematic perspective views illustrating examples of electronic devices.

### MODE FOR CARRYING OUT THE INVENTION

In this specification and the like, a semiconductor device refers to a device that utilizes semiconductor characteristics, and means a circuit including a semiconductor element (e.g., a transistor, a diode, and a photodiode), or a device including the circuit. The semiconductor device also means all devices that can function by utilizing semiconductor characteristics. For example, an integrated circuit, a chip including an integrated circuit, and an electronic component including a chip in a package are each an example of the semiconductor device. Moreover, for example, a memory device, a display device, a light-emitting apparatus, a lighting device, an electronic device, and the like themselves are semiconductor devices and include semiconductor devices in some cases.

In the case where there is description “X and Y are connected” in this specification and the like, a case where X and Y are electrically connected, a case where X and Y are functionally connected, and a case where X and Y are directly connected are regarded as being disclosed in this specification and the like. Accordingly, without being limited to a predetermined connection relation, for example, a connection relation shown in drawings or described with texts, a connection relation other than one shown in drawings or described with texts is regarded as being disclosed in the drawings or description with the texts. Each of X and Y denotes an object (e.g., a device, an element, a circuit, a wiring, an electrode, a terminal, a conductive film, or a layer).

For example, in the case where X and Y are electrically connected, one or more elements that allow electrical connection between X and Y (e.g., a switch, a transistor, a capacitor, an inductor, a resistor, a diode, a display device, a light-emitting device, or a load) can be connected between X and Y. Note that a switch has a function of being controlled to be turned on or off. That is, the switch has a function of being in a conducting state (on state) or a non-conducting state (off state) to control whether current flows or not.

In the case where an element and a power supply line (e.g., a wiring supplying VDD (high power supply potential), VSS (low power supply potential), GND (the ground potential), or a desired potential) are both provided between X and Y, X and Y are not defined as being electrically connected. In the case where only a power supply line is provided between X and Y, there is no element between X and Y; therefore, X and Y are directly connected. Accordingly, in the case where only a power supply line is provided between X and Y, X and Y can be expressed as being “electrically connected”. However, in the case where an element and a power supply line are both provided between X and Y, X and Y are not defined as being electrically connected, although X and the power supply line are electrically connected (through the element) and Y and the power supply line are electrically connected. Note that in the case where a gate and a source of a transistor are provided between X and Y, X and Y are not defined as being electrically connected. Note that in the case where a gate and a drain of a transistor are provided between X and Y, X and Y are not defined as being electrically connected. That is, in the case where a drain and a source of a transistor are provided between X and Y, X and Y are defined as being electrically connected. Note that in the case where a capacitor is provided between X and Y, X and Y are defined as being electrically connected in some cases and not defined in other cases. For example, in the case where a capacitor is provided between X and Y in a structure of a digital circuit or a logic circuit, X and Y are not defined as being electrically connected in some cases. On the other hand, for example, in the case where a capacitor is provided between X and Y in a structure of an analog circuit, X and Y are defined as being electrically connected in some cases.

For example, in the case where X and Y are functionally connected, one or more circuits that allow functional connection between X and Y (e.g., a logic circuit (e.g., an inverter, a NAND circuit, or a NOR circuit); a signal converter circuit (e.g., a digital-analog converter circuit, an analog-digital converter circuit, or a gamma correction circuit); a potential level converter circuit (e.g., a power supply circuit such as a step-up circuit or a step-down circuit, or a level shifter circuit for changing the potential level of a signal); a voltage source; a current source; a switching circuit; an amplifier circuit (e.g., a circuit that can increase signal amplitude, the amount of current, or the like, an operational amplifier, a differential amplifier circuit, a source follower circuit, or a buffer circuit); a signal generation circuit; a memory circuit; or a control circuit) can be connected between X and Y. For instance, even if another circuit is interposed between X and Y, X and Y are regarded as being functionally connected when a signal output from X is transmitted to Y.

Note that an explicit description “X and Y are electrically connected” includes the case where X and Y are electrically connected (i.e., the case where X and Y are connected with another element or another circuit provided therebetween) and the case where X and Y are directly connected (i.e., the case where X and Y are connected without another element or another circuit provided therebetween).

The expression “X, Y, a source (sometimes called one of a first terminal and a second terminal) of a transistor, and a drain (sometimes called the other of the first terminal and the second terminal) of the transistor are electrically connected to each other, and X, the source of the transistor, the drain of the transistor, and Y are electrically connected to each other in this order” can be used, for example. Alternatively, it can be expressed as “X is electrically connected to Y through a source and a drain of a transistor, and X, the source of the transistor, the drain of the transistor, and Y are provided in this connection order”. Alternatively, it can be expressed as “X is electrically connected to Y through a source and a drain of a transistor, and X, the source of the transistor, the drain of the transistor, and Y are provided in this connection order”. When the connection order in a circuit structure is defined by an expression similar to the above examples, a source and a drain of a transistor can be distinguished from each other to specify the technical scope. Note that these expressions are examples and the expression is not limited to these expressions. Here, each of X and Y denotes an object (e.g., a device, an element, a circuit, a wiring, an electrode, a terminal, a conductive film, or a layer).

Even when independent components are electrically connected to each other in a circuit diagram, one component has functions of a plurality of components in some cases. For example, when part of a wiring also functions as an electrode, one conductive film has both functions of a wiring and an electrode. Thus, electrical connection in this specification includes, in its category, such a case where one conductive film has functions of a plurality of components.

In this specification and the like, a “resistor” can be, for example, a circuit element having a resistance value higher than 0Ω or a wiring having a resistance value higher than 0Ω. Therefore, in this specification and the like, a “resistor” includes a wiring having a resistance value, a transistor in which current flows between a source and a drain, a diode, and a coil. Thus, the term “resistor” can sometimes be replaced with the term “resistance”, “load”, “region having a resistance value”, or the like. Conversely, the term “resistance”, “load”, “region having a resistance value”, or the like can sometimes be replaced with the term “resistor”. The resistance value can be, for example, preferably higher than or equal to 1 mΩ and lower than or equal to 10Ω, further preferably higher than or equal to 5 mΩ and lower than or equal to 5Ω, still further preferably higher than or equal to 10 mΩ and lower than or equal to 1Ω. As another example, the resistance value may be higher than or equal to 1Ω and lower than or equal to 1×10⁹Ω.

In this specification and the like, a “capacitor” can be, for example, a circuit element having an electrostatic capacitance value higher than 0 F, a region of a wiring having an electrostatic capacitance value higher than 0 F, parasitic capacitance, or gate capacitance of a transistor. The term “capacitor”, “parasitic capacitance”, or “gate capacitance” can sometimes be replaced with the term “capacitance”. Conversely, the term “capacitance” can be replaced with the term “capacitor”, “parasitic capacitance”, or “gate capacitance” in some cases. In addition, a “capacitor” (including a “capacitor” with three or more terminals) includes an insulator and a pair of conductors between which the insulator is interposed. Thus, the term “pair of conductors” of “capacitor” can be replaced with “pair of electrodes”, “pair of conductive regions”, “pair of regions”, or “pair of terminals”. In addition, the terms “one of a pair of terminals” and “the other of the pair of terminals” are referred to as a first terminal and a second terminal, respectively, in some cases. Note that the electrostatic capacitance value can be higher than or equal to 0.05 fF and lower than or equal to 10 pF, for example. As another example, the electrostatic capacitance value may be higher than or equal to 1 pF and lower than or equal to 10 μF.

In this specification and the like, a transistor includes three terminals called a gate, a source, and a drain. The gate is a control terminal for controlling the conducting state of the transistor. Two terminals functioning as the source and the drain are input/output terminals of the transistor. One of the two input/output terminals serves as the source and the other serves as the drain on the basis of the conductivity type (n-channel type or p-channel type) of the transistor and the levels of potentials applied to the three terminals of the transistor. Thus, the terms “source” and “drain” can sometimes be replaced with each other in this specification and the like. In this specification and the like, expressions “one of a source and a drain” (or a first electrode or a first terminal) and “the other of the source and the drain” (or a second electrode or a second terminal) are used in description of the connection relation of a transistor. Depending on the transistor structure, a transistor may include a back gate in addition to the above three terminals. In that case, in this specification and the like, one of the gate and the back gate of the transistor may be referred to as a first gate and the other of the gate and the back gate of the transistor may be referred to as a second gate. Moreover, the terms “gate” and “back gate” can be replaced with each other in one transistor in some cases. In the case where a transistor includes three or more gates, the gates may be referred to as a first gate, a second gate, and a third gate in this specification and the like.

In this specification and the like, for example, a transistor with a multi-gate structure having two or more gate electrodes can be used as the transistor. With the multi-gate structure, channel formation regions are connected in series; accordingly, a plurality of transistors are connected in series. Thus, with the multi-gate structure, the amount of off-state current can be reduced, and the withstand voltage of the transistor can be increased (the reliability can be improved). Alternatively, with the multi-gate structure, drain-source current does not change very much even if drain-source voltage changes at the time of an operation in a saturation region, so that a flat slope of voltage-current characteristics can be obtained. By utilizing the flat slope of the voltage-current characteristics, an ideal current source circuit or an active load having an extremely high resistance value can be obtained. Accordingly, a differential circuit, a current mirror circuit, and the like having excellent properties can be obtained.

In this specification and the like, circuit elements such as a “light-emitting device” and a “light-receiving device” sometimes have polarities called an “anode” and a “cathode”. In the case of a “light-emitting device”, the “light-emitting device” can sometimes emit light when a forward bias is applied (a positive potential with respect to a “cathode” is applied to an “anode”). In the case of a “light-receiving device”, current is sometimes generated between an “anode” and a “cathode” when a zero bias or a reverse bias is applied (a negative potential with respect to a “cathode” is applied to an “anode”) and the “light-receiving device” is irradiated with light. As described above, an “anode” and a “cathode” are sometimes regarded as input/output terminals of the circuit elements such as a “light-emitting device” and a “light-receiving device”. In this specification and the like, an “anode” and a “cathode” of the circuit element such as a “light-emitting device” or a “light-receiving device” are sometimes called terminals (a first terminal, a second terminal, and the like). For example, one of an “anode” and a “cathode” is called a first terminal and the other of the “anode” and the “cathode” is called a second terminal in some cases.

The case where a single circuit element is illustrated in a circuit diagram may include a case where the circuit element includes a plurality of circuit elements. For example, the case where a single resistor is illustrated in a circuit diagram may include a case where two or more resistors are electrically connected to each other in series. For another example, the case where a single capacitor is illustrated in a circuit diagram may include a case where two or more capacitors are electrically connected to each other in parallel. For another example, the case where a single transistor is illustrated in a circuit diagram may include a case where two or more transistors are electrically connected to each other in series and their gates are electrically connected to each other. Similarly, for another example, the case where a single switch is illustrated in a circuit diagram may include a case where the switch includes two or more transistors which are electrically connected to each other in series or in parallel and whose gates are electrically connected to each other.

In this specification and the like, a node can be referred to as a terminal, a wiring, an electrode, a conductive layer, a conductor, or an impurity region depending on the circuit structure and the device structure. Furthermore, a terminal, a wiring, or the like can be referred to as a node.

In this specification and the like, “voltage” and “potential” can be replaced with each other as appropriate. “Voltage” refers to a potential difference from a reference potential, and when the reference potential is a ground potential, for example, “voltage” can be replaced with “potential”. Note that the ground potential does not necessarily mean 0 V. Moreover, potentials are relative values, and a potential supplied to a wiring, a potential applied to a circuit or the like, and a potential output from a circuit or the like, for example, change with a change of the reference potential.

In this specification and the like, the terms “high-level potential” and “low-level potential” do not mean a particular potential. For example, in the case where two wirings are both described as “functioning as a wiring for supplying a high-level potential”, the levels of the high-level potentials supplied from the wirings are not necessarily equal to each other. Similarly, in the case where two wirings are both described as “functioning as a wiring for supplying a low-level potential”, the levels of the low-level potentials supplied from the wirings are not necessarily equal to each other.

“Current” means a charge transfer phenomenon (electrical conduction); for example, the description “electrical conduction of positively charged particles occurs” can be rephrased as “electrical conduction of negatively charged particles occurs in the opposite direction”. Thus, unless otherwise specified, “current” in this specification and the like refers to a charge transfer phenomenon (electrical conduction) accompanied by carrier movement. Examples of a carrier here include an electron, a hole, an anion, a cation, and a complex ion, and the type of carrier differs between current flow systems (e.g., a semiconductor, a metal, an electrolyte solution, and a vacuum). The “direction of current” in a wiring or the like refers to the direction in which a carrier with a positive charge moves, and the amount of current is expressed as a positive value. In other words, the direction in which a carrier with a negative charge moves is opposite to the direction of current, and the amount of current is expressed as a negative value. Thus, in the case where the polarity of current (or the direction of current) is not specified in this specification and the like, the description “current flows from element A to element B” can be rephrased as “current flows from element B to element A”. The description “current is input to element A” can be rephrased as “current is output from element A”.

Ordinal numbers such as “first”, “second”, and “third” in this specification and the like are used to avoid confusion among components. Thus, the ordinal numbers do not limit the number of components. In addition, the ordinal numbers do not limit the order of components. In this specification and the like, for example, a “first” component in one embodiment can be referred to as a “second” component in other embodiments or the scope of claims. Moreover, in this specification and the like, for example, a “first” component in one embodiment can be omitted in other embodiments or the scope of claims.

In this specification and the like, the terms for describing positioning, such as “over” and “under”, are sometimes used for convenience to describe the positional relation between components with reference to drawings. The positional relationship between components is changed as appropriate in accordance with the direction in which the components are described. Thus, the positional relation is not limited to the terms described in the specification and the like, and can be described with another term as appropriate depending on the situation. For example, the expression “an insulator positioned over (on) a top surface of a conductor” can be replaced with the expression “an insulator positioned under (on) a bottom surface of a conductor” when the direction of a drawing illustrating these components is rotated by 180°.

Furthermore, the terms “over” and “under” do not necessarily mean that a component is placed directly over or directly under and in direct contact with another component. For example, the expression “electrode B over insulating layer A” does not necessarily mean that the electrode B is formed over and in direct contact with the insulating layer A, and does not exclude the case where another component is provided between the insulating layer A and the electrode B. Similarly, for example, the expression “electrode B above insulating layer A” does not necessarily mean that the electrode B is formed above and in direct contact with the insulating layer A, and does not exclude the case where another component is provided between the insulating layer A and the electrode B. Similarly, for example, the expression “electrode B under insulating layer A” does not necessarily mean that the electrode B is formed under and in direct contact with the insulating layer A, and does not exclude the case where another component is provided between the insulating layer A and the electrode B.

In this specification and the like, components arranged in a matrix and their positional relation are sometimes described using terms such as “row” and “column”. The positional relationship between components is changed as appropriate in accordance with the direction in which the components are described. Thus, the positional relation is not limited to the terms described in the specification and the like, and can be described with another term as appropriate depending on the situation. For example, the term “row direction” can be replaced with the term “column direction” when the direction of the diagram is rotated by 90°.

In this specification and the like, the terms “film” and “layer” can be interchanged with each other depending on the situation. For example, the term “conductive layer” can be replaced with the term “conductive film” in some cases. For another example, the term “insulating film” can be changed into the term “insulating layer” in some cases. Alternatively, the terms “film” and “layer” are not used and can be interchanged with another term depending on the case or the situation. For example, the term “conductive layer” or “conductive film” can be changed into the term “conductor” in some cases. Furthermore, for example, the term “insulating layer” or “insulating film” can be changed into the term “insulator” in some cases.

In this specification and the like, the terms “electrode”, “wiring”, “terminal”, and the like do not limit the functions of such components. For example, an “electrode” is used as part of a “wiring” in some cases, and vice versa. Furthermore, the term “electrode” or “wiring” also includes, for example, the case where a plurality of “electrodes” or “wirings” are formed in an integrated manner. For example, a “terminal” is used as part of a “wiring” or an “electrode” in some cases, and vice versa. Furthermore, the term “terminal” also includes the case where two or more selected from “electrodes”, “wirings”, and “terminals” are formed in an integrated manner, for example. Therefore, for example, an “electrode” can be part of a “wiring” or a “terminal”, and a “terminal” can be part of a “wiring” or an “electrode”. Moreover, the term “electrode”, “wiring”, or “terminal” is sometimes replaced with the term “region” depending on the case.

In this specification and the like, the terms “wiring”, “signal line”, and “power supply line” can be interchanged with each other depending on the case or the situation. For example, the term “wiring” can be changed into the term “signal line” in some cases. For another example, the term “wiring” can be changed into the term “power supply line” or the like in some cases. Conversely, the term “signal line” or “power supply line” can be changed into the term “wiring” in some cases. The term “power supply line” can be changed into the term “signal line” in some cases. Similarly, the term “signal line” can be changed into the term “power supply line” in some cases. The term “potential” that is applied to a wiring can be changed into the term “signal” depending on the case or the situation. Conversely, the term “signal” can be changed into the term “potential” in some cases.

In this specification and the like, a timing chart is used in some cases to describe an operation method of a semiconductor device. In this specification and the like, the timing chart shows an ideal operation example and a period, a level of a signal (e.g., a potential or a current), and a timing described in the timing chart are not limited unless otherwise specified. In the timing chart described in this specification and the like, the level of a signal (e.g., a potential or a current) input to a wiring (including a node) and a timing can be changed depending on the circumstances. For example, even when two periods are shown to have an equal length, the two periods have different lengths in some cases. Furthermore, for example, even when one of two periods is shown long and the other is shown short, the two periods can have the equal length in some cases, or the one period has a short length and the other has a long length in other cases.

In this specification and the like, a metal oxide is an oxide of a metal in a broad sense. Metal oxides are classified into an oxide insulator, an oxide conductor (including a transparent oxide conductor), an oxide semiconductor (also simply referred to as an OS), and the like. For example, in the case where a metal oxide is included in a channel formation region of a transistor, the metal oxide is referred to as an oxide semiconductor in some cases. That is, when a metal oxide can form a channel formation region of a transistor that has at least one of an amplifying function, a rectifying function, and a switching function, the metal oxide can be referred to as a metal oxide semiconductor. In the case where an OS transistor is mentioned, the OS transistor can also be referred to as a transistor including a metal oxide or an oxide semiconductor.

In this specification and the like, a metal oxide containing nitrogen is also collectively referred to as a metal oxide in some cases. A metal oxide containing nitrogen may be called a metal oxynitride.

In this specification and the like, an impurity in a semiconductor refers to, for example, an element other than a main component of a semiconductor layer. For example, an element with a concentration of lower than 0.1 atomic % is an impurity. When an impurity is contained, for example, at least one of an increase in the density of defect states in a semiconductor, a decrease in carrier mobility, and a decrease in crystallinity occurs in some cases. In the case where the semiconductor is an oxide semiconductor, examples of an impurity that changes characteristics of the semiconductor include Group 1 elements, Group 2 elements, Group 13 elements, Group 14 elements, Group 15 elements, and transition metals other than the main components; specific examples are hydrogen (contained also in water), lithium, sodium, silicon, boron, phosphorus, carbon, and nitrogen. In the case where the semiconductor is a silicon layer, examples of an impurity that changes characteristics of the semiconductor include Group 1 elements, Group 2 elements, Group 13 elements, and Group 15 elements (except oxygen and hydrogen).

In this specification and the like, a switch has a function of being in a conducting state (on state) or a non-conducting state (off state) to control whether current flows or not. Alternatively, a switch has a function of selecting and changing a current path. Thus, a switch may have two terminals or three or more terminals through which current flows, in addition to a control terminal. For example, an electrical switch or a mechanical switch can be used. That is, a switch can be any element capable of controlling current, and is not limited to a particular element.

Examples of an electrical switch include a transistor (e.g., a bipolar transistor and a MOS transistor), a diode (e.g., a PN diode, a PIN diode, a Schottky diode, a MIM (Metal Insulator Metal) diode, a MIS (Metal Insulator Semiconductor) diode, and a diode-connected transistor), and a logic circuit in which such elements are combined. Note that in the case of using a transistor as a switch, a “conducting state” of the transistor refers to a state where a source electrode and a drain electrode of the transistor can be regarded as being electrically short-circuited or a state where a current can be made to flow between the source electrode and the drain electrode. Furthermore, a “non-conducting state” of the transistor refers to a state where the source electrode and the drain electrode of the transistor can be regarded as being electrically disconnected. Note that in the case where a transistor operates just as a switch, there is no particular limitation on the polarity (conductivity type) of the transistor.

In this specification, “parallel” indicates a state where two straight lines are placed at an angle greater than or equal to −10° and less than or equal to 10°. Thus, the case where the angle is greater than or equal to −5° and less than or equal to 5° is also included. In addition, “approximately parallel” or “substantially parallel” indicates a state where two straight lines are placed at an angle greater than or equal to −30° and less than or equal to 30°. Moreover, “perpendicular” indicates a state where two straight lines are placed at an angle greater than or equal to 80° and less than or equal to 100°. Thus, the case where the angle is greater than or equal to 85° and less than or equal to 95° is also included. Furthermore, “approximately perpendicular” or “substantially perpendicular” indicates a state where two straight lines are placed at an angle greater than or equal to 60° and less than or equal to 120°.

In this specification and the like, one embodiment of the present invention can be constituted by appropriately combining a structure described in an embodiment with any of the structures described in the other embodiments. In addition, in the case where a plurality of structure examples are described in one embodiment, the structure examples can be combined as appropriate.

Note that a content (or part of the content) described in one embodiment can be applied to, combined with, or replaced with at least one of another content (or part of the content) in the embodiment and a content (or part of the content) described in one or a plurality of different embodiments.

Note that in each embodiment, a content described in the embodiment is a content described using a variety of diagrams or a content described with text disclosed in the specification.

Note that by combining a diagram (or part thereof) described in one embodiment with at least one of another part of the diagram, a different diagram (or part thereof) described in the embodiment, and a diagram (or part thereof) described in one or a plurality of different embodiments, much more diagrams can be provided.

Embodiments described in this specification are described with reference to the drawings. Note that the embodiments can be implemented in many different modes, and it will be readily appreciated by those skilled in the art that modes and details can be changed in various ways without departing from the spirit and scope thereof. Thus, the present invention should not be interpreted as being limited to the description in the embodiments. Note that in the structures of the invention in the embodiments, the same portions or portions having similar functions are denoted by the same reference numerals in different drawings, and repeated description thereof is omitted in some cases. In perspective views and the like, illustration of some components may be omitted for clarity of the drawings.

In this specification, a plan view is sometimes used to explain a structure in each embodiment. A plan view is a diagram showing a plane of a structure seen in the vertical direction or a diagram showing a plane (section) of a structure cut in the horizontal direction, for example. Hidden lines (e.g., dashed lines) shown in a plan view can indicate the positional relation between a plurality of components included in a structure or the overlapping relation between the plurality of components. In this specification and the like, the term “plan view” can be replaced with the term “schematic plan view”, “projection view”, “top view”, or “bottom view”. A plane (section) of a structure cut in a direction other than the horizontal direction may be referred to as a plan view depending on circumstances.

In this specification, a cross-sectional view is sometimes used to explain a structure in each embodiment. A plan view is a diagram showing a plane of a structure seen in the horizontal direction or a diagram showing a plane (section) of a structure cut in the vertical direction, for example. In this specification and the like, the term “cross-sectional view” can be replaced with the term “schematic cross-sectional view”, “front view”, or “side view”. A plane (section) of a structure cut in a direction other than the perpendicular direction may be referred to as a cross-sectional view depending on conditions.

In this specification and the like, when a plurality of components are denoted with the same reference numerals, and in particular need to be distinguished from each other, an identification sign such as “_l”, “[n]”, or “[m,n]” is sometimes added to the reference numerals. Components denoted with identification signs such as “_l”, “[n]”, and “[m,n]” in the drawings and the like are sometimes described without such identification signs in this specification and the like when the components do not need to be distinguished from each other.

In the drawings in this specification, the size, the layer thickness, or the region is exaggerated for clarity in some cases. Therefore, the size, the layer thickness, or the region is not limited to the illustrated scale. The drawings are schematic views showing ideal examples, and embodiments of the present invention are not limited to shapes, values, or the like shown in the drawings. For example, variations in a signal, a voltage, or a current due to noise, variations in a signal, a voltage, or a current due to difference in timing, or the like can be included.

### Embodiment 1

In this embodiment, a semiconductor device of one embodiment of the present invention is described.

### Circuit Structure Example of Semiconductor Device

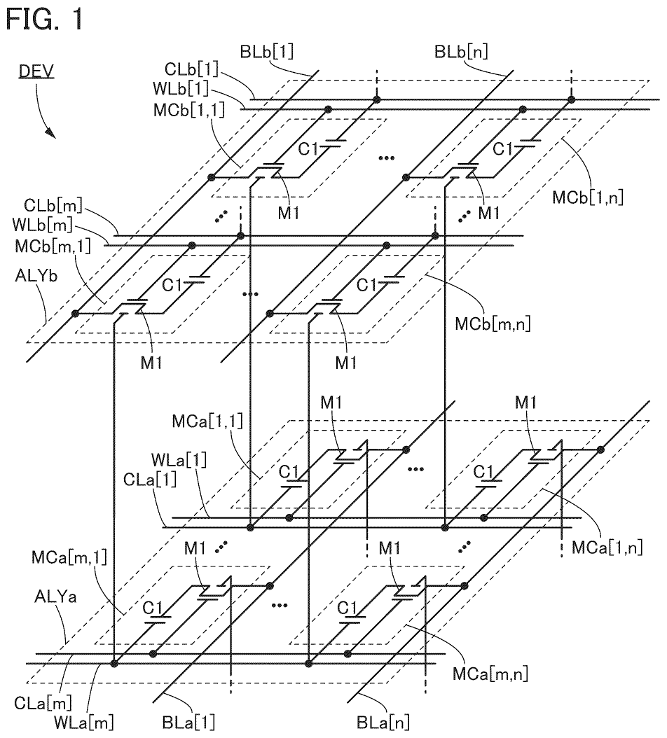

FIG. 1 is a circuit diagram illustrating a structure example of a semiconductor device DEV of one embodiment of the present invention. The semiconductor device DEV includes a memory layer ALYa and a memory layer ALYb, for example. Note that the memory layer ALYb is positioned above the memory layer ALYa in FIG. 1.

The memory layer ALYa and the memory layer ALYb each include a plurality of memory cells. Specifically, in each of the memory layer ALYa and the memory layer ALYb, a plurality of memory cells are arranged in an array. In FIG. 1, for example, the memory cells are arranged in a matrix of m rows and n columns (m is an integer of 1 or more and n is an integer of 1 or more) in each of the memory layer ALYa and the memory layer ALYb.

Note that in this specification and drawings, for example, a memory cell MC positioned in the first column and the first row of the matrix of the memory layer ALYa is referred to as a memory cell MCa[1,1], and a memory cell positioned in the m-th row and the n-th column of the matrix of the memory layer ALYb is referred to as a memory cell MCb[m,n].

Note that although the number of rows and the number of columns of the matrix of the memory layer ALYa are equal to those of the matrix of the memory layer ALYb in FIG. 1, the number of rows and the number of columns of the matrix of the memory layer ALYa are not necessarily equal to those of the matrix of the memory layer ALYb.

Note that the memory cell MC illustrated in FIG. 1 is an example of a memory cell called a DRAM (Dynamic Random Access Memory) and includes a transistor M1 and a capacitor C1.

In particular, in this specification and the like, a DRAM where an OS transistor is used as the transistor M1 is referred to as a DOSRAM (Dynamic Oxide Semiconductor Random Access Memory) (registered trademark) in some cases.

An OS transistor is preferably used as the transistor M1, for example. Specifically, examples of a metal oxide included in a channel formation region of the OS transistor include indium oxide, gallium oxide, and zinc oxide. The metal oxide preferably includes one or two or more selected from indium, an element M, and zinc. The element M is one or more kinds selected from gallium, aluminum, silicon, boron, yttrium, tin, copper, vanadium, beryllium, titanium, iron, nickel, germanium, zirconium, molybdenum, lanthanum, cerium, neodymium, hafnium, tantalum, tungsten, cobalt, and magnesium. In particular, the element M is preferably one or more kinds selected from aluminum, gallium, yttrium, and tin.

It is particularly preferable that an oxide containing indium (In), gallium (Ga), and zinc (Zn) (also referred to as IGZO) be used as the metal oxide used for a semiconductor layer. Alternatively, it is preferable to use an oxide containing indium, tin, and zinc (also referred to as ITZO (registered trademark)). Alternatively, it is preferable to use an oxide containing indium, gallium, tin, and zinc. Alternatively, it is preferable to use an oxide containing indium (In), aluminum (Al), and zinc (Zn) (also referred to as IAZO). Alternatively, it is preferable to use an oxide containing indium (In), aluminum (Al), gallium (Ga), and zinc (Zn) (also referred to as IAGZO). Note that the OS transistor will be described in detail in description of a cross-sectional structure example of the semiconductor device.

A transistor other than an OS transistor may be used as the transistor M1. For example, a transistor including silicon in a channel formation region (hereinafter referred to as a Si transistor) can be employed as the transistor M1. As the silicon, single crystal silicon, amorphous silicon (sometimes referred to as hydrogenated amorphous silicon), microcrystalline silicon, or polycrystalline silicon (including low-temperature polycrystalline silicon) can be used, for example.

Examples of a transistor that can be used as the transistor M1 other than an OS transistor and a Si transistor include a transistor including germanium in a channel formation region, a transistor including a compound semiconductor, such as zinc selenide, cadmium sulfide, gallium arsenide, indium phosphide, gallium nitride, or silicon germanium, in a channel formation region, a transistor including a carbon nanotube in a channel formation region, and a transistor including an organic semiconductor in a channel formation region.

Although the transistor M1 illustrated in FIG. 1 is an n-channel transistor, the transistor M1 may be a p-channel transistor depending on conditions or circumstances. In the case where an n-channel transistor is replaced with a p-channel transistor, a potential or the like input to the memory cell MC needs to be appropriately changed so that the memory cell MC normally operates. Note that the same applies to transistors described in other parts of the specification and transistors illustrated in other drawings, not only to that in FIG. 1. In this embodiment, the structure of the memory cell MC is described assuming that the transistor M1 is an n-channel transistor.

The transistor M1 in an on state preferably operates in a saturation region. Depending on circumstances, the transistor M1 in an on state may operate in a linear region. Alternatively, the transistor M1 may operate in a subthreshold region.

The transistor M1 is, for example, a transistor having a structure including gates over and under a channel; the transistor M1 includes a first gate and a second gate. For convenience, the first gate is referred to as a gate (sometimes referred to as a front gate) and the second gate is referred to as a back gate so that they are distinguished from each other, but the first gate and the second gate can be interchanged; thus, the term “gate” can be replaced with the term “back gate”. Therefore, in this specification and the like, the term “gate” can be replaced with the term “back gate”. Similarly, the term “back gate” can be replaced with the term “gate”. As a specific example, a connection structure in which “a gate is electrically connected to a first wiring and a back gate is electrically connected to a second wiring” can be replaced with a connection structure in which “a back gate is electrically connected to a first wiring and a gate is electrically connected to a second wiring”.

Note that the above description of the transistor applies to not only the transistor M1 but also transistors described in other parts of the specification and transistors illustrated in the drawings.

In each of the memory cell MCa[1,1] to a memory cell MCa[m,n] and a memory cell MCb[1,1] to the memory cell MCb[m,n], a first terminal of the transistor M1 is electrically connected to a first terminal of the capacitor C1.

In each of the memory cell MCa[1,1] to the memory cell MCa[m,1] arranged in the first column of the matrix of the memory layer ALYa, a second terminal of the transistor M1 is electrically connected to a wiring BLa[1]. In each of the memory cell MCa[1,n] to the memory cell MCa[m,n] arranged in the n-th column of the matrix of the memory layer ALYa, a second terminal of the transistor M1 is electrically connected to a wiring BLa[n]. In each of the memory cell MCb[1,1] to the memory cell MCb[m,1] arranged in the first column of the matrix of the memory layer ALYb, a second terminal of the transistor M1 is electrically connected to a wiring BLb[1]. In each of the memory cell MCb[1,n] to the memory cell MCb[m,n] arranged in the n-th column of the matrix of the memory layer ALYb, a second terminal of the transistor M1 is electrically connected to a wiring BLb[n].

In each of the memory cell MCa[1,1] to the memory cell MCa[1,n] arranged in the first row of the matrix of the memory layer ALYa, the gate of the transistor M1 is electrically connected to a wiring WLa[1], and a second terminal of the capacitor C1 is electrically connected to a wiring CLa[1]. In each of the memory cell MCa[m,1] to the memory cell MCa[m,n] arranged in the m-th row of the matrix of the memory layer ALYa, the gate of the transistor M1 is electrically connected to a wiring WLa[m], and a second terminal of the capacitor C1 is electrically connected to a wiring CLa[m]. In each of the memory cell MCb[1,1] to the memory cell MCb[1,n] arranged in the first row of the matrix of the memory layer ALYb, the gate of the transistor M1 is electrically connected to a wiring WLb[1], and a second terminal of the capacitor C1 is electrically connected to a wiring CLb[1]. In each of the memory cell MCb[m,1] to the memory cell MCb[m,n]arranged in the m-th row of the matrix of the memory layer ALYb, the gate of the transistor M1 is electrically connected to a wiring WLb[m], and a second terminal of the capacitor C1 is electrically connected to a wiring CLb[m].

In each of the memory cell MCb[1,1] to the memory cell MCb[1,n] arranged in the first row of the matrix of the memory layer ALYb, the back gate of the transistor M1 is electrically connected to the wiring CLa[1] extended in the memory layer ALYa. In each of the memory cell MCb[m,1] to the memory cell MCb[m,n] arranged in the m-th row of the matrix of the memory layer ALYb, the back gate of the transistor M1 is electrically connected to the wiring CLa[m]extended in the memory layer ALYa.

Note that the back gate of the transistor M1 included in each of the memory cell MCa[1,1] to the memory cell MCa[m,n] placed in the memory layer ALYa may be electrically connected to a wiring extended below the memory layer ALYa (not illustrated), for example. The wiring CLa[1] to the wiring CLa[m] extended in the memory layer ALYb may be electrically connected to a back gate of a transistor placed above the memory layer ALYb (not illustrated), for example.

The wiring WLa[1] to the wiring WLa[m] function as word lines for the memory cell MCa[1,1] to the memory cell MCa[m,n] included in the memory layer ALYa. Similarly, the wiring WLb[1] to the wiring WLb[m] function as word lines for the memory cell MCb[1,1] to the memory cell MCb[m,n] included in the memory layer ALYb. That is, the wiring WLa[1] to the wiring WLa[m] and the wiring WLb[1] to the wiring WLb[m] function as wirings that transmit selection signals (which may be currents, variable potentials, or pulse voltages) for selecting the memory cells MC on which writing or reading is to be performed. Note that the wiring WLa[1] to the wiring WLa[m] and the wiring WLb[1] to the wiring WLb[m] may function as wirings that supply a constant potential depending on circumstances.

The wiring BLa[1] to the wiring BLa[n] function as bit lines for the memory cell MCa[1,1] to the memory cell MCa[m,n] included in the memory layer ALYa. Similarly, the wiring BLb[1] to the wiring BLb[n] function as bit lines for the memory cell MCb[1,1] to the memory cell MCb[m,n] included in the memory layer ALYb. That is, the wiring BLa[1] to the wiring BLa[n] and the wiring BLb[1] to the wiring BLb[n] function as wirings that transmit write data to the selected memory cells MC and function as wirings that transmit data read from the selected memory cells MC. Note that the wiring BLa[1] to the wiring BLa[n] and the wiring BLb[1] to the wiring BLb[n] may function as wirings that supply a constant potential depending on circumstances.

The wiring CLa[1] to the wiring CLa[m] and the wiring CLb[1] to the wiring CLb[m]function as wirings that supply a constant potential, for example. The potential can be, for example, a high-level potential, a low-level potential, a positive potential, the ground potential, or a negative potential. Note that the wiring CLa[1] to the wiring CLa[m] and the wiring CLb[1] to the wiring CLb[m] may function as wirings that supply not a constant potential but a variable potential (e.g., a pulse voltage) depending on circumstances.

### Cross-Sectional Structure Example of Semiconductor Device

Next, a structure example of the semiconductor device DEV is described.

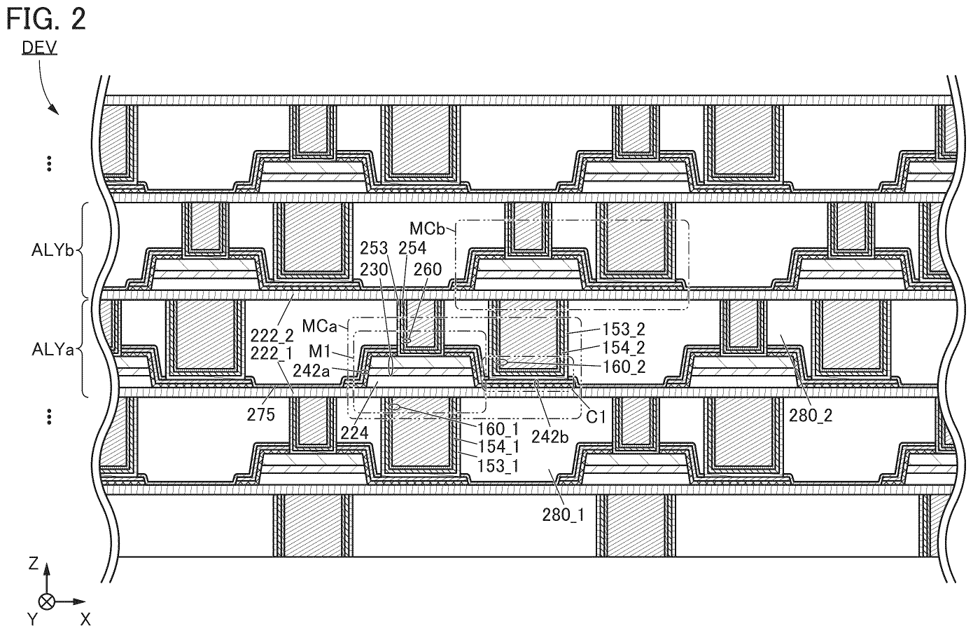

FIG. 2 is a schematic cross-sectional view illustrating a structure example of the semiconductor device DEV of one embodiment of the present invention. In FIG. 2, the semiconductor device DEV includes not only the memory layer ALYa and the memory layer ALYb but also a memory layer provided below the memory layer ALYa and a memory layer provided above the memory layer ALYb.

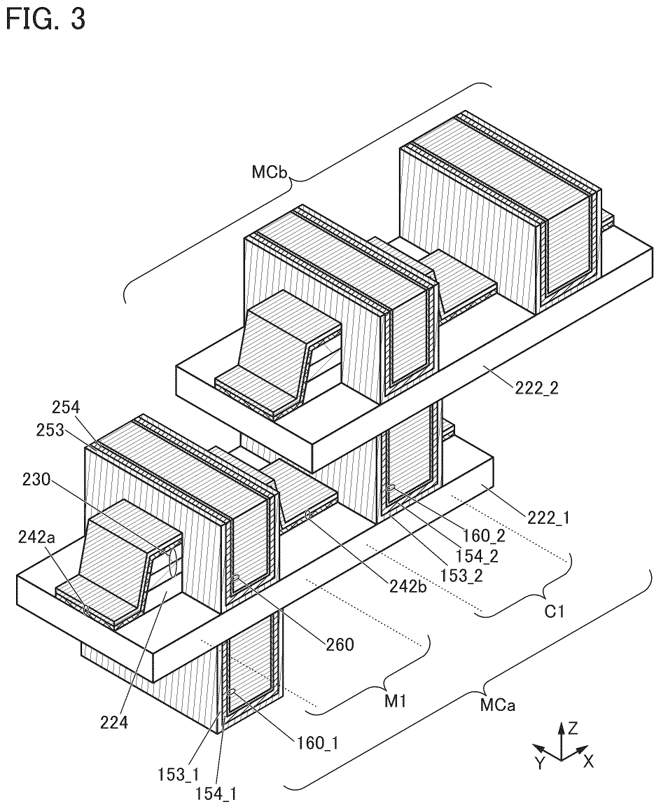

FIG. 3 is a schematic perspective view illustrating a structure example of the semiconductor device DEV in FIG. 2. Note that in FIG. 3, hatching of an insulator 222_1 and an insulator 222_2 described later is intentionally omitted and an insulator 275 is not illustrated so that the stacked-layer structure of the memory layer ALYa and the memory layer ALYb can be easily seen.

The X direction shown in FIG. 2 is parallel to the channel length direction of the transistor M1, the Y direction is perpendicular to the X direction, and the Z direction is perpendicular to the X direction and the Y direction. The X direction, the Y direction, and the Z direction shown in FIG. 2 form right-handed systems. Note that the X direction, the Y direction, and the Z direction in FIG. 2 are also shown in FIG. 3 and drawings described later.

In order to briefly describe the structure example of the semiconductor device DEV, first, attention is focused on the memory layer ALYa in FIG. 2.

The memory layer ALYa includes the insulator 2221, an insulator 224, an insulator 253, an insulator 254, the insulator 275, an insulator 153_2, an insulator 154_2, an insulator 280_2, a conductor 242a, a conductor 242b, a conductor 160_2, a conductor 260, and an oxide 230, for example.

Note that the memory layer positioned below the memory layer ALYa includes an insulator 153_1, the insulator 154_2, an insulator 2801, and a conductor 1601, for example.

Note that in the memory layer ALYa, part of the memory cell MCa is provided over the insulator 222_1.

As described in the circuit structure example, the memory cell MCa includes the transistor M1 and the capacitor C1. Note that the transistor M1 is an OS transistor in FIG. 2, for example. That is, the semiconductor layer of the transistor M1 includes a metal oxide.

The transistor M1 includes the insulator 224, the insulator 253, the insulator 254, the conductor 242a, the conductor 242b, the conductor 260, the conductor 1601, and the oxide 230.

In FIG. 2, the capacitor C1 includes the insulator 153_2, the insulator 154_2, the conductor 242b, and the conductor 160_2.

The conductor 260 is provided to overlap with a region including the oxide 230, for example. The conductor 260 functions as the gate (sometimes referred to as a first gate) of the transistor M1. The conductor 260 functions as any one of the wiring WLa[1] to the wiring WLa[m] in FIG. 1.

The insulator 253 and the insulator 254 functions as a first gate insulating film.

The oxide 230 is provided to overlap with a region including the conductor 160_1 with the insulator 222_1 therebetween, for example. The oxide 230 functions as a semiconductor included in the channel formation region of the transistor M1.

The conductor 160_1 functions as the back gate (sometimes referred to as a second gate) of the transistor M1. The conductor 160_1 also functions as one of a pair of electrodes of a capacitor included in a memory cell of the memory layer positioned below the memory layer ALYa.

The conductor 160_1 is provided to fill an opening formed in the insulator 280_1. Note that the insulator 153_1, an insulator 154_1, and the conductor 160_1 are formed in this order in the opening.

The insulator 222_1 and the insulator 224 function as a second gate insulating film of the transistor M1.

The conductor 242a is provided over part of the oxide 230 and part of the insulator 222_1, for example. Similarly, the conductor 242b is provided over part of the oxide 230 and part of the insulator 2221, for example. In particular, the conductor 242a and the conductor 242b are physically separated from each other by the conductor 260. The conductor 242a functions as one of a source and a drain of the transistor M1, and the conductor 242b functions as the other of the source and the drain of the transistor M1. The conductor 242a functions as any one of the wiring BLa[1] to the wiring BLa[n] in FIG. 1 or a conductor electrically connected to the wiring. Note that the insulator 275 for preventing diffusion of oxygen into the conductor 242a and the conductor 242b is provided over the conductor 242a and the conductor 242b.

The conductor 160_2 is provided, for example, in a region that does not overlap with the oxide 230 and is located over the conductor 242b with the insulator 153_1 and the insulator 153_2 functioning as a dielectric therebetween. In other words, in a region where the insulator 222_1 and the conductor 160_2 are formed in this order, an insulator functioning as a dielectric is provided over the conductor 160_2, and the conductor 160_2 is provided over the insulator. The dielectric functions as an insulator sandwiched between the pair of electrodes of the capacitor C1 in FIG. 1, and the conductor 160_2 corresponds to the second terminal of the capacitor C1 in FIG. 1. The conductor 160_2 functions as any one of the wiring CLa[1] to the wiring CLa[m] in FIG. 1. Furthermore, the conductor 160_2 also functions as the back gate of the transistor M1 included in the memory cell MCb of the memory layer ALYb in FIG. 1.

The memory layer ALYb includes the insulator 2222, for example.

The insulator 222_2 is provided above the conductor 260 and the conductor 160_2.

In the memory layer ALYb, part of the memory cell MCb is provided over the insulator 222_2. Specifically, like the transistor M1 of the memory cell MCa, the transistor M1 of the memory cell MCb is provided such that the semiconductor included in the channel formation region of the transistor M1 in the memory cell MCb overlaps with a region including the conductor 160_2 functioning as the second terminal of the capacitor C1.

For the structures of the transistor M1 and the capacitor C1 included in the memory cell MCb, the above description of the structures of the transistor M1 and the capacitor C1 in the memory cell MCa is referred to.

The conductor 160_2 included in the capacitor C1 of the memory cell MCb also functions as the back gate of the transistor M1 included in a memory cell of the memory layer placed above the memory layer ALYb.

The semiconductor device DEV is formed as illustrated in FIG. 2, whereby the conductor corresponding to the second terminal of the capacitor C1 in the memory cell in the lower memory layer can also serve as the conductor corresponding to the back gate of the transistor M1 in the memory cell of the upper memory layer. At the time of forming one memory layer, the conductor corresponding to the gate of the transistor M1 included in the memory cell and the conductor corresponding to the second terminal of the capacitor C1 can be formed at the same time. That is, the structure illustrated in FIG. 2 offers the following advantages: the number of photomasks for manufacturing the semiconductor device DEV can be smaller than that in the case of a conventional structure, and the manufacturing process of the semiconductor device DEV can be shortened.

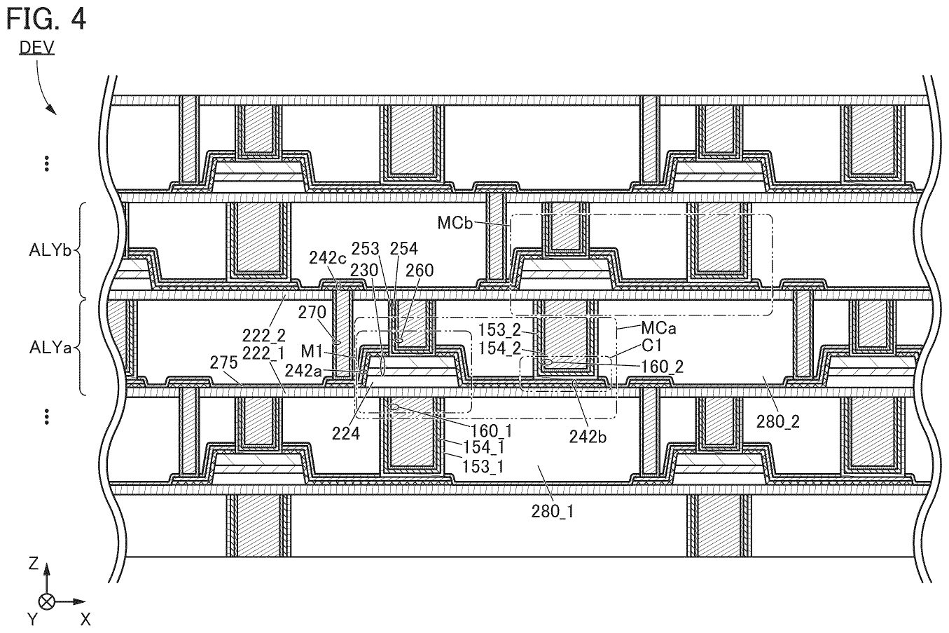

The structure of the semiconductor device DEV in FIG. 2 may be changed depending on circumstances. For example, the structure of the semiconductor device DEV in FIG. 2 may be changed to that of the semiconductor device DEV illustrated in FIG. 4. In the semiconductor device DEV in FIG. 4, a conductor 270 functioning as a plug or a wiring is provided over the conductor 242a not overlapping with the oxide 230, and a conductor 242c is provided over the conductor 270 and the insulator 222_2. In that case, the conductor 242c can be formed at the same time as the conductor 242a and the conductor 242b included in the memory cell MCb of the memory layer ALYb. In addition, the conductor 242c can be formed using the same material as the conductor 242a and the conductor 242b. The conductor 242c functions as any one of the wiring BLa[1] to the wiring BLa[n] in the memory layer ALYa.

### Layout Example of Semiconductor Device

Next, the layout of the memory layer included in the semiconductor device DEV is described.

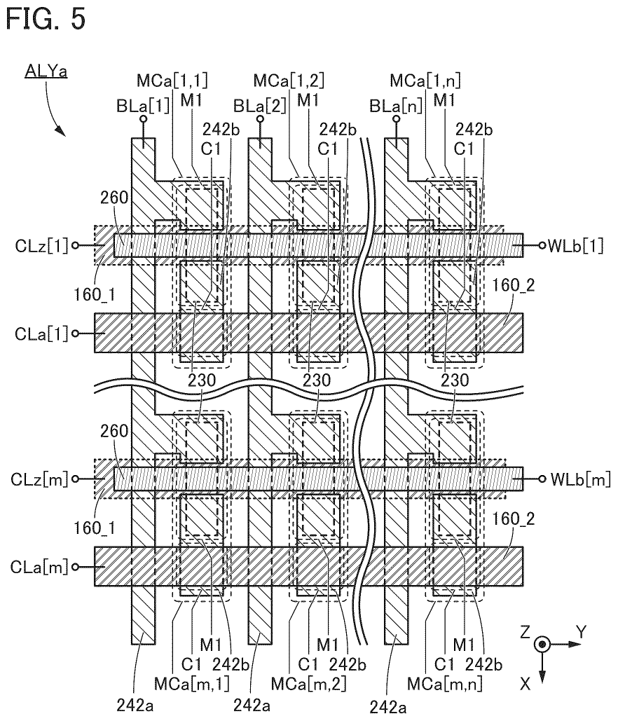

FIG. 5 is a layout diagram (plan view) illustrating the circuit structure of the memory layer ALYa of the semiconductor device DEV illustrated in FIG. 2. Note that for convenience, wirings that are extended below the memory layer ALYa and electrically connected to the back gates of the transistors M1 included in the memory cells MCa are denoted as a wiring CLz[1] to a wiring CLz[m] in FIG. 5. In addition, insulators included in the semiconductor device DEV are not illustrated in FIG. 5.

As in the description of the semiconductor device DEV in FIG. 2, the conductor 160_1 is provided below the memory layer ALYa in FIG. 5. The oxide 230 is provided above the conductor 160_1. The conductor 242a and the conductor 242b are provided to cover part of the oxide 230. The conductor 260 is provided above the oxide 230, the conductor 242a, and the conductor 242b. The conductor 160_2 is provided above the conductor 242a and the conductor 242b.

As illustrated in FIG. 5, the conductor 242a functions as the wiring BLa[1] to the wiring BLa[n] extending in the column direction.

As illustrated in FIG. 5, the conductor 160_1 functions as the wiring CLz[1] to the wiring CLz[m] extending in the row direction. Note that in the case where the memory layer ALYa illustrated in FIG. 5 is replaced with the memory layer ALYb, the conductor 160_1 can be regarded as the wiring CLa[1] to the wiring CLa[m] extending in the row direction.

As illustrated in FIG. 5, the conductor 160_2 functions as the wiring CLa[1] to the wiring CLa[m] extending in the row direction. Note that in the case where the memory layer ALYa illustrated in FIG. 5 is replaced with the memory layer ALYb, the conductor 160_2 can be regarded as the wiring CLb[1] to the wiring CLb[m] extending in the row direction.

In FIG. 5, the transistor M1 is formed with the oxide 230, part of the conductor 242a, part of the conductor 242b, part of the conductor 260, part of the conductor 1601, a gate insulating film (not illustrated), and the like. The capacitor C1 is formed with part of the conductor 242b, part of the conductor 160_2, the insulator (not illustrated) functioning as a dielectric, and the like.

Each of the oxide 230, the conductor 242a, the conductor 242b, the conductor 260, the conductor 160_1, and the conductor 160_2 can be formed by a lithography method, for example. Specifically, for example, in the case where the conductor 242a is formed, a conductive material to be the conductor 242a is formed by one or more methods selected from a sputtering method, a CVD method, a PLD method, and an ALD method, and then a desired pattern is formed by a lithography method. The oxide 230, the conductor 242b, the conductor 260, the conductor 160_1, and the conductor 160_2 can also be formed by a method similar to the above.

For example, an insulator may be provided between the oxide 230 and the conductor 260, between the oxide 230 and the conductor 1601, and between the conductor 242b and the conductor 160_2. In particular, the insulator provided between the oxide 230 and the conductor 260 functions as a first gate insulating film (sometimes referred to as a gate insulating film or a front gate insulating film) in some cases.

In a process of forming the memory layer ALYa, planarization treatment using a chemical mechanical polishing method or the like may be performed in order that the heights of film surfaces on which one or more selected from an insulator, a conductor, and a semiconductor are formed can be equal to each other.

### Structure Example of Memory Cell

Next, a structure example of the memory cell of the semiconductor device DEV illustrated in FIG. 2 is described.

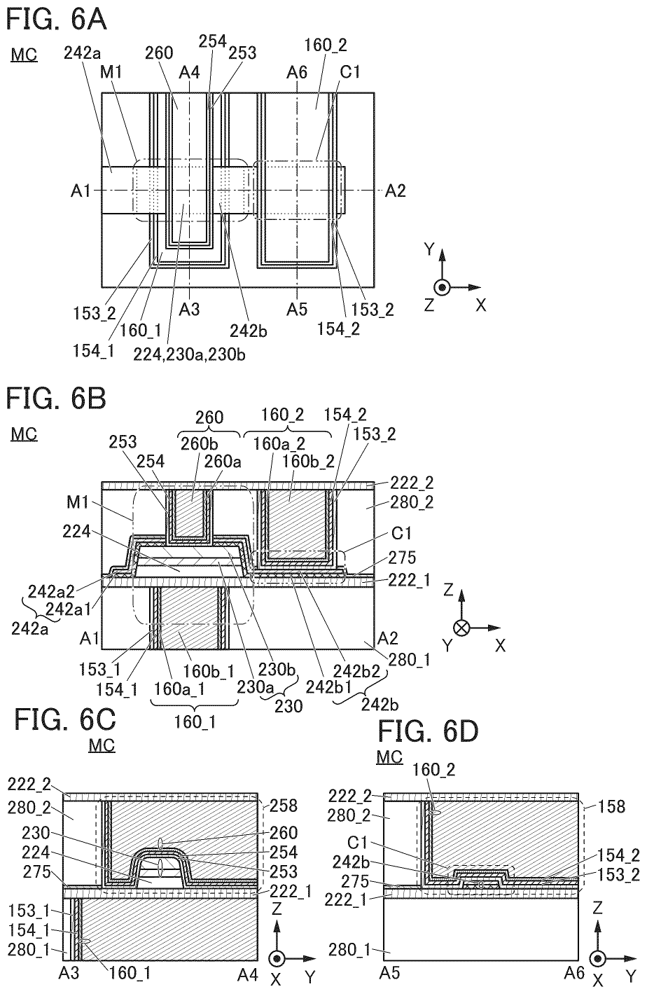

FIG. 6A to FIG. 6D are a schematic plan view and schematic cross-sectional views of the memory cell MC including the transistor M1 and the capacitor C1 in the semiconductor device DEV in FIG. 2. FIG. 6A is the schematic plan view of the memory cell MC. FIG. 6B to FIG. 6D are the schematic cross-sectional views of the memory cell MC. Here, FIG. 6B is a cross-sectional view of a portion along dashed-dotted line A1-A2 illustrated in FIG. 6A, and is a cross-sectional view of the transistor M1 in the channel length direction. FIG. 6C is a schematic cross-sectional view of a portion along dashed-dotted line A3-A4 illustrated in FIG. 6A, and is a schematic cross-sectional view of the transistor M1 in the channel width direction. FIG. 6D is a schematic cross-sectional view of a portion along dashed-dotted line A5-A6 illustrated in FIG. 6A, and is a schematic cross-sectional view of the capacitor C1. Note that some components are omitted in the top view of FIG. 6A for clarity of the drawing.

The memory cell MC includes the insulator 2801, the insulator 1531, the insulator 154_1, and the conductor 160_1 (a conductor 160a_1 and a conductor 160b_1) over a substrate (not illustrated). Furthermore, the memory cell MC includes the insulator 222_1 over the insulator 280_1, the insulator 153_1, the insulator 154_1, and the conductor 160_1. Moreover, the memory cell MC includes the insulator 224 in a region that is over the insulator 222_1 and includes an area overlapping with the conductor 160_1; an oxide 230a over the insulator 224; and an oxide 230b over the oxide 230a. In addition, the memory cell MC includes the conductor 242a (a conductor 242al and a conductor 242a2) and the conductor 242b (a conductor 242b1 and a conductor 242b2) over the insulator 222_1, a side surface of the insulator 224, a side surface of the oxide 230a, and the oxide 230b. Furthermore, the memory cell MC includes the insulator 275 over the insulator 2221, the conductor 242a, and the conductor 242b, and the insulator 280_2 over the insulator 275. Moreover, the memory cell MC includes the insulator 253 over the oxide 230b, the insulator 254 over the insulator 253, and the conductor 260 (a conductor 260a and a conductor 260b) over the insulator 254. In addition, the memory cell MC includes the insulator 153_2 in a region that is over the conductor 242b and does not overlap with the oxide 230a or the oxide 230b; the insulator 154_2 over the insulator 153_2; and the conductor 160_2 (a conductor 160a_2 and a conductor 160b_2) over the insulator 154_2. Moreover, the memory cell MC includes the insulator 222_2 over the insulator 280_2, the insulator 253, the insulator 254, the conductor 260, the insulator 153_2, the insulator 154_2, and the conductor 160_2. In particular, one or both of the transistor M1 and the capacitor C1 are provided to be embedded in the insulator 280_2.

In this specification and the like, the oxide 230a and the oxide 230b are collectively referred to as the oxide 230 in some cases.

An opening 258 reaching the oxide 230b is provided in the insulator 280_2 and the insulator 275. That is, the opening 258 includes a region overlapping with the oxide 230b. It can also be said that the insulator 275 includes an opening overlapping with the opening included in the insulator 280_2. That is, the opening 258 includes the opening included in the insulator 280_2 and the opening included in the insulator 275. The insulator 253, the insulator 254, and the conductor 260 are placed in the opening 258. That is, the conductor 260 includes a region overlapping with the oxide 230b with the insulator 253 and the insulator 254 therebetween. The conductor 260, the insulator 253, and the insulator 254 are provided between the conductor 242a and the conductor 242b in the channel length direction of the transistor M1. The insulator 254 includes a region in contact with a side surface of the conductor 260 and a region in contact with the bottom surface of the conductor 260. As illustrated in FIG. 6C, the top surface of the insulator 222_1 is exposed in a region of the opening 258 that does not overlap with the oxide 230.

The oxide 230 preferably includes the oxide 230a placed over the insulator 224 and the oxide 230b placed over the oxide 230a. Including the oxide 230a under the oxide 230b makes it possible to inhibit diffusion of impurities into the oxide 230b from components formed below the oxide 230a.

Although a structure in which two layers, the oxide 230a and the oxide 230b, are stacked as the oxide 230 in the transistor M1 is described, the present invention is not limited thereto. For example, the oxide 230 may be provided as a single layer of the oxide 230b or to have a stacked-layer structure of three or more layers, or the oxide 230a and the oxide 230b may each have a stacked-layer structure.

In FIG. 6A to FIG. 6D, the transistor M1 includes the oxide 230 functioning as a semiconductor layer, the conductor 260 functioning as a first gate (also referred to as a gate, a top gate, or a front gate) electrode, the conductor 160_1 functioning as a second gate (also referred to as a back gate) electrode, the conductor 242a functioning as one of a source electrode and a drain electrode, and the conductor 242b functioning as the other of the source electrode and the drain electrode. The insulator 253 and the insulator 254 functioning as a first gate insulator are also included. The insulator 222_1 and the insulator 224 functioning as a second gate insulator are also included. Note that the gate insulator is also referred to as a gate insulating layer or a gate insulating film in some cases. At least part of a region of the oxide 230 overlapping with the conductor 260 functions as a channel formation region.

The first gate electrode and the first gate insulating film are placed in the opening 258 formed in the insulator 280_2 and the insulator 275. That is, the conductor 260, the insulator 254, and the insulator 253 are placed in the opening 258.

The capacitor C1 includes the conductor 242b functioning as a lower electrode, the insulator 153_2 and the insulator 154_2 functioning as a dielectric, and the conductor 160_2 functioning as an upper electrode. That is, the capacitor C1 forms a MIM (Metal-Insulator-Metal) capacitor.

The upper electrode and the dielectric of the capacitor C1 are placed in an opening 158 formed in the insulator 280_2 and the insulator 275. That is, the conductor 160 2, the insulator 153_2, and the insulator 154_2 are placed in the opening 158.

The memory cell MC including the transistor M1 and the capacitor C1 and described in this embodiment can be used as a memory cell of a memory device. In that case, the conductor 242a is electrically connected to a sense amplifier in some cases, and the conductor 242a functions as a bit line. Here, as illustrated in FIG. 6A, the capacitor C1 is provided so as to at least partly overlap with the conductor 242b included in the transistor M1. Accordingly, the capacitor C1 can be provided without a significant increase in the area occupied by the capacitor C1 in a plan view, and thus the semiconductor device of this embodiment can be miniaturized or highly integrated.

### Example of Method for Manufacturing Semiconductor Device

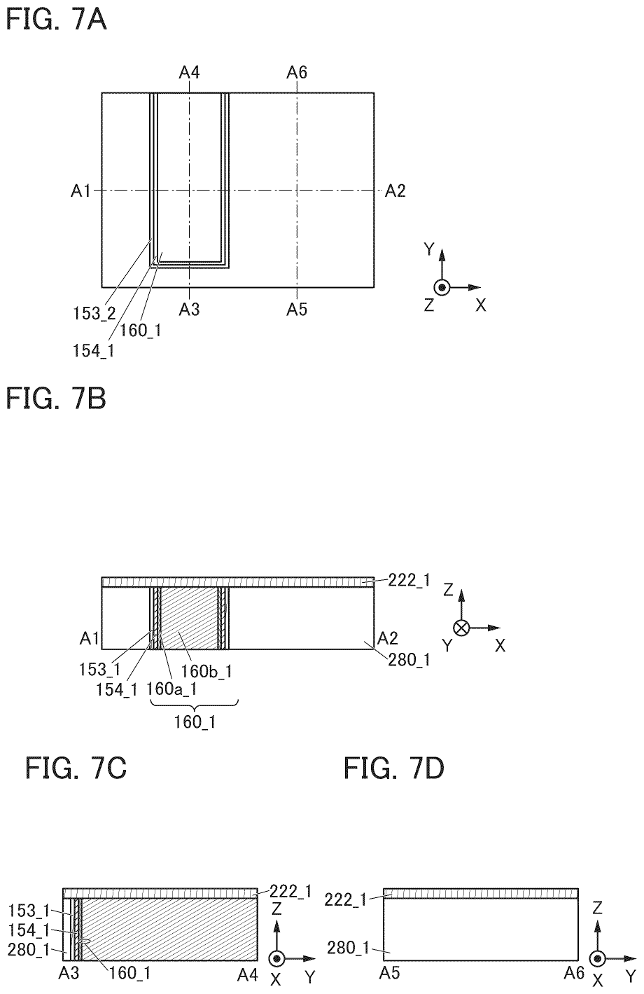

Next, an example of a method for manufacturing the memory layer ALYa of the semiconductor device DEV illustrated in FIG. 6A to FIG. 6D is described. Note that FIG. 7A to FIG. 16D are used for describing the example of the manufacturing method.

In each of FIG. 7A to FIG. 16D, A illustrates a schematic plan view. Moreover, B of each drawing is a schematic cross-sectional view corresponding to a portion along the dashed-dotted line A1-A2 illustrated in A of each drawing, and is also a schematic cross-sectional view of the transistor M1 in the channel length direction. Furthermore, C of each drawing is a schematic cross-sectional view corresponding to a portion along the dashed-dotted line A3-A4 illustrated in A of each drawing, and is also a schematic cross-sectional view of the transistor M1 in the channel width direction. In addition, D of each drawing is a schematic cross-sectional view of a portion along dashed-dotted line A5-A6 in A of each drawing. Note that for clarity of the drawing, some components are not illustrated in the schematic plan view of A of each drawing.

Hereinafter, an insulating material for forming an insulator, a conductive material for forming a conductor, or a semiconductor material for forming a semiconductor can be deposited by a deposition method such as a sputtering method, a CVD (Chemical Vapor Deposition) method, an MBE (Molecular Beam Epitaxy) method, a PLD (Pulsed Laser Deposition) method, or an ALD (Atomic Layer Deposition) method as appropriate.

First, a substrate (not illustrated) is prepared, and the insulator 280_1, the insulator 153_1, the insulator 1541, and the conductor 160_1 are formed above the substrate (see FIG. 7A to FIG. 7D).

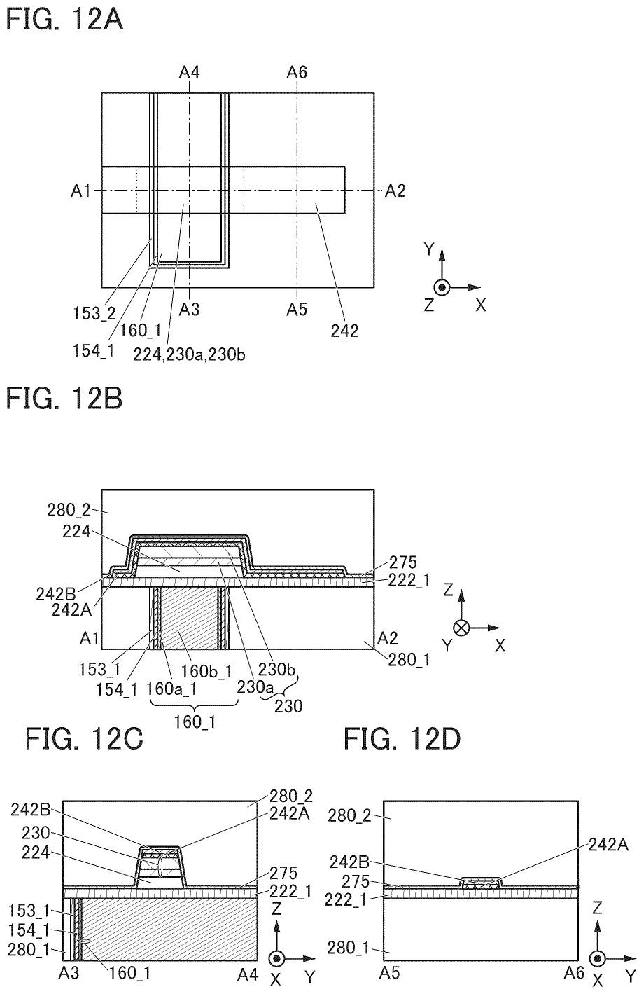

For example, the insulator 280_1 is deposited over the substrate, and then an opening is formed in the insulator 280_1 in a region where the insulator 1531, the insulator 154_1, and the conductor 160_1 are to be formed. After the opening is formed, the insulator 1531, the insulator 154_1, and the conductor 160_1 are sequentially deposited in the opening, and then planarization treatment such as a chemical mechanical polishing (CMP) method is performed to remove part of each of the insulator 1531, the insulator 1541, and the conductor 160_1, so that the insulator 280_1 is exposed. Thus, the insulator 153_1, the insulator 154_1, and the conductor 160_1 can be formed only in the opening formed in the conductor 160_1. Note that for the formation of the insulator 153_1, the insulator 1541, and the conductor 160_1, a method for forming the insulator 153_2, the insulator 154_2, and the conductor 160_2, which is to be described later, can be referred to (see FIG. 12A to FIG. 16D).

Next, the insulator 2221 is deposited over the insulator 280_1, the insulator 153_1, the insulator 154_1, and the conductor 1601 (see FIG. 7A to FIG. 7D). An insulator containing an oxide of one or both of aluminum and hafnium is preferably deposited as the insulator 222_1. Note that as the insulator containing an oxide of one or both of aluminum and hafnium, aluminum oxide, hafnium oxide, an oxide containing aluminum and hafnium (hafnium aluminate), or the like is preferably used. Alternatively, hafnium-zirconium oxide is preferably used. The insulator containing an oxide of one or both of aluminum and hafnium has a barrier property against oxygen, hydrogen, and water. When the insulator 222_1 has a barrier property against hydrogen and water, hydrogen and water contained in components provided around the transistor M1 are inhibited from diffusing into the transistor M1 through the insulator 2221, and generation of oxygen vacancies in the oxide 230 can be inhibited.

The insulator 222_1 can be deposited by a deposition method such as a sputtering method, a CVD method, an MBE method, a PLD method, or an ALD method. In this embodiment, for the insulator 2221, hafnium oxide is deposited by an ALD method. It is particularly preferable to use a method for forming hafnium oxide with a reduced hydrogen concentration.

Note that a high-k material with a high dielectric constant may be used as the insulating material used for the insulator 222_1. Examples of the high-k material with a high dielectric constant include a metal oxide containing one kind or two or more kinds selected from aluminum, gallium, yttrium, zirconium, tungsten, titanium, tantalum, nickel, germanium, and magnesium in addition to the above-described hafnium oxide. Alternatively, aluminum oxide, hafnium oxide, and an oxide containing aluminum and hafnium (hafnium aluminate), which are insulators each containing an oxide of one or both of aluminum and hafnium, may be used for the insulator 222_1. Alternatively, a material that can be used for the insulator 253 or the insulator 254 described later may be used for the insulator 222_1. The insulator 222_1 may have a stacked-layer structure including two or more selected from the above-described materials.

Next, heat treatment is preferably performed. The heat treatment is performed at higher than or equal to 250° C. and lower than or equal to 650° C., preferably higher than or equal to 300° C. and lower than or equal to 500° C., further preferably higher than or equal to 320° C. and lower than or equal to 450° C. Note that the heat treatment is performed in a nitrogen gas or inert gas atmosphere, or an atmosphere containing an oxidizing gas at 10 ppm or more, 1% or more, or 10% or more. For example, in the case where the heat treatment is performed in a mixed atmosphere of a nitrogen gas and an oxygen gas, the proportion of the oxygen gas may be approximately 20%. The heat treatment may be performed under reduced pressure. Alternatively, the heat treatment may be performed in an atmosphere containing an oxidizing gas at 10 ppm or more, 1% or more, or 10% or more in order to compensate for oxygen released, after heat treatment is performed in a nitrogen gas or inert gas atmosphere.

The gas used in the above heat treatment is preferably highly purified. For example, the amount of moisture contained in the gas used in the above heat treatment is 1 ppb or less, preferably 0.1 ppb or less, further preferably 0.05 ppb or less. The heat treatment using a highly purified gas can prevent entry of moisture or the like into the insulator 222_1 and the like as much as possible.

In this embodiment, as the heat treatment, treatment is performed at 400° C. for one hour with a flow rate ratio of a nitrogen gas to an oxygen gas of 4:1 after the deposition of the insulator 222_1. Through the heat treatment, impurities such as water or hydrogen contained in the insulator 222_1 can be removed, for example. In the case where an oxide containing hafnium is used for the insulator 2221, the insulator 222_1 is partly crystallized by the heat treatment in some cases. The heat treatment can also be performed after the deposition of the insulator 224, for example.

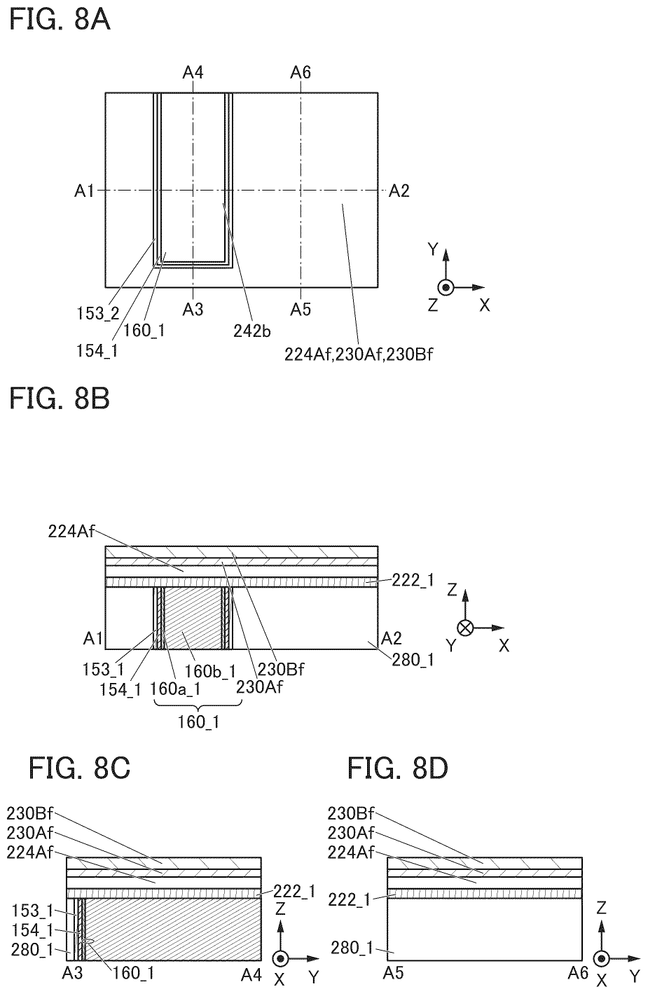

Next, an insulating film 224Af is deposited over the insulator 222_1 (see FIG. 8A to FIG. 8D). The insulating film 224Af can be deposited by a deposition method such as a sputtering method, a CVD method, an MBE method, a PLD method, or an ALD method. In this embodiment, for the insulating film 224Af, silicon oxide is deposited by a sputtering method. By using a sputtering method that does not need to use a molecule containing hydrogen as a deposition gas, the hydrogen concentration in the insulating film 224Af can be reduced. The hydrogen concentration in the insulating film 224Af is preferably reduced in this manner because the insulating film 224Af is in contact with the oxide 230a in a later step.

Other than silicon oxide, an insulating material such as silicon oxynitride may be used for the insulating film 224Af, for example.

Next, an oxide film 230Af and an oxide film 230Bf are deposited in this order over the insulating film 224Af (see FIG. 8A to FIG. 8D). Note that the oxide film 230Af and the oxide film 230Bf are preferably deposited successively without being exposed to an atmospheric environment. Through the deposition without exposure to an atmospheric environment, impurities or moisture from an atmospheric environment can be prevented from being attached onto the oxide film 230Af and the oxide film 230Bf, so that the vicinity of an interface between the oxide film 230Af and the oxide film 230Bf can be kept clean.

The oxide film 230Af and the oxide film 230Bf can be deposited by a sputtering method, a CVD method, an MBE method, a PLD method, an ALD method, or the like. In this embodiment, the oxide film 230Af and the oxide film 230Bf are deposited by a sputtering method.

For example, in the case where the oxide film 230Af and the oxide film 230Bf are deposited by a sputtering method, oxygen or a mixed gas of oxygen and a noble gas is used as a sputtering gas. Increasing the proportion of oxygen contained in the sputtering gas can increase the amount of excess oxygen in the deposited oxide films. In the case where the oxide films are deposited by a sputtering method, the above In-M-Zn oxide target or the like can be used.

In particular, when the oxide film 230Af is deposited, part of oxygen contained in the sputtering gas is supplied to the insulator 224 in some cases. Thus, the proportion of oxygen contained in the sputtering gas is higher than or equal to 70%, preferably higher than or equal to 80%, further preferably 100%.

In the case where the oxide film 230Bf is formed by a sputtering method and the proportion of oxygen contained in the sputtering gas for deposition is higher than 30% and lower than or equal to 100%, preferably higher than or equal to 70% and lower than or equal to 10000, an oxygen-excess oxide semiconductor is formed. In a transistor including an oxygen-excess oxide semiconductor for its channel formation region, relatively high reliability can be obtained. Note that one embodiment of the present invention is not limited thereto. In the case where the oxide film 230Bf is formed by a sputtering method and the proportion of oxygen contained in the sputtering gas for deposition is higher than or equal to 1% and lower than or equal to 30%, preferably higher than or equal to 5% and lower than or equal to 20%, an oxygen-deficient oxide semiconductor is formed. In a transistor including an oxygen-deficient oxide semiconductor for its channel formation region, relatively high field-effect mobility can be obtained. Furthermore, when the deposition is performed while the substrate is being heated, the crystallinity of the oxide film can be improved.

In this embodiment, the oxide film 230Af is deposited by a sputtering method using an oxide target with In:Ga:Zn=1:3:4 [atomic ratio]. The oxide film 230Bf is deposited by a sputtering method using an oxide target with In:Ga:Zn=4:2:4.1 [atomic ratio], an oxide target with In:Ga:Zn=1:1:1 [atomic ratio], an oxide target with In:Ga:Zn=1:1:1.2 [atomic ratio], or an oxide target with In:Ga:Zn=1:1:2 [atomic ratio]. Note that each of the oxide films is preferably formed so as to have characteristics required for the oxide 230a and the oxide 230b by selecting the deposition conditions and the atomic ratios as appropriate.

Note that the insulating film 224Af, the oxide film 230Af, and the oxide film 230Bf are preferably deposited by a sputtering method without exposure to the air. For example, a multi-chamber deposition apparatus may be used. As a result, entry of hydrogen into the insulating film 224Af, the oxide film 230Af, and the oxide film 230Bf in intervals between deposition steps can be inhibited.

Note that the oxide film 230Af and the oxide film 230Bf may be deposited by an ALD method. When the oxide film 230Af and the oxide film 230Bf are deposited by an ALD method, the films with uniform thicknesses can be formed even in a groove or an opening having a high aspect ratio. When a PEALD method is used, the oxide film 230Af and the oxide film 230Bf can be formed at a lower temperature than that in the case of employing a thermal ALD method.

Next, heat treatment is preferably performed. The heat treatment can be performed in a temperature range where the oxide film 230Af and the oxide film 230Bf do not become polycrystals, i.e., at higher than or equal to 250° C. and lower than or equal to 650° C., preferably higher than or equal to 400° C. and lower than or equal to 600° C. Note that the heat treatment is performed in a nitrogen gas or inert gas atmosphere, or an atmosphere containing an oxidizing gas at 10 ppm or more, 1% or more, or 10% or more. For example, in the case where the heat treatment is performed in a mixed atmosphere of a nitrogen gas and an oxygen gas, the proportion of the oxygen gas may be approximately 20%. The heat treatment may be performed under reduced pressure. Alternatively, the heat treatment may be performed in an atmosphere containing an oxidizing gas at 10 ppm or more, 1% or more, or 10% or more in order to compensate for oxygen released, after heat treatment is performed in a nitrogen gas or inert gas atmosphere.

The gas used in the above heat treatment is preferably highly purified. For example, the amount of moisture contained in the gas used in the above heat treatment is 1 ppb or less, preferably 0.1 ppb or less, further preferably 0.05 ppb or less. The heat treatment using a highly purified gas can prevent entry of moisture or the like into the oxide film 230Af and the oxide film 230Bf as much as possible.

In this embodiment, the heat treatment is performed at 400° C. for one hour with a flow rate ratio of a nitrogen gas to an oxygen gas being 4:1. Through such heat treatment using an oxygen gas, an impurity such as carbon, water, or hydrogen in the oxide film 230Af and the oxide film 230Bf can be reduced. Furthermore, the reduction of an impurity in the films improves the crystallinity of the oxide film 230Bf, thereby offering a dense structure with higher density. Thus, crystalline regions in the oxide film 230Af and the oxide film 230Bf are expanded, so that in-plane variations of the crystalline regions in the oxide film 230Af and the oxide film 230Bf can be reduced. Accordingly, an in-plane variation of electrical characteristics of the transistors M1 can be reduced.

By performing the heat treatment, hydrogen in the insulating film 224Af, the oxide film 230Af, and the oxide film 230Bf moves into the insulator 222_1 and is absorbed by the insulator 222_1. In other words, hydrogen in the insulating film 224Af, the oxide film 230Af, and the oxide film 230Bf diffuses into the insulator 222_1. Accordingly, the hydrogen concentration in the insulator 222_1 increases, while the hydrogen concentrations in the insulating film 224Af, the oxide film 230Af, and the oxide film 230Bf decrease.

In particular, the insulating film 224Af functions as a gate insulator of the transistor M1, and the oxide film 230Af and the oxide film 230Bf function as a channel formation region of the transistor M1. Thus, the transistor M1 preferably includes the insulating film 224Af, the oxide film 230Af, and the oxide film 230Bf with reduced hydrogen concentrations because favorable reliability can be obtained.

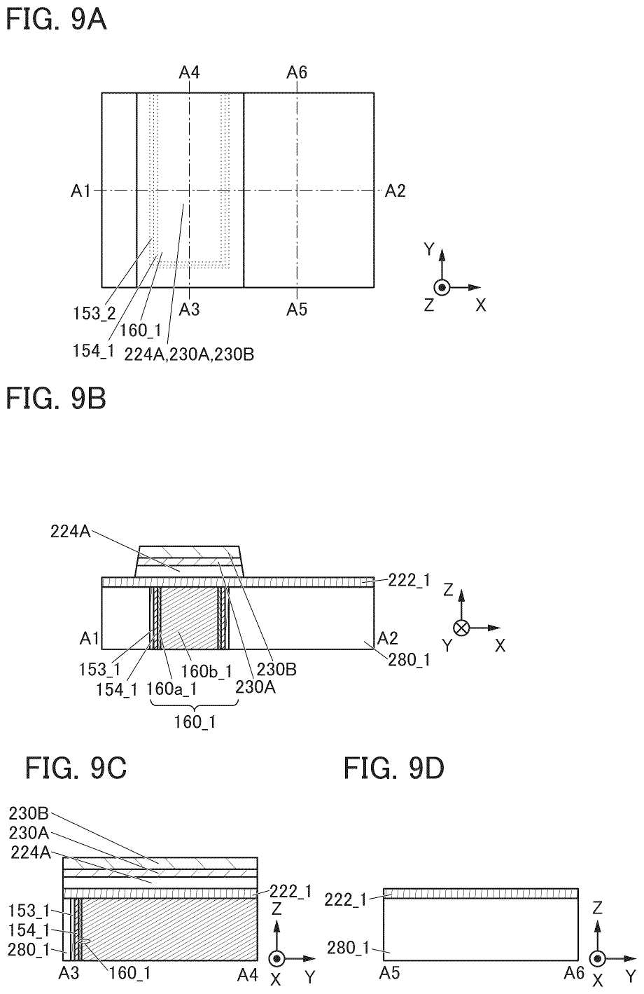

Next, the insulating film 224Af, the oxide film 230Af, and the oxide film 230Bf are processed into a band-like shape by a lithography method to form an insulating layer 224A, an oxide layer 230A, and an oxide layer 230B (see FIG. 9A to FIG. 9D). Here, the insulating layer 224A, the oxide layer 230A, and the oxide layer 230B are formed to extend in a direction parallel to the dashed-dotted line A3-A4 (the channel width direction of the transistor M1 or the Y direction illustrated in FIG. 6A). The insulating layer 224A, the oxide layer 230A, and the oxide layer 230B are formed to at least partly overlap with the conductor 160_1. A dry etching method or a wet etching method can be used for the processing. Processing by a dry etching method is suitable for microfabrication. The insulating film 224Af, the oxide film 230Af, and the oxide film 230Bf may be processed under different conditions.

Note that in the lithography method, first, a resist is exposed to light through a mask. Next, a region exposed to light is removed or left using a developing solution, so that a resist mask is formed. Then, etching treatment through the resist mask is conducted, whereby a conductor, a semiconductor, an insulator, or the like can be processed into a desired shape. The resist mask may be formed through, for example, exposure of the resist to KrF excimer laser light, ArF excimer laser light, EUV (Extreme Ultraviolet) light, or the like. A liquid immersion technique may be employed in which a gap between a substrate and a projection lens is filled with a liquid (e.g., water) in light exposure. An electron beam or an ion beam may be used instead of the light. Note that a mask is unnecessary in the case of using an electron beam or an ion beam. Note that the resist mask can be removed by dry etching treatment such as ashing, wet etching treatment, wet etching treatment after dry etching treatment, or dry etching treatment after wet etching treatment.

In addition, a hard mask formed of an insulator or a conductor may be used under the resist mask. In the case where a hard mask is used, a hard mask with a desired shape can be formed in the following manner: an insulating film or a conductive film that is a hard mask material is formed over the oxide film 230Bf, a resist mask is formed thereover, and then the hard mask material is etched. The etching of the oxide film 230Bf and the like may be performed after removing the resist mask or with the resist mask remaining. In the latter case, the resist mask sometimes disappears during the etching. The hard mask may be removed by etching after the etching of the oxide film 230Bf and the like. Meanwhile, the hard mask is not necessarily removed when the hard mask material does not affect later steps or can be utilized in later steps.

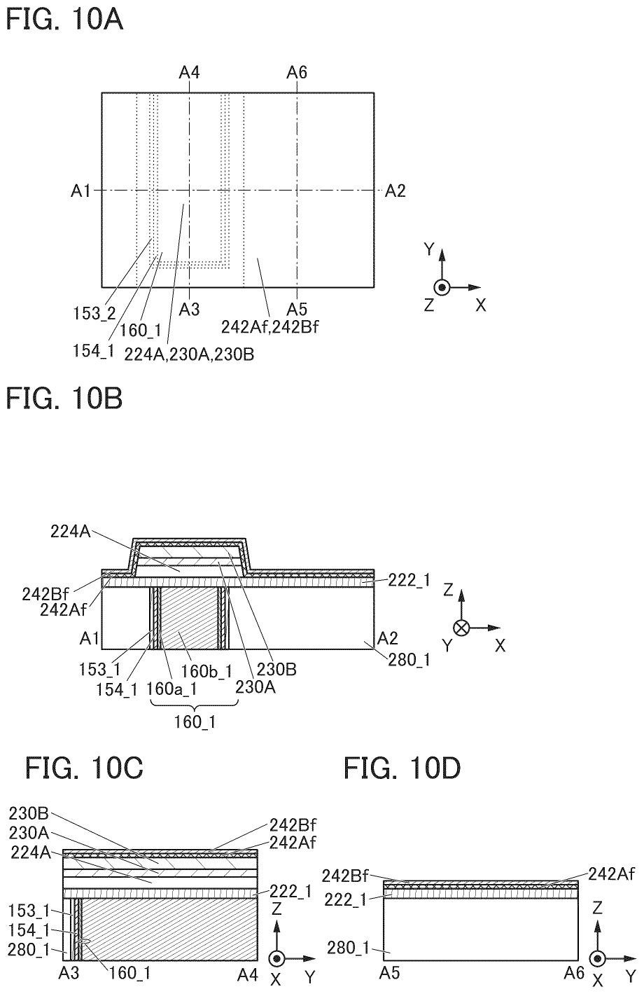

Next, a conductive film 242Af and a conductive film 242Bf are deposited in this order over the insulator 222_1 and the oxide layer 230B (see FIG. 10A to FIG. 10D). The conductive film 242Af and the conductive film 242Bf can be deposited by a deposition method such as a sputtering method, a CVD method, an MBE method, a PLD method, or an ALD method. For example, tantalum nitride is deposited as the conductive film 242Af by a sputtering method and tungsten is deposited as the conductive film 242Bf. Note that heat treatment may be performed before the deposition of the conductive film 242Af. This heat treatment may be performed under reduced pressure, and the conductive film 242Af may be successively deposited without exposure to the air. Such treatment can remove moisture and hydrogen adsorbed onto the surface of the oxide layer 230B, and further can reduce the moisture concentration and the hydrogen concentration in the oxide layer 230A and the oxide layer 230B. The heat treatment is preferably performed at a temperature higher than or equal to 100° C. and lower than or equal to 400° C. In this embodiment, the heat treatment is performed at 200° C.

Note that for the conductive film 242Af, a conductive material such as a nitride containing tantalum, a nitride containing titanium, a nitride containing molybdenum, a nitride containing tungsten, a nitride containing tantalum and aluminum, or a nitride containing titanium and aluminum may be used other than tantalum nitride, for example. For another example, a conductive material such as ruthenium oxide, ruthenium nitride, an oxide containing strontium and ruthenium, or an oxide containing lanthanum and nickel may be used. These materials are preferable because they are each a conductive material that is not easily oxidized or a material that maintains the conductivity even after absorbing oxygen.

For the conductive film 242Bf, other than tungsten, a conductive material, e.g., a metal element selected from aluminum, chromium, copper, silver, gold, platinum, tantalum, nickel, titanium, molybdenum, tungsten, hafnium, vanadium, niobium, manganese, magnesium, zirconium, beryllium, indium, ruthenium, iridium, strontium, and lanthanum; an alloy containing any of the above metal elements; an alloy containing a combination of the above metal elements; or the like, may be used. For example, a conductive material such as titanium nitride, tungsten, a nitride containing titanium and aluminum, a nitride containing tantalum and aluminum, ruthenium oxide, ruthenium nitride, an oxide containing strontium and ruthenium, or an oxide containing lanthanum and nickel may be used. Tantalum nitride, titanium nitride, a nitride containing titanium and aluminum, a nitride containing tantalum and aluminum, ruthenium oxide, ruthenium nitride, an oxide containing strontium and ruthenium, and an oxide containing lanthanum and nickel are preferable because they are oxidation-resistant conductive materials or materials that maintain their conductivity even after absorbing oxygen.

Materials that can be used for both the conductive film 242Af and the conductive film 242Bf may be used for the conductive film 242Af and the conductive film 242Bf. Alternatively, the same material may be used for the conductive film 242Af and the conductive film 242Bf. That is, the conductor 242al and the conductor 242a2 may be one conductor in the memory cell MC. Similarly, the conductor 242b1 and the conductor 242b2 may be one conductor.

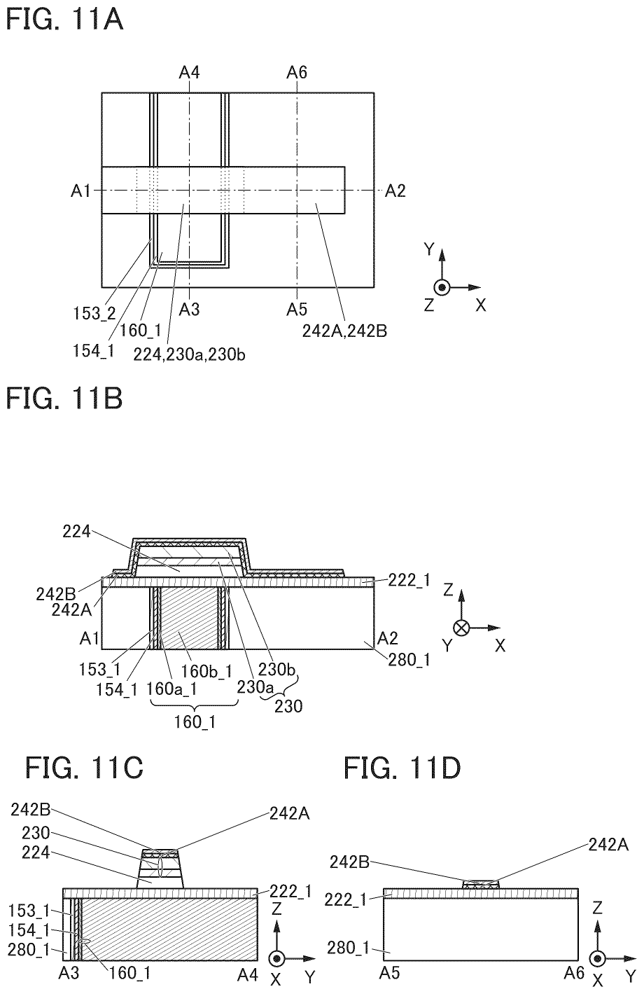

Next, the insulating layer 224A, the oxide layer 230A, the oxide layer 230B, the conductive film 242Af, and the conductive film 242Bf are processed by a lithography method to form the insulator 224, the oxide 230a, and the oxide 230b that have an island shape and a conductive layer 242A and a conductive layer 242B that have an island shape and include an opening (see FIG. 11A to FIG. 11D). For example, the insulating layer 224A, the oxide layer 230A, the oxide layer 230B, the conductive film 242Af, and the conductive film 242Bf are processed to form the insulator 224, the oxide 230a, and the oxide 230b that have an island shape; the conductive layer 242A and the conductive layer 242B that extend in a direction parallel to the dashed-dotted line A1-A2 (the channel length direction of the transistor M1 or the X direction illustrated in FIG. 6A); and then, the conductive layer 242A and the conductive layer 242B are processed to form the conductive layer 242A and the conductive layer 242B which have an opening. Alternatively, for example, the insulating layer 224A, the oxide layer 230A, the oxide layer 230B, the conductive film 242Af, and the conductive film 242Bf may be processed into an island shape to form the insulator 224, the oxide 230a, the oxide 230b, the conductive layer 242A, and the conductive layer 242B, and then an opening may be formed in the conductive layer 242A and the conductive layer 242B.

Here, the insulator 224, the oxide 230a, the oxide 230b, the conductive layer 242A, and the conductive layer 242B are formed to at least partly overlap with the conductor 160_1. The opening provided in the conductive layer 242A and the conductive layer 242B is formed in a position not overlapping with the oxide 230b. A dry etching method or a wet etching method can be used for the processing. Processing by a dry etching method is suitable for microfabrication. The insulating layer 224A, the oxide layer 230A, the oxide layer 230B, the conductive film 242Af, and the conductive film 242Bf may be processed under different conditions.

Furthermore, as illustrated in FIG. 11B to FIG. 11D, the side surfaces of the insulator 224, the oxide 230a, the oxide 230b, the conductive layer 242A, and the conductive layer 242B may have tapered shapes. Each of the insulator 224, the oxide 230a, the oxide 230b, the conductive layer 242A, and the conductive layer 242B may have a taper angle greater than or equal to 60° and less than 90°. With such tapered shapes of the side surfaces, the coverage with the insulator 275 and the like can be improved in a later step, so that defects such as a void can be reduced.

Not being limited to the above, the side surfaces of the insulator 224, the oxide 230a, the oxide 230b, the conductive layer 242A, and the conductive layer 242B may substantially perpendicular to the top surface of the insulator 222_1. With such a structure, a plurality of transistors M1 can be provided with high density in a small area.

A by-product generated in the above etching process is sometimes formed in a layered manner on the side surfaces of the insulator 224, the oxide 230a, the oxide 230b, the conductive layer 242A, and the conductive layer 242B. In that case, the layered by-product is formed between the insulator 275 and the insulator 224, the oxide 230a, the oxide 230b, the conductive layer 242A, and the conductive layer 242B. Hence, the layered by-product formed in contact with the top surface of the insulator 222_1 is preferably removed.

Next, the insulator 275 is deposited to cover the insulator 224, the oxide 230a, the oxide 230b, the conductive layer 242A, and the conductive layer 242B (see FIG. 12A to FIG. 12D). Here, it is preferable that the insulator 275 be in contact with the top surface of the insulator 222_1 and the side surface of the insulator 224. The insulator 275 can be deposited by a deposition method such as a sputtering method, a CVD method, an MBE method, a PLD method, or an ALD method. The insulator 275 is preferably formed using an insulating film having a function of inhibiting passage of oxygen. For example, silicon nitride may be deposited as the insulator 275 by an ALD method. Alternatively, as the insulator 275, aluminum oxide may be deposited by a sputtering method, and silicon nitride may be deposited thereover by a PEALD method. When the insulator 275 has such a stacked-layer structure, the function of inhibiting diffusion of impurities such as water or hydrogen and oxygen is improved in some cases.

In that manner, the oxide 230a, the oxide 230b, the conductive layer 242A, and the conductive layer 242B can be covered with the insulator 275, which has a function of inhibiting diffusion of oxygen. This can reduce direct diffusion of oxygen from the insulator 280_2 or the like formed later into the insulator 224, the oxide 230a, the oxide 230b, the conductive layer 242A, and the conductive layer 242B in a later process.

Next, an insulating film to be the insulator 280_2 is deposited over the insulator 275. The insulating film can be deposited by a deposition method such as a sputtering method, a CVD method, an MBE method, a PLD method, or an ALD method. A silicon oxide film may be deposited by a sputtering method as the insulating film, for example. When the insulating film is deposited by a sputtering method in an oxygen-containing atmosphere, the insulator 280_2 containing excess oxygen can be formed. By using a sputtering method that does not need to use a molecule containing hydrogen as a deposition gas, the hydrogen concentration in the insulator 280_2 can be reduced. Note that heat treatment may be performed before the deposition of the insulating film. The heat treatment may be performed under reduced pressure, and the insulating film may be successively deposited without exposure to the air. Such treatment can remove moisture and hydrogen adsorbed onto the surface of the insulator 275 and the like, and further can reduce the moisture concentration and the hydrogen concentration in the oxide 230a, the oxide 230b, and the insulator 224. For the heat treatment, the above heat treatment conditions can be used.

For the insulating film to be the insulator 280_2, a material with a low permittivity is preferably used. Specific examples of the material with a low permittivity include silicon oxide and silicon oxynitride. Other examples of the material with a low permittivity include silicon oxide to which fluorine is added, silicon oxide to which carbon is added, silicon oxide to which carbon and nitrogen are added, and porous silicon oxide.

Silicon nitride oxide or silicon nitride may be used for the insulating film to be the insulator 280_2.

Note that in this specification and the like, oxynitride refers to a material that contains more oxygen than nitrogen in its composition, and nitride oxide refers to a material that contains more nitrogen than oxygen in its composition. For example, silicon oxynitride refers to a material that contains more oxygen than nitrogen in its composition, and silicon nitride oxide refers to a material that contains more nitrogen than oxygen in its composition.

Next, the insulating film to be the insulator 280_2 is subjected to planarization treatment such as a CMP method, so that the insulator 280_2 with a flat top surface is formed (see FIG. 12A to FIG. 12D). Note that, for example, silicon nitride may be deposited over the insulator 280_2 by a sputtering method and CMP treatment may be performed on the silicon nitride until the insulator 280_2 is reached.

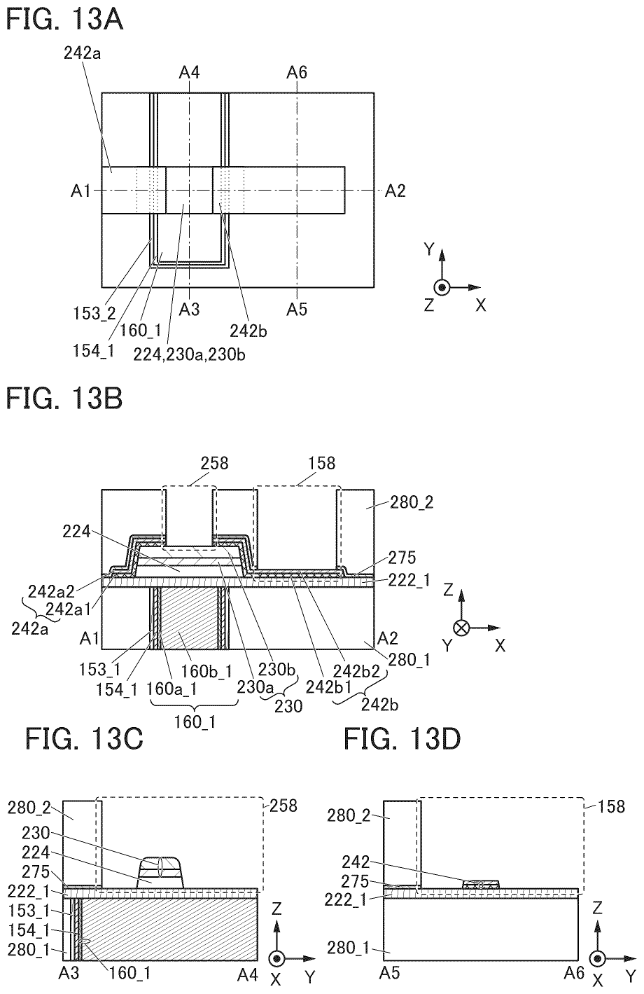

Next, in a region where the conductor 160_1 and the oxide 230 overlap with each other, part of the insulator 280_2, part of the insulator 275, part of the conductive layer 242A, and part of the conductive layer 242B are processed to form the opening 258 reaching the oxide 230b. By the formation of the opening 258, the conductor 242al and the conductor 242b1 can be formed from the conductive layer 242A, and the conductor 242a2 and the conductor 242b2 can be formed from the conductive layer 242B (see FIG. 13A to FIG. 13D).

The part of the insulator 280_2, the part of the insulator 275, and the part of the conductive layer 242B can be processed by a dry etching method or a wet etching method. Processing by a dry etching method is suitable for microfabrication. The processing may be performed under different conditions. For example, the part of the insulator 280_2 may be processed by a dry etching method, the part of the insulator 275 may be processed by a wet etching method, and the part of the conductive layer 242B may be processed by a dry etching method.

As illustrated in FIG. 13A and FIG. 13C, the opening 258 is preferably formed to extend in a direction parallel to the dashed-dotted line A3-A4 (the channel width direction of the transistor or the Y direction illustrated in FIG. 6A and FIG. 6C). By forming the opening 258 in that manner, the conductor 260 to be formed later can be provided to extend in the above-described direction, so that the conductor 260 can function as a wiring. The opening 258 is preferably formed to overlap with the conductor 160_1.

The width of the opening 258 is preferably small because the channel length of the transistor M1 reflects the width. For example, the width of the opening 258 is preferably greater than or equal to 1 nm or greater than or equal to 5 nm and less than or equal to 60 nm, less than or equal to 50 nm, less than or equal to 40 nm, less than or equal to 30 nm, less than or equal to 20 nm, or less than or equal to 10 nm. In order to process the opening 258 minutely, a lithography method using an electron beam or short-wavelength light such as EUV light is preferably used.

In the case where the opening 258 is processed minutely, the part of the insulator 280_2, the part of the insulator 275, the part of the conductive layer 242B, and the part of the conductive layer 242A are preferably processed by anisotropic etching. Processing by a dry etching method is particularly preferable because it is suitable for microfabrication. The processing may be performed under different conditions.

When the insulator 280_2, the insulator 275, the conductive layer 242B, and the conductive layer 242A are processed by anisotropic etching, side surfaces of the conductor 242a and the conductor 242b that face each other can be formed to be substantially perpendicular to the top surface of the oxide 230b. Such a structure can inhibit formation of what is called an Loff region in a region of the oxide 230 in the vicinity of an end portion of the conductor 242a and a region of the oxide 230 in the vicinity of an end portion of the conductor 242b. Accordingly, the frequency characteristics of the transistor M1 can be improved, and the operation speed of the semiconductor device of one embodiment of the present invention can be improved.

However, without limitation to the above, the side surfaces of the insulator 280_2, the insulator 275, and the conductor 242 (the conductor 242a and the conductor 242b) have tapered shapes in some cases. The taper angle of the insulator 280_2 is larger than that of the conductor 242 in some cases. An upper portion of the oxide 230b is sometimes removed when the opening 258 is formed.

By the etching process, impurities may be attached onto the side surface of the oxide 230a, the top surface and the side surface of the oxide 230b, the side surface of the conductor 242, the side surface of the insulator 280_2, and the like; alternatively, the impurities may be diffused thereinto. A process of removing such impurities may be performed. In addition, a damaged region might be formed on the surface of the oxide 230b by the above dry etching. Such a damaged region may be removed. The impurities result from components contained in the insulator 280_2, the insulator 275, the conductive layer 242B, and the conductive layer 242A; components contained in a member of an apparatus used to form the opening; and components contained in a gas or a liquid used for etching, for instance. Examples of the impurities include hafnium, aluminum, silicon, tantalum, fluorine, and chlorine.

In particular, impurities such as aluminum and silicon might reduce the crystallinity of the oxide 230b. Thus, it is preferable that impurities such as aluminum and silicon be removed from the surface of the oxide 230b and the vicinity thereof. The concentration of the impurities is preferably reduced. For example, the concentration of aluminum atoms at the surface of the oxide 230b and the vicinity thereof is lower than or equal to 5.0 atomic %, preferably lower than or equal to 2.0 atomic %, further preferably lower than or equal to 1.5 atomic %, still further preferably lower than or equal to 1.0 atomic %, and yet further preferably lower than 0.3 atomic %.

Note that the density of the crystal structure is reduced in the low-crystallinity region of the oxide 230b owing to impurities such as aluminum and silicon; thus, a large amount of V_{O}H (V_{O} refers to oxygen vacancies and V_{O}H refers to defects generated by entry of hydrogen into V_{O}) is formed, and the transistor tends to be normally on (in a state where a channel is present when a voltage of 0 V is applied between the gate and the source and current flows through the transistor). Hence, the low-crystallinity region of the oxide 230b is preferably reduced or removed.

In contrast, the oxide 230b preferably has a layered CAAC structure. In particular, the CAAC structure preferably reaches a lower end portion of a drain in the oxide 230b. Here, in the transistor M1, the conductor 242a or the conductor 242b, and its vicinity function as a drain. In other words, the oxide 230b in the vicinity of the lower end portion of the conductor 242a (conductor 242b) preferably has a CAAC structure. In that manner, the low-crystallinity region of the oxide 230b is removed and the CAAC structure is formed also in the end portion of the drain, which significantly affects the drain withstand voltage, so that a variation in electrical characteristics of the transistors M1 can be further suppressed. In addition, the reliability of the transistor M1 can be improved.

In order to remove impurities and the like attached to the surface of the oxide 230b in the above etching process, cleaning treatment is performed. Examples of the cleaning method include wet cleaning using a cleaning solution or the like (which can also be referred to as wet etching treatment), plasma treatment using plasma, and cleaning by heat treatment, and any of these cleanings may be performed in appropriate combination. Note that the cleaning treatment sometimes makes the groove portion deeper.

In the wet cleaning, an aqueous solution in which one or more selected from ammonia water, oxalic acid, phosphoric acid, and hydrofluoric acid are diluted with carbonated water or pure water can be used. Alternatively, the wet cleaning may be performed using pure water or carbonated water. Alternatively, ultrasonic cleaning using such an aqueous solution, pure water, or carbonated water may be performed. Alternatively, such cleaning methods may be performed in combination as appropriate.

Note that in this specification and the like, in some cases, an aqueous solution in which hydrofluoric acid is diluted with pure water is referred to as diluted hydrofluoric acid, and an aqueous solution in which ammonia water is diluted with pure water is referred to as diluted ammonia water. The concentration, temperature, and the like of the aqueous solution may be adjusted as appropriate in accordance with an impurity to be removed, the structure of a semiconductor device to be cleaned, or the like. The concentration of ammonia in the diluted ammonia water is higher than or equal to 0.01% and lower than or equal to 5%, preferably higher than or equal to 0.1% and lower than or equal to 0.5%. The concentration of hydrogen fluoride in the diluted hydrofluoric acid is higher than or equal to 0.01 ppm and lower than or equal to 100 ppm, preferably higher than or equal to 0.1 ppm and lower than or equal to 10 ppm.

For the ultrasonic cleaning, a frequency higher than or equal to 200 kHz is preferable, and a frequency higher than or equal to 900 kHz is further preferable. Damage to the oxide 230b and the like can be reduced with this frequency.

The cleaning treatment may be performed a plurality of times, and the cleaning solution may be changed in every cleaning treatment. For example, the first cleaning treatment may use diluted hydrofluoric acid or diluted ammonia water, and the second cleaning treatment may use pure water or carbonated water.

As the cleaning treatment in this embodiment, wet cleaning using diluted ammonia water is performed. The cleaning treatment can remove impurities that are attached onto the surfaces of the oxide 230a, the oxide 230b, and the like or diffused into the oxide 230a, the oxide 230b, and the like. Furthermore, the crystallinity of the oxide 230b can be increased.

After the etching or the cleaning treatment, heat treatment may be performed. The heat treatment is performed at higher than or equal to 100° C. and lower than or equal to 450° C., preferably higher than or equal to 350° C. and lower than or equal to 400° C. Note that the heat treatment is performed in a nitrogen gas or inert gas atmosphere, or an atmosphere containing an oxidizing gas at 10 ppm or more, 1% or more, or 10% or more. For example, the heat treatment is preferably performed in an oxygen atmosphere. Accordingly, oxygen can be supplied to the oxide 230a and the oxide 230b to reduce oxygen vacancies. In addition, the crystallinity of the oxide 230b can be improved by such heat treatment. The heat treatment may be performed under reduced pressure. Alternatively, the heat treatment may be performed in an oxygen atmosphere, and then another heat treatment may be successively performed in a nitrogen atmosphere without exposure to the air.

Next, in a region where the conductive layer 242A, the conductive layer 242B, and the insulator 222_1 overlap with each other and the conductor 160_1 and the oxide 230 do not overlap with each other, part of the insulator 280_2 and part of the insulator 275 are processed, whereby the opening 158 reaching the conductive layer 242B (the conductor 242b2) is formed (see FIG. 13A to FIG. 13D).

The opening 158 can be formed by a dry etching method or a wet etching method as in the formation of the opening 258. For example, the part of the insulator 280_2 may be processed by a dry etching method, and the part of the insulator 275 may be processed by a wet etching method.

As illustrated in FIG. 13A and FIG. 13D, the opening 158 is preferably formed to extend in a direction parallel to the dashed-dotted line A5-A6 (the channel width direction of the transistor or the Y direction illustrated in FIG. 6A and FIG. 13D). By forming the opening 158 in that manner, the conductor 160_2 to be formed later can be provided to extend in the above-described direction, so that the conductor 160_2 can function as a wiring.

Note that the opening 158 and the opening 258 may be formed at a time; alternatively, one of the opening 158 and the opening 258 may be formed first and then the other may be formed. Note that the opening 258 is preferably formed so that the oxide 230b is exposed at the bottom portion of the opening 258, and the opening 158 is preferably formed so that the conductor 242b2 is exposed at the bottom portion of the opening 158. Therefore, the opening 158 and the opening 258 are preferably formed by processing methods under different conditions.

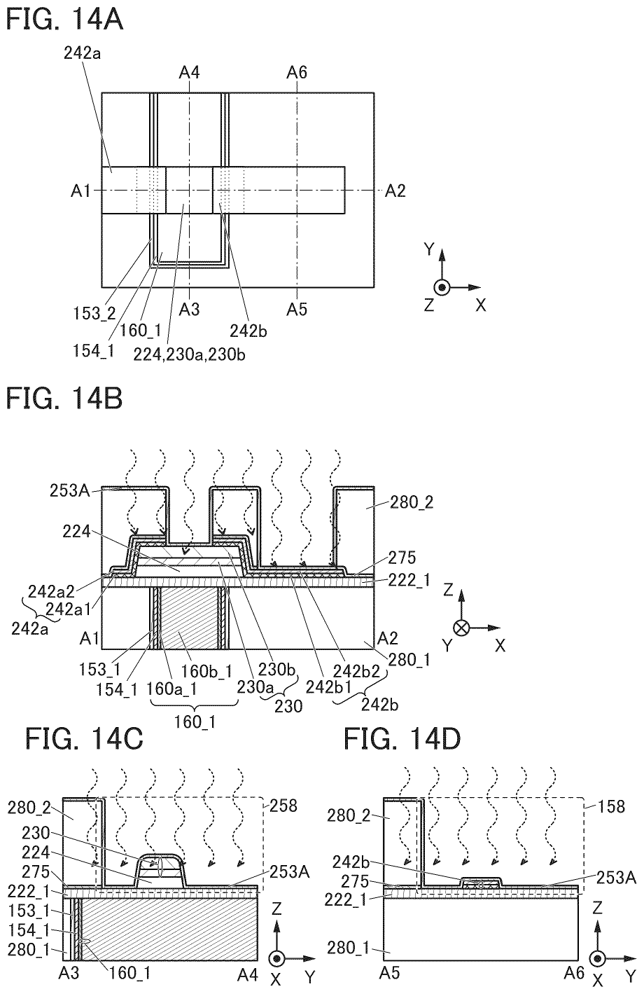

Next, an insulating film 253A is deposited (see FIG. 14A to FIG. 14D). The insulating film 253A is an insulating film to be the insulator 253 and the insulator 153_2 in a later process. The insulating film 253A can be deposited by a deposition method such as a sputtering method, a CVD method, an MBE method, a PLD method, or an ALD method. The insulating film 253A is preferably deposited by an ALD method. As described above, it is preferable to deposit the insulating film 253A to have a small thickness, and an unevenness of the thickness needs to be reduced. Since an ALD method is a deposition method in which a precursor and a reactant (e.g., oxidizer) are alternately introduced and the film thickness can be adjusted with the number of repetition times of the cycle, accurate control of the film thickness is possible. Furthermore, as illustrated in FIG. 14B and FIG. 14C, the insulating film 253A needs to be deposited on the bottom surface and the side surfaces of each of the opening 258 and the opening 158 with good coverage. In the opening 258, it is preferable that the insulating film 253A be deposited on the top surface and the side surface of the oxide 230 with good coverage. In addition, in the opening 158, it is preferable that the insulating film 253A be deposited on the side surface and the top surface of the conductor 242b with good coverage. By an ALD method, atomic layers can be deposited one by one on the bottom surface and the side surface of each of the opening 258 and the opening 158, whereby the insulating film 253A can be deposited in each of the openings with good coverage.

When the insulating film 253A is deposited by an ALD method, ozone (O₃), oxygen (O₂), water (H₂O), or the like can be used as the oxidizer. When an oxidizer without containing hydrogen, such as ozone (O₃) or oxygen (O₂), is used, the amount of hydrogen diffusing into the oxide 230b can be reduced.

In this embodiment, hafnium oxide is deposited as the insulating film 253A by a thermal ALD method.

Alternatively, a high-k material with a high dielectric constant may be used as an insulating material used for the insulating film 253A. Examples of the high-k material with a high dielectric constant include a metal oxide containing one kind or two or more kinds selected from aluminum, gallium, yttrium, zirconium, tungsten, titanium, tantalum, nickel, germanium, and magnesium in addition to the above-described hafnium oxide. Alternatively, any of aluminum oxide, hafnium oxide, and an oxide containing aluminum and hafnium (hafnium aluminate), which are insulators each contain an oxide of one or both of aluminum and hafnium, may be used for the insulating film 253A.

In addition, an insulating material such as silicon oxide, silicon oxynitride, or silicon nitride oxide can be used for the insulating film 253A. Alternatively, an insulating material such as silicon oxide to which fluorine is added or silicon oxide to which carbon is added can be used for the insulating film 253A. Alternatively, silicon oxide to which carbon and nitrogen are added can be used for the insulating film 253A. Alternatively, porous silicon oxide can be used for the insulating film 253A. In particular, silicon oxide and silicon oxynitride, which are thermally stable, are preferable. Alternatively, the insulating film 253A may have a stacked-layer structure including two or more selected from the above-described materials.

Next, it is preferable to perform microwave treatment in an atmosphere containing oxygen (see FIG. 14A to FIG. 14D). Here, the microwave treatment refers to, for example, treatment using an apparatus including a power source that generates high-density plasma with the use of a microwave. In this specification and the like, a microwave refers to an electromagnetic wave having a frequency greater than or equal to 300 MHz and less than or equal to 300 GHz. Note that in the case where the insulating film 253A has a stacked-layer structure, the microwave treatment may be performed at the time when part of the insulating film 253A is deposited. For example, in the case where the insulating film 253A includes a silicon oxide film or a silicon oxynitride film, the microwave treatment may be performed at the time when the silicon oxide film or the silicon oxynitride film is deposited.

Here, dotted-line arrows in FIG. 14B to FIG. 14D indicate high-frequency waves such as microwaves or RF, oxygen plasma, oxygen radicals, or the like. The microwave treatment is preferably performed with a microwave treatment apparatus including a power source for generating high-density plasma using microwaves, for example. Here, the frequency of the microwave treatment apparatus is set to greater than or equal to 300 MHz and less than or equal to 300 GHz, preferably greater than or equal to 2.4 GHz and less than or equal to 2.5 GHz, for example, 2.45 GHz. Oxygen radicals at a high density can be generated with high-density plasma.

The electric power of the power source that applies microwaves of the microwave treatment apparatus is set to higher than or equal to 1000 W and lower than or equal to 10000 W, preferably higher than or equal to 2000 W and lower than or equal to 5000 W. The microwave treatment apparatus may be provided with a power source that applies RF to the substrate side. Furthermore, application of RF to the substrate side allows oxygen ions generated by the high-density plasma to be introduced into the oxide 230b efficiently. By the effect of the plasma, the microwave, or the like, V_{O}H included in the region of the oxide 230 that does not overlap with the conductor 242a or the conductor 242b can be divided and hydrogen can be removed from the region. That is, V_{O}H contained in the region can be reduced. As a result, oxygen vacancies and V_{O}H in the region can be reduced to lower the carrier concentration. In addition, oxygen radicals generated by the oxygen plasma can be supplied to oxygen vacancies formed in the region, thereby further reducing oxygen vacancies in the region and lowering the carrier concentration.

As illustrated in FIG. 14B to FIG. 14D, the conductor 242a and the conductor 242b block the effect of high-frequency waves such as microwaves or RF, oxygen plasma, or the like, and thus such an effect does not take on the region of the oxide 230b overlapping with the conductor 242a or the conductor 242b. Hence, a reduction in V_{O}H and supply of an excess amount of oxygen do not occur in the region in the microwave treatment, preventing a decrease in carrier concentration.

The insulator 253 having a barrier property against oxygen is provided in contact with the side surfaces of the conductor 242a and the conductor 242b. This can inhibit formation of oxide films on the side surfaces of the conductor 242a and conductor 242b by the microwave treatment.

Furthermore, the film quality of the insulator 253 can be improved, leading to higher reliability of the transistor M1.

In the above manner, oxygen vacancies and V_{O}H can be selectively removed from the region of the oxide 230 not overlapping with the conductor 242a or the conductor 242b, whereby the region can be an i-type or substantially i-type region. Furthermore, supply of excess oxygen to regions of the oxide 230 overlapping with the conductor 242a and the conductor 242b functioning as the source region and the drain region can be inhibited and the conductivity can be maintained. As a result, a change in the electrical characteristics of the transistor M1 can be inhibited, and thus a variation in the electrical characteristics of the transistors M1 in the substrate plane can be inhibited.

In the microwave treatment, thermal energy is directly transmitted to the oxide 230b in some cases owing to an electromagnetic interaction between the microwave and a molecule in the oxide 230b. The oxide 230b may be heated by this thermal energy. Such heat treatment is sometimes referred to as microwave annealing. When microwave treatment is performed in an atmosphere containing oxygen, an effect equivalent to that of oxygen annealing is sometimes obtained. In the case where hydrogen is contained in the oxide 230b, the thermal energy may be transmitted to the hydrogen in the oxide 230b and the hydrogen activated by the energy may be released from the oxide 230b.

Note that microwave treatment may be performed before the deposition of the insulating film 253A, without the microwave treatment performed after the deposition of the insulating film 253A.

After the microwave treatment after the deposition of the insulating film 253A, heat treatment may be performed with a reduced pressure being maintained. Such treatment enables hydrogen in the insulating film 253A, the oxide 230b, and the oxide 230a to be removed efficiently. Part of hydrogen is gettered by the conductor 242 (the conductor 242a and the conductor 242b) in some cases. Alternatively, the step of performing microwave treatment and then performing heat treatment with the reduced pressure being maintained may be repeated a plurality of cycles. The repetition of the heat treatment enables hydrogen in the insulating film 253A, the oxide 230b, and the oxide 230a to be removed more efficiently. Note that the temperature of the heat treatment is preferably higher than or equal to 300° C. and lower than or equal to 500° C. The microwave treatment, i.e., the microwave annealing may also serve as the heat treatment. The heat treatment is not necessarily performed in the case where the oxide 230b and the like are adequately heated by the microwave annealing.

Furthermore, the microwave treatment improves the film quality of the insulating film 253A, thereby inhibiting diffusion of impurities such an hydrogen or water. Accordingly, impurities such as hydrogen or water can be inhibited from diffusing into the oxide 230b, the oxide 230a, and the like through the insulator 253 in a later process such as deposition of a conductive film to be the conductor 260 or later treatment such as heat treatment.

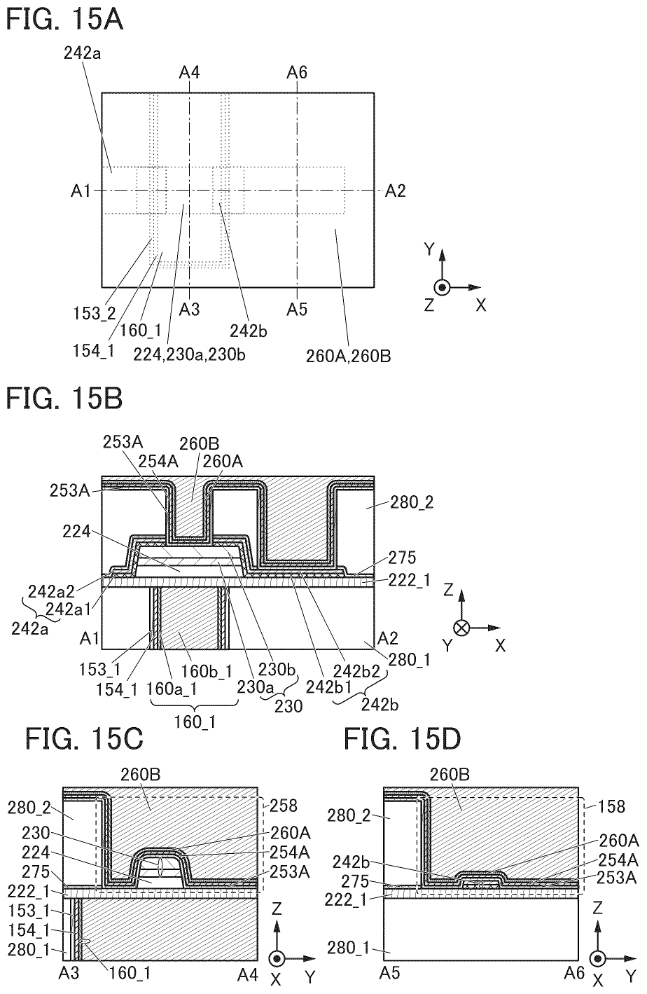

Next, an insulating film 254A to be the insulator 254 and the insulator 154_2 is deposited (see FIG. 15A to FIG. 15D). The insulating film 254A can be deposited by a deposition method such as a sputtering method, a CVD method, an MBE method, a PLD method, or an ALD method. Like the insulating film 253A, the insulating film 254A is preferably deposited by an ALD method. By an ALD method, the insulating film 254A can be deposited to have a small thickness and good coverage. In this embodiment, for the insulating film 254A, silicon nitride is deposited by a PEALD method.

Note that an insulating material that can be used for the insulating film 253A may be used for the insulating film 254A.

The same material as the insulating film 253A may be used for the insulating film 254A. That is, in the memory cell MC, the insulator 253 and the insulator 254 may be one insulator. Similarly, the insulator 153_1 and the insulator 1541 may be one insulator, and the insulator 153_2 and the insulator 154_2 may be one insulator.

Next, a conductive film 260A to be the conductor 260a and the conductor 160a_2 and a conductive film 260B to be the conductor 260b and the conductor 160b_2 are deposited in this order (see FIG. 15A to FIG. 15D). The conductive film to be the conductor 260a and the conductive film to be the conductor 260b can be formed by a deposition method such as a sputtering method, a CVD method, an MBE method, a PLD method, or an ALD method. In this embodiment, titanium nitride is deposited as the conductive film 260A to be the conductor 260a by an ALD method, and tungsten is deposited as the conductive film 260B to be the conductor 260b by a CVD method.

Note that for the conductive film 260A, a conductive material such as tantalum, tantalum nitride, titanium, ruthenium, or ruthenium oxide may be used other than titanium nitride. Alternatively, a stacked-layer structure including two or more selected from the above-described materials may be used for the conductive film 260A. For the conductive film 260B, a conductive material such as copper or aluminum may be used other than tungsten. Alternatively, a stacked-layer structure including two or more selected from the above-described materials may be used for the conductive film 260B.

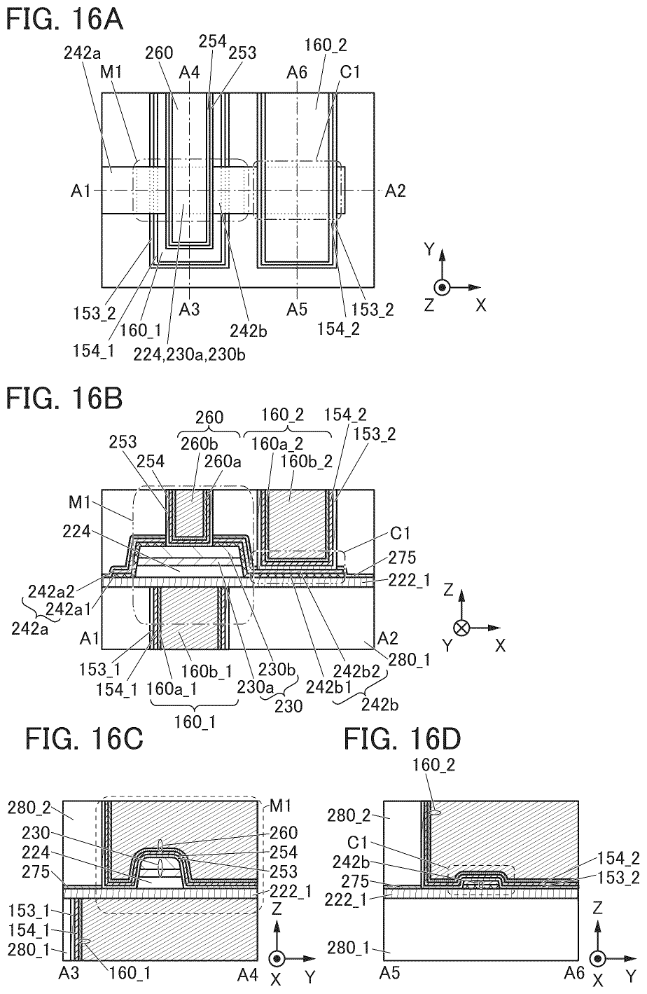

Next, the insulating film 253A, the insulating film 254A, the conductor 260a, and the conductor 260b are polished by planarization treatment such as a CMP method until the insulator 280_2 is exposed. That is, portions of the insulating film 253A, the insulating film 254A, the conductor 260a, and the conductor 260b that are exposed from the opening 258 and the opening 158 are removed. Thus, the insulator 253, the insulator 254, and the conductor 260 (the conductor 260a and the conductor 260b) are formed in the opening 258, and the insulator 153_2, the insulator 154_2, and the conductor 160_2 (the conductor 160a_2 and the conductor 160b_2) are formed in the opening 158 (see FIG. 16A to FIG. 16D).

Accordingly, the insulator 253 is provided in contact with the inner wall and the side surface of the opening 258 overlapping with the oxide 230b. The conductor 260 is placed to fill the opening 258 with the insulator 253 and the insulator 254 therebetween. In that manner, the transistor M1 is formed.

The insulator 153_2 is provided in contact with the inner wall and the side surface of the opening 158 overlapping with the conductor 242b. The conductor 160_2 is placed to fill the opening 158 with the insulator 153_2 and the insulator 154_2 therebetween. In that manner, the capacitor C1 is formed.

Then, heat treatment may be performed under conditions similar to those for the above heat treatment. In this embodiment, treatment is performed at 400° C. for one hour in a nitrogen atmosphere. The heat treatment can reduce the moisture concentration and the hydrogen concentration in the insulator 280_2. After the heat treatment, the insulator 2222 may be successively deposited without exposure to the air.

Next, the insulator 222_2 is formed over the insulator 253, the insulator 254, the conductor 260, the insulator 153_2, the insulator 154_2, the conductor 160_2, and the insulator 280_2 (see FIG. 6A to FIG. 6D). The insulator 222_2 can be deposited by a deposition method such as a sputtering method, a CVD method, an MBE method, a PLD method, or an ALD method. For example, hafnium oxide with a reduced hydrogen concentration is preferably deposited as the insulator 2222 by an ALD method, like in the case of the insulator 222_1.

Through the above process, the semiconductor device including the memory cell MCa or the memory cell MCb illustrated in FIG. 2 can be manufactured. As illustrated in FIG. 6A to FIG. 16D, with the use of the method for manufacturing a semiconductor device described in this embodiment, the capacitor C1 and the transistor M1 can be manufactured in the same process. This can reduce the number of manufacturing steps of the semiconductor device including the capacitor C1 and the transistor M1.

In the semiconductor device including the memory cell MCa or the memory cell MCb illustrated in FIG. 2, the area occupied by the memory cell can be small. In other words, the recording density of the semiconductor device can be increased.

Note that the method for manufacturing a semiconductor device of one embodiment of the present invention is not limited to that illustrated in FIG. 6A to FIG. 16D. The materials and steps in the method for manufacturing a semiconductor device may be changed depending on circumstances.

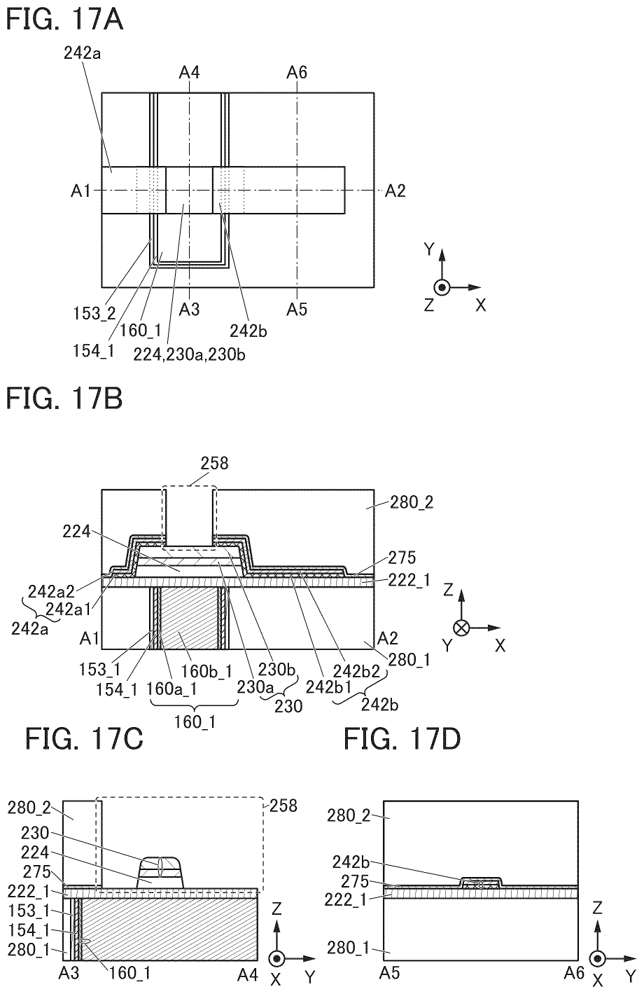

For example, after the insulator 280_2 is formed in FIG. 12A to FIG. 12D, the semiconductor device may be manufactured by the manufacturing process illustrated in FIG. 17A to FIG. 21D.

After the insulator 280_2 is formed in FIG. 12A to FIG. 12D, part of the insulator 280_2, part of the insulator 275, part of the conductive layer 242A, and part of the conductive layer 242B are processed in a region where the conductor 160_1 and the oxide 230 overlap with each other, whereby the opening 258 reaching the oxide 230b is formed. By the formation of the opening 258, the conductor 242a1 and the conductor 242b1 can be formed from the conductive layer 242A, and the conductor 242a2 and the conductor 242b2 can be formed from the conductive layer 242B (see FIG. 17A to FIG. 17D). For the specific process, the description of FIG. 13A to FIG. 13D can be referred to.

After the formation of the opening 258, microwave treatment is preferably performed in an oxygen-containing atmosphere, as in FIG. 14A to FIG. 14D.

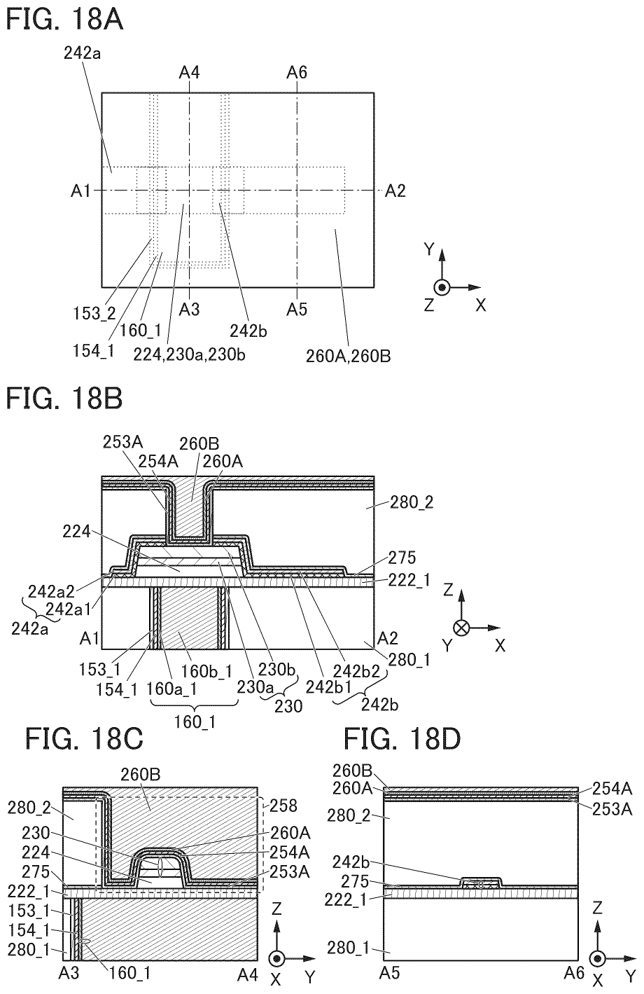

Next, the insulating film 253A, the insulating film 254A, the conductive film 260A, and the conductive film 260B are formed in this order over the insulator 280_2 and the oxide 230 (see FIG. 18A to FIG. 18D). For the specific process, the description of FIG. 15A to FIG. 15D can be referred to.

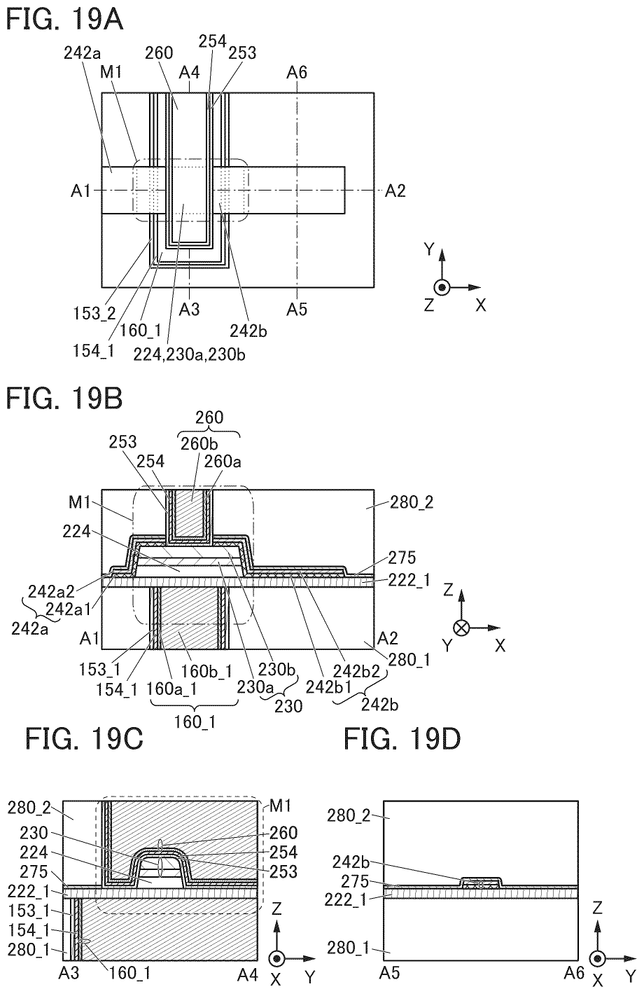

After that, the insulating film 253A, the insulating film 254A, the conductor 260a, and the conductor 260b are polished by planarization treatment such as a CMP method until the insulator 280_2 is exposed. Thus, the insulator 253, the insulator 254, and the conductor 260 (the conductor 260a and the conductor 260b) are formed in the opening 258 (FIG. 19A to FIG. 19D). For the specific process, the description of FIG. 16A to FIG. 16D can be referred to. The resulting one corresponds to the gate of the transistor M1.

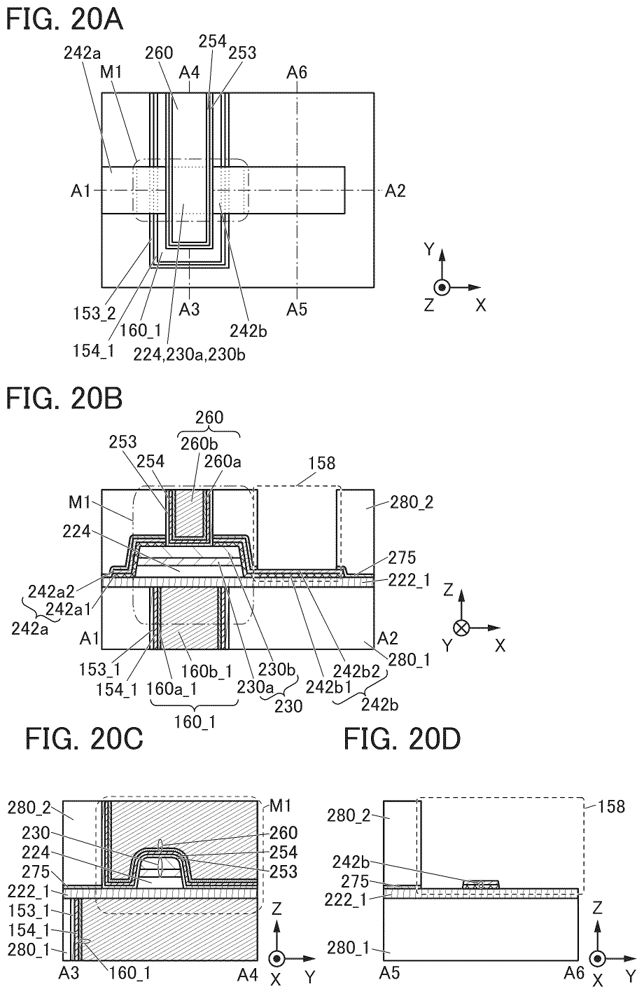

After the insulator 253, the insulator 254, and the conductor 260 (the conductor 260a and the conductor 260b) are formed in FIG. 19A to FIG. 19D, part of the insulator 280_2 and part of the insulator 275 are processed in a region where the conductor 242b and the insulator 222_1 overlap with each other and the conductor 160_1 and the oxide 230 do not overlap with each other, so that the opening 158 reaching the conductor 242b (the conductor 242b2) is formed (see FIG. 20A to FIG. 20D). For the specific process, the description of FIG. 13A to FIG. 13D can be referred to.

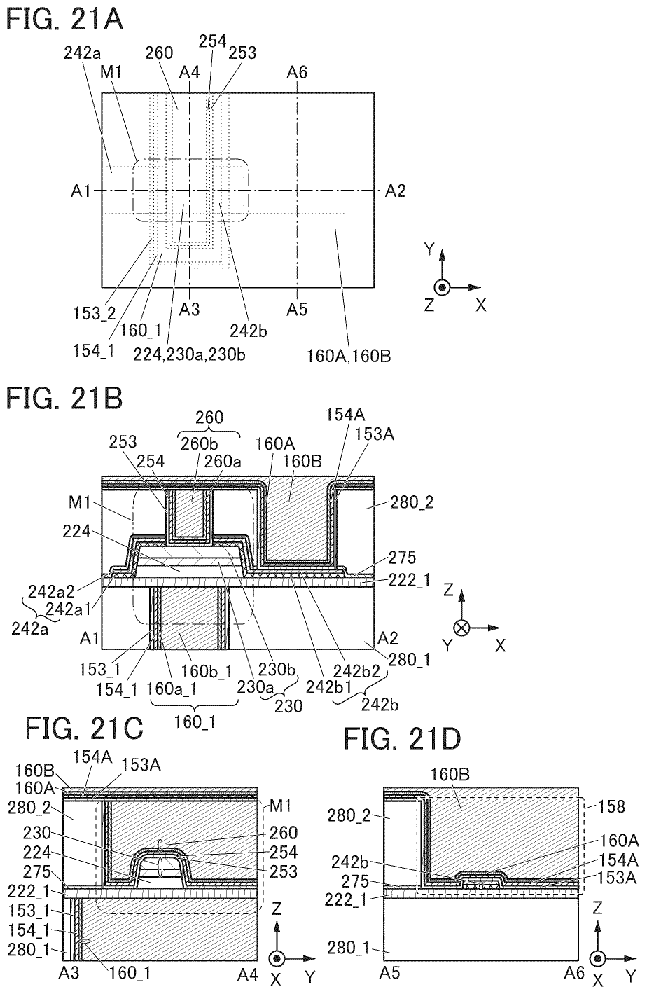

Next, an insulating film 153A, an insulating film 154A, a conductive film 160A, and a conductive film 160B are formed in this order over the insulator 280_2 and the conductor 242b (the conductor 242b2) (see FIG. 21A to FIG. 21D). For example, any of the materials that can be used for the insulating film 253A can be used for the insulating film 153A. Any of the materials that can be used for the insulating film 254A can be used for the insulating film 154A, for example. Any of the materials that can be used for the conductive film 260A can be used for the insulating film 160A, for example. Any of the materials that can be used for the conductive film 260B can be used for the insulating film 160B, for example. For the specific process, the description of FIG. 15A to FIG. 15D can be referred to.

After that, the insulating film 153A, the insulating film 154A, the conductive film 160A, and the conductive film 160B are polished by planarization treatment such as a CMP method until the insulator 280_2 is exposed. Thus, the insulator 153_2, the insulator 154_2, and the conductor 160_2 (the conductor 160a_2 and the conductor 160b_2) are formed in the opening 158. By being subjected to the planarization treatment, the semiconductor device illustrated in FIG. 21A to FIG. 21D has substantially the same structure as that illustrated in FIG. 16A to FIG. 16D. Note that the description of FIG. 16A to FIG. 16D can be referred to for the specific process of the planarization treatment.

As described above, the semiconductor device of one embodiment of the present invention can be manufactured also by performing the manufacturing process illustrated in FIG. 17A to FIG. 21D after the insulator 280_2 is formed in FIG. 12A to FIG. 12D. In addition, the following formation order (not illustrated) may be employed in the method for manufacturing the semiconductor device of one embodiment of the present invention: the opening 158 is formed in advance; the insulator 153_2, the insulator 154_2, and the conductor 160_2 (the conductor 160a_2 and the conductor 160b_2) are formed in the opening 158; after that, the opening 258 is formed; and then the insulator 253, the insulator 254, and the conductor 260 (the conductor 260a and the conductor 260b) are formed in the opening 258.

### Modification Example of Semiconductor Device

A structure example of the semiconductor device DEV of one embodiment of the present invention, which is different from the cross-sectional structure example in FIG. 2, is described below.

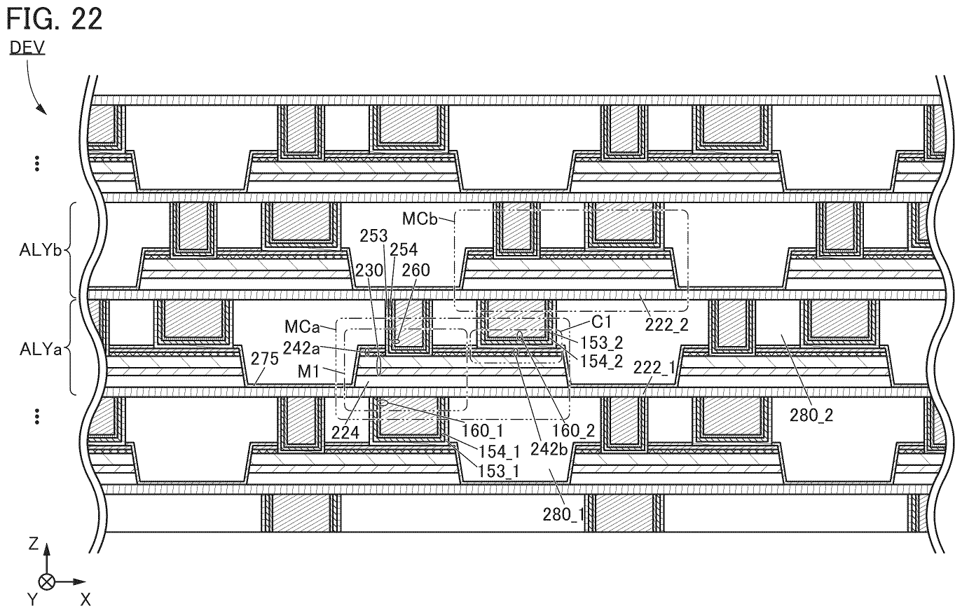

A schematic cross-sectional view of FIG. 22 is a modification example of the semiconductor device DEV illustrated in FIG. 2. Specifically, the semiconductor device DEV illustrated in FIG. 22 is different from the semiconductor device DEV illustrated in FIG. 2 in that the conductor 242b, the oxide 230, and the capacitor C1 overlap with each other.

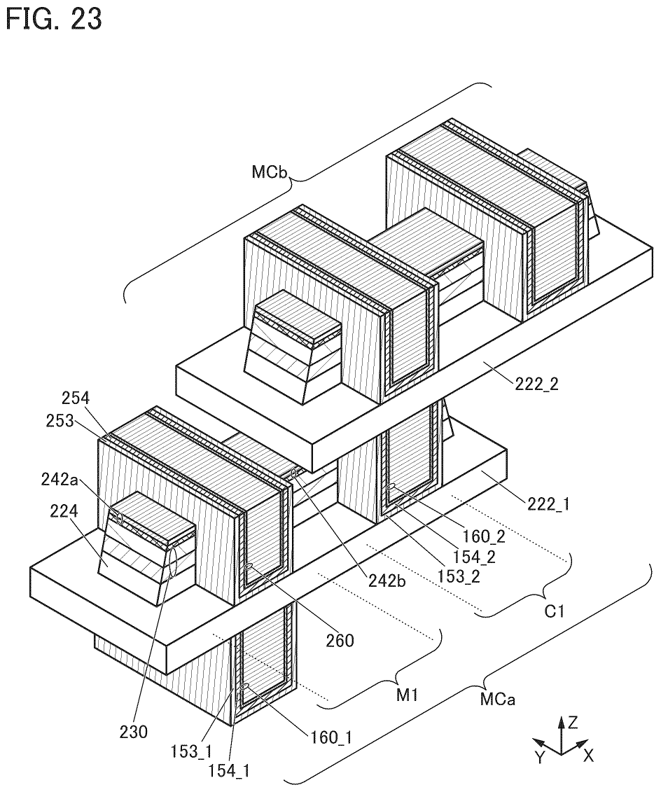

FIG. 23 is a schematic perspective view illustrating a structure example of the semiconductor device DEV in FIG. 22. Note that in FIG. 23, hatching of the insulator 222_1 and the insulator 222_2 described later is intentionally omitted and the insulator 275 is not illustrated so that the stacked-layer structure of the memory layer ALYa and the memory layer ALYb can be easily seen.

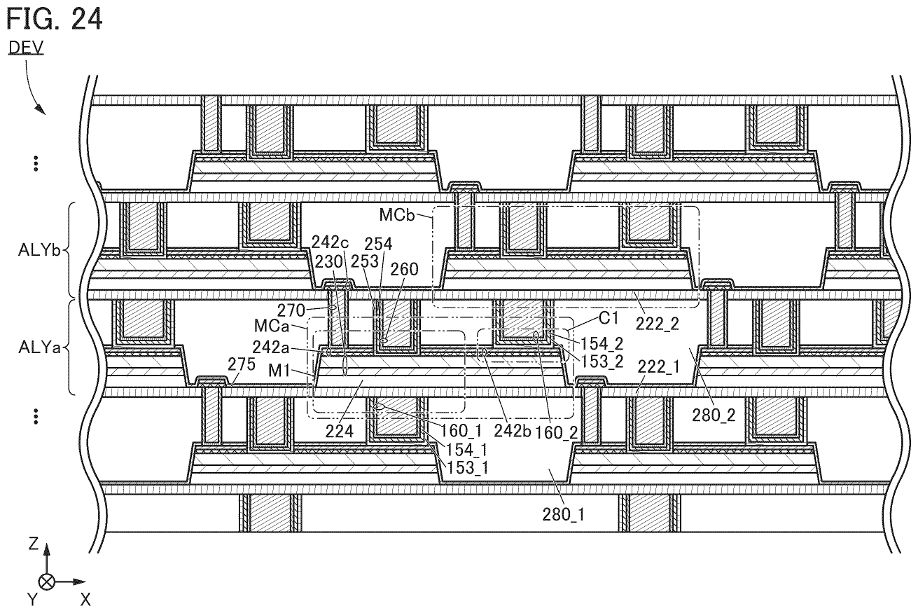

The semiconductor device DEV in FIG. 22 may have a structure in which a conductor functioning as a plug or a wiring is provided over the conductor 242a and a wiring is provided over the conductor, as in FIG. 4. For example, the semiconductor device DEV illustrated in FIG. 24 is a modification example of the semiconductor device DEV in FIG. 22, in which the conductor 270 functioning as a plug or a wiring is provided over the conductor 242a, and the conductor 242c functioning as a wiring is provided over the conductor 270 and the insulator 222_2. Note that the conductor 242c can be formed at the same time as the conductor 242a and the conductor 242b included in the memory cell MCb in the memory layer ALYb. In addition, the conductor 242c can be formed using the same material as the conductor 242a and the conductor 242b. Moreover, the conductor 242c functions as any one of the wiring BLa[1] to the wiring BLa[n] in the memory layer ALYa.

### Structure Example of Memory Cell

Next, a structure example of the memory cell of the semiconductor device DEV illustrated in FIG. 22 is described.

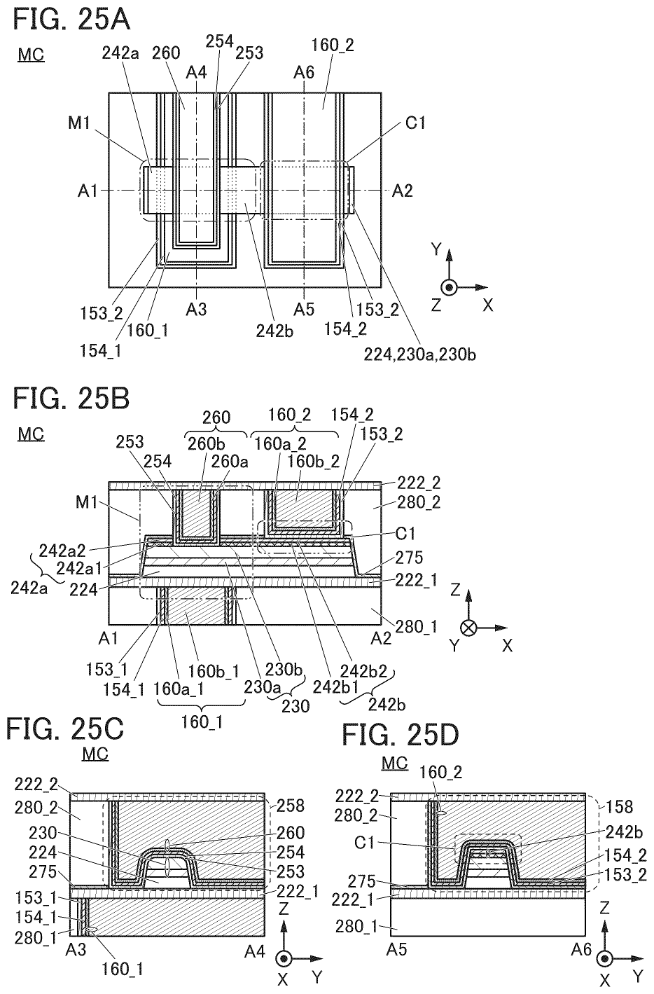

FIG. 25A to FIG. 25D are a schematic plan view and schematic cross-sectional views of the memory cell MC including the transistor M1 and the capacitor C1 in the semiconductor device DEV in FIG. 22. FIG. 25A is the schematic plan view of the memory cell MC. FIG. 25B to FIG. 25D are the schematic cross-sectional views of the memory cell MC. Here, FIG. 25B is a cross-sectional view of a portion along dashed-dotted line A1-A2 illustrated in FIG. 25A, and is a cross-sectional view of the transistor M1 in the channel length direction. FIG. 25C is a schematic cross-sectional view of a portion along dashed-dotted line A3-A4 illustrated in FIG. 25A, and is a schematic cross-sectional view of the transistor M1 in the channel width direction. FIG. 25D is a schematic cross-sectional view of a portion along dashed-dotted line A5-A6 illustrated in FIG. 25A, and is a schematic cross-sectional view of the capacitor C1. Note that some components are omitted in the top view of FIG. 25A for clarity of the drawing.

The memory cell MC includes the insulator 2801, the insulator 1531, the insulator 154_1, and the conductor 160_1 (the conductor 160a_1 and the conductor 160b_1) over a substrate (not illustrated). Furthermore, the memory cell MC includes the insulator 222_1 over the insulator 280_1, the insulator 153_1, the insulator 154_1, and the conductor 160_1. In addition, the memory cell MC includes the insulator 224 in a region that is over the insulator 222_1 and includes an area overlapping with the conductor 160_1; the oxide 230a over the insulator 224; and the oxide 230b over the oxide 230a. Furthermore, the memory cell MC includes the conductor 242a (the conductor 242a1 and the conductor 242a2) over the insulator 2221, and the conductor 242b (the conductor 242b1 and the conductor 242b2). Moreover, the memory cell MC includes the insulator 275 over the insulator 2221, a side surface of the insulator 224, a side surface of the oxide 230, a side surface of the conductor 242a, and the conductor 242b; and the insulator 280_2 over the insulator 275. In addition, the memory cell MC includes the insulator 253 in a region that is over the oxide 230b and overlaps with the conductor 160_1; the insulator 254 over the insulator 253; and the conductor 260 (the conductor 260a and the conductor 260b) over the insulator 254. Furthermore, the memory cell MC includes the insulator 153_2 in a region that is over the conductor 242b and does not overlap with the conductor 160_1; the insulator 154_2 over the insulator 153_2; and the conductor 160_2 (the conductor 160a_2 and the conductor 160b_2) over the insulator 154_2. In addition, the memory cell MC includes the insulator 222_2 over the insulator 280_2, the insulator 253, the insulator 254, the conductor 260, the insulator 153_2, the insulator 154_2, and the conductor 160_2. In particular, one or both of the transistor M1 and the capacitor C1 are provided to be embedded in the insulator 280_2.

Note that the description of the insulators, conductors, and oxides in FIG. 6A to FIG. 6D is referred to for the insulator 280_1, the insulator 153_1, the insulator 154_1, the conductor 160_1, the insulator 2221, the insulator 224, the oxide 230, the conductor 242a, the conductor 242b, the insulator 275, the insulator 280_2, the insulator 253, the insulator 254, the conductor 260, the insulator 153_2, the insulator 154_2, the conductor 160_2, and the insulator 222_2, which are illustrated in FIG. 25A to FIG. 25D.

Although not illustrated in FIG. 25A to FIG. 25D, the conductor 242a and the conductor 242b may also be provided over the side surface of the insulator 224, the side surface of the oxide 230a, and the side surface of the oxide 230. Similarly, the conductor 242a and the conductor 242b may also be provided over the insulator 222_1. When the conductor 242a and the conductor 242b are provided over the side surface of the insulator 224, the side surface of the oxide 230a, the side surface of the oxide 230, and the insulator 2221, the conductor 242a and the conductor 242b provided over the side surface of the insulator 224, the side surface of the oxide 230a, the side surface of the oxide 230, and the insulator 222_1 can each be a wiring electrically connected to one of the source electrode and the drain electrode of the transistor M1. In that case, the wiring functions as a bit line.

### Example of Method for Manufacturing Semiconductor Device

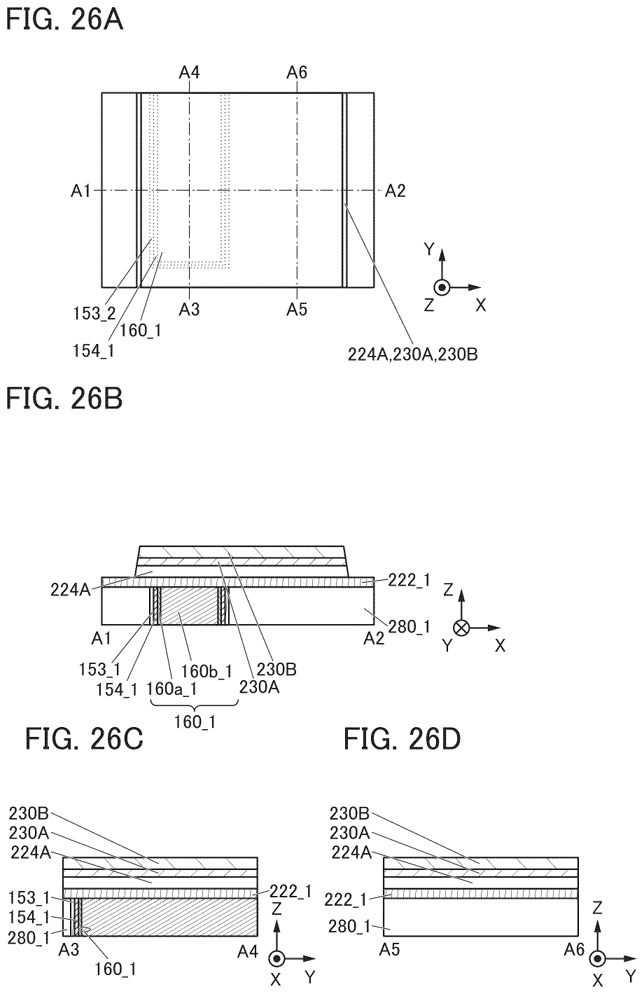

Next, an example of a method for manufacturing the memory layer ALYa of the semiconductor device DEV illustrated in FIG. 25A to FIG. 25D is described. Note that FIG. 26A to FIG. 31D are used for describing the example of the manufacturing method.

In each of FIG. 26A to FIG. 31D, A illustrates a schematic plan view. Moreover, B of each drawing is a schematic cross-sectional view corresponding to a portion along the dashed-dotted line A1-A2 illustrated in A of each drawing, and is also a schematic cross-sectional view of the transistor M1 in the channel length direction. Furthermore, C of each drawing is a schematic cross-sectional view corresponding to a portion along the dashed-dotted line A3-A4 illustrated in A of each drawing, and is also a schematic cross-sectional view of the transistor M1 in the channel width direction. In addition, D of each drawing is a schematic cross-sectional view of a portion along the dashed-dotted line A5-A6 in A of each drawing. Note that for clarity of the drawing, some components are not illustrated in the schematic plan view of A of each drawing.

Note that in a method for manufacturing the memory cell of the semiconductor device DEV in FIG. 22, portions similar to those in the method for manufacturing the memory cell of the semiconductor device DEV in FIG. 2 are not described in some cases. For the method for manufacturing the memory cell of the semiconductor device DEV in FIG. 22, the method for manufacturing the memory cell of the semiconductor device DEV in FIG. 2 can be referred to.

First, a substrate (not illustrated) is prepared, and the insulator 280_1, the insulator 153_1, the insulator 1541, and the conductor 160_1 are formed above the substrate (see FIG. 26A to FIG. 26D). For the formation methods of the insulator 280_1, the insulator 153_1, the insulator 154_1, and the conductor 1601, the description in FIG. 7A to FIG. 7D can be referred to.

Next, the insulator 2221 is deposited over the insulator 280_1, the insulator 153_1, the insulator 154_1, and the conductor 1601 (see FIG. 26A to FIG. 26D). For the formation method of the insulator 222_1, the description in FIG. 7A to FIG. 7D can be referred to.

Next, the insulating layer 224A, the oxide layer 230A, and the oxide layer 230B are formed over the insulator 222_1 (see FIG. 26A to FIG. 26D). Specifically, as described in FIG. 8A to FIG. 8D, an insulating film to be the insulating layer 224A, an oxide film to be the oxide layer 230A, and an oxide film to be the oxide layer 230B are formed in this order, and then the insulating film to be the insulating layer 224A, the oxide film to be the oxide layer 230A, and the oxide layer 230B are each processed by a lithography method or the like as described in FIG. 9A to FIG. 9D. Note that the formation method in FIG. 26A to FIG. 26D is different from the formation method in FIG. 9A to FIG. 9D in that the insulating layer 224A, the oxide layer 230A, and the oxide layer 230B are formed also in a region where the capacitor C1 is to be formed later, e.g., in a region not overlapping with the conductor 160_1.

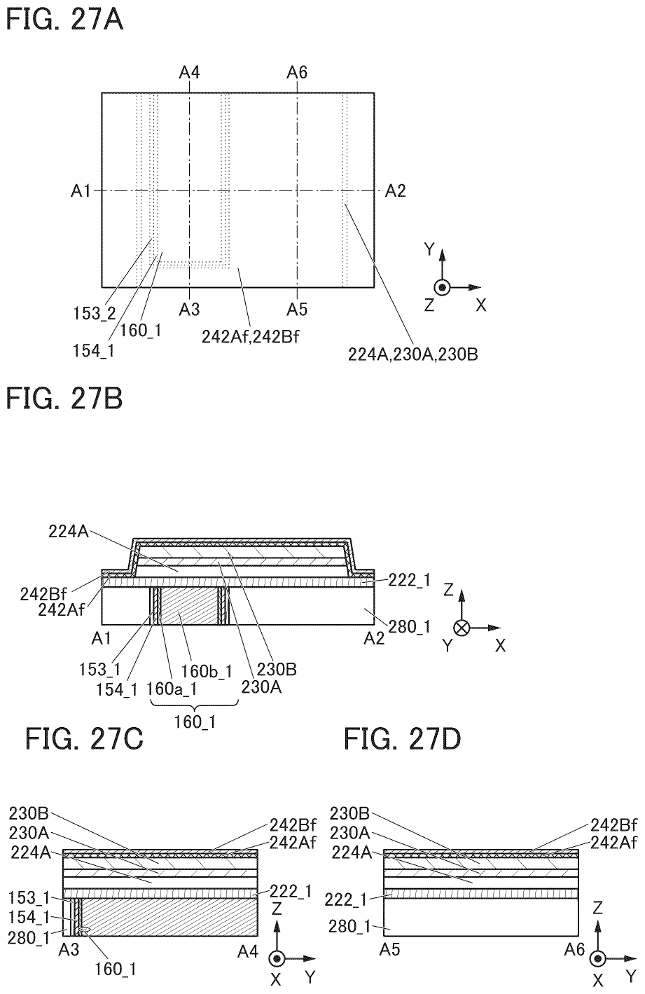

Next, the conductive film 242Af and the conductive film 242Bf are deposited in this order over the insulator 222_1 and the oxide layer 230B (see FIG. 27A to FIG. 27D). For the formation methods of the conductive film 242Af and the conductive film 242Bf, the description in FIG. 10A to FIG. 10D can be referred to.

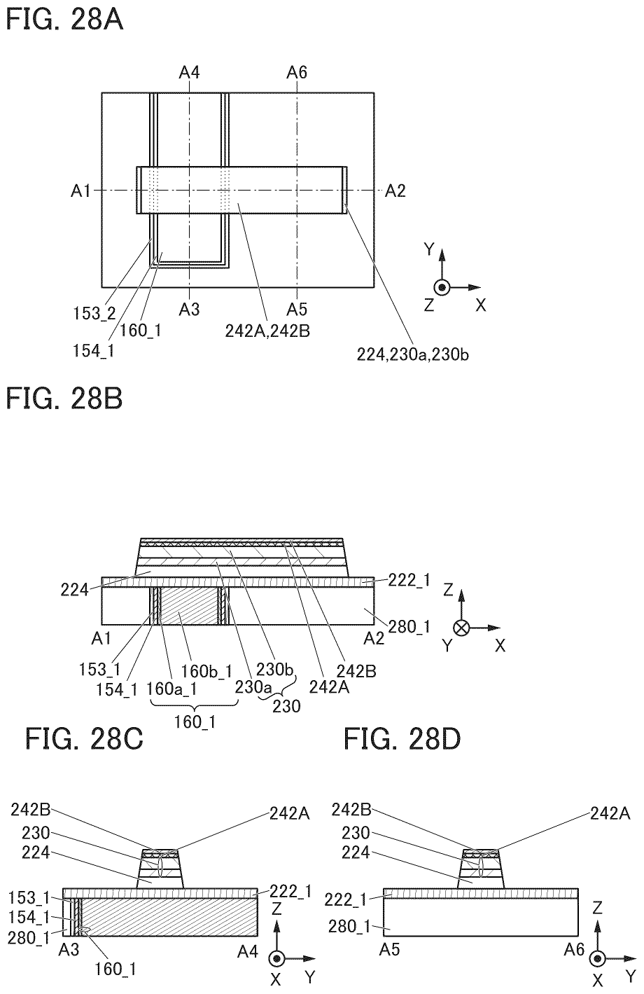

Next, the insulating layer 224A, the oxide layer 230A, the oxide layer 230B, the conductive film 242Af, and the conductive film 242Bf are processed by a lithography method to form the insulator 224, the oxide 230a, the oxide 230b, the conductive layer 242A, and the conductive layer 242B, which have an island shape (see FIG. 28A to FIG. 28D). For the processing of the insulating layer 224A, the oxide layer 230A, the oxide layer 230B, the conductive film 242Af, and the conductive film 242Bf, the description in FIG. 11A to FIG. 11D can be referred to.

Although not illustrated in FIG. 28A to FIG. 28D, the processing may be performed so that the conductive layer 242A and the conductive layer 242B are formed over the insulator 222_1, the side surface of the insulator 224, the side surface of the oxide 230a, and the side surface of the oxide 230b. The conductive layer 242A and the conductive layer 242B formed over the insulator 222_1, the side surface of the insulator 224, the side surface of the oxide 230a, and the side surface of the oxide 230b function as wirings, for example.

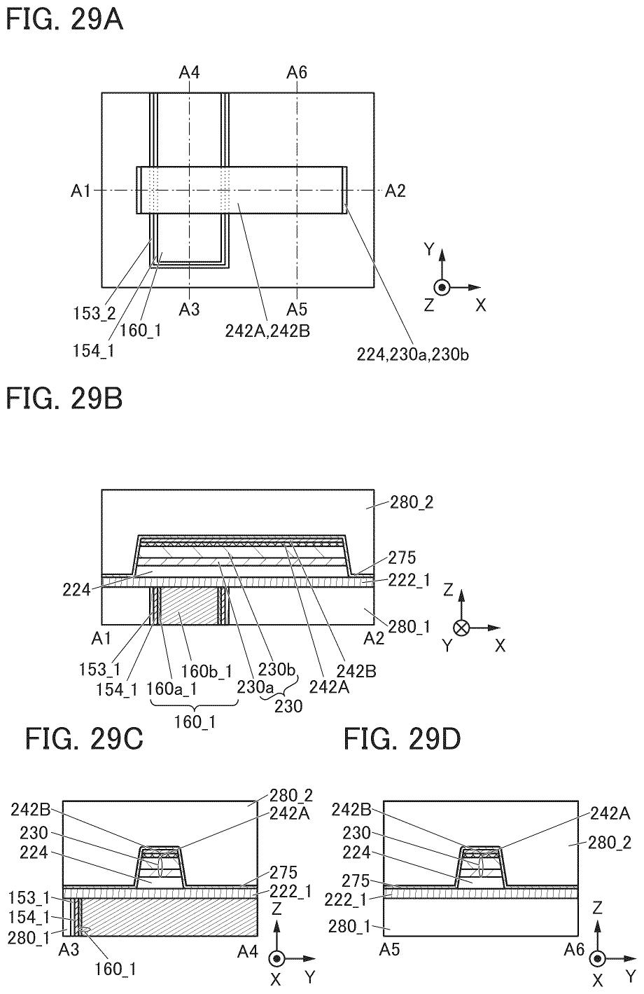

Next, the insulator 275 is deposited to cover the insulator 224, the oxide 230a, the oxide 230b, the conductive layer 242A, and the conductive layer 242B, and an insulating film to be the insulator 280_2 is deposited over the insulator 275. After that, the insulating film to be the insulator 280_2 is subjected to planarization treatment such as a CMP method, so that the insulator 280_2 with a flat top surface is formed (see FIG. 29A to FIG. 29D). For the formation methods of the insulator 275 and the insulator 280_2, the description in FIG. 12A to FIG. 12D can be referred to.

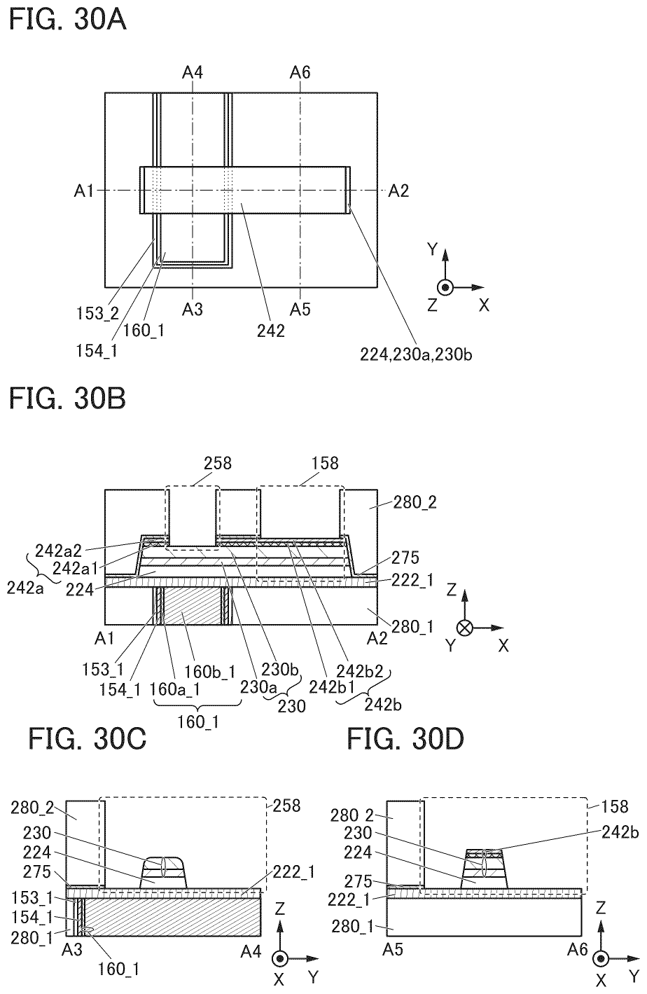

Next, in a region where the conductor 160_1 and the oxide 230 overlap with each other, part of the insulator 280_2, part of the insulator 275, part of the conductive layer 242A, and part of the conductive layer 242B are processed to form the opening 258 reaching the oxide 230b. By the formation of the opening 258, the conductor 242al and the conductor 242b1 can be formed from the conductive layer 242A, and the conductor 242a2 and the conductor 242b2 can be formed from the conductive layer 242B (see FIG. 30A to FIG. 30D). For the formation method of the opening 258, the description in FIG. 13A to FIG. 13D can be referred to.

In addition, in a region where the conductive layer 242A, the conductive layer 242B, and the insulator 222_1 overlap with each other and the conductor 160_1 and the oxide 230 do not overlap with each other, part of the insulator 280_2 and part of the insulator 275 are processed, whereby the opening 158 reaching the conductive layer 242B (the conductor 242b2) is formed (see FIG. 30A to FIG. 30D). For the formation method of the opening 158, the description in FIG. 13A to FIG. 13D can be referred to.

Note that the opening 158 and the opening 258 may be formed at a time; alternatively, one of the opening 158 and the opening 258 may be formed first and then the other may be formed. Note that the opening 258 is preferably formed so that the oxide 230b is exposed at the bottom portion of the opening 258, and the opening 158 is preferably formed so that the conductor 242b2 is exposed at the bottom portion of the opening 158. Therefore, the opening 158 and the opening 258 are preferably formed by processing methods under different conditions.

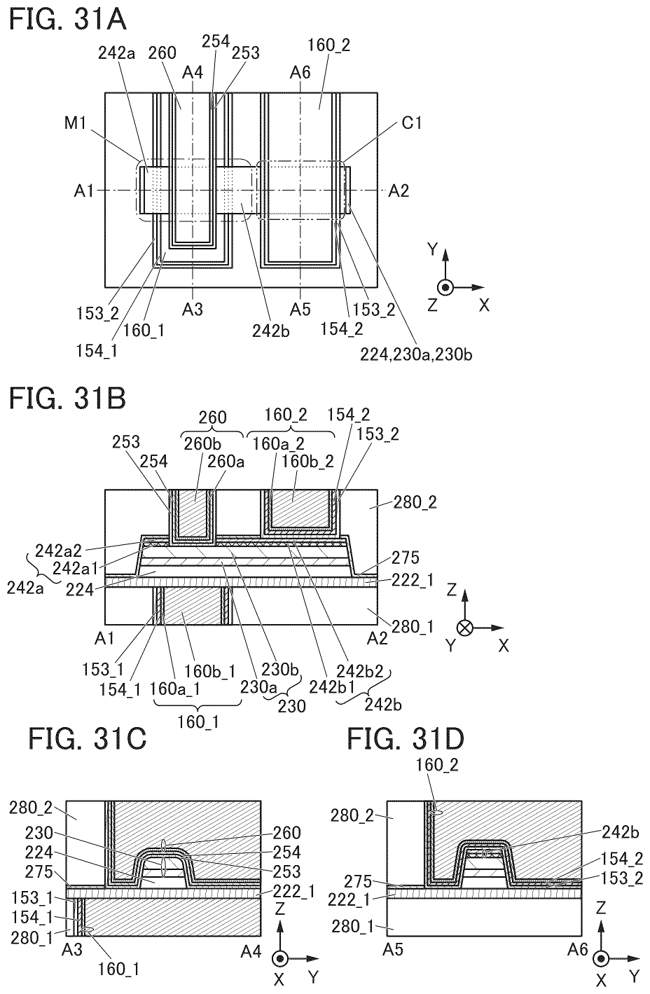

Next, an insulating film to be the insulator 253 is deposited over the insulator 280_2, the bottom surface and the side surface of the opening 258, and the bottom surface and the side surface of the opening 158. After the insulating film to be the insulator 253 is deposited, microwave treatment may be performed. After that, an insulating film to be the insulator 254 and a conductive film to be the conductor 260 and the conductor 160_2 are deposited in this order over the insulating film to be the insulator 253. After the formation of the conductive film to be the conductor 260 and the conductor 160_2, polishing is performed by planarization treatment such as a CMP method until the insulating film to be the insulator 253, the insulating film to be the insulator 254, and the conductive film to be the conductor 260 and the conductor 160_2 are exposed. That is, portions of the insulating film to be the insulator 253, the insulating film to be the insulator 254, and the conductive film to be the conductor 260 and the conductor 160_2 that are exposed from the opening 258 and the opening 158 are removed. Thus, the insulator 253, the insulator 254, and the conductor 260 (the conductor 260a and the conductor 260b) are formed in the opening 258, and the insulator 153_2, the insulator 154_2, and the conductor 160_2 (the conductor 160a_2 and the conductor 160b_2) are formed in the opening 158 (see FIG. 31A to FIG. 31D). For the formation methods of the insulator 253, the insulator 254, the conductor 260, the insulator 153_2, the insulator 154_2, and the conductor 160_2, the description in FIG. 14A to FIG. 16D can be referred to.

Next, the insulator 222_2 is formed over the insulator 253, the insulator 254, the conductor 260, the insulator 153_2, the insulator 154_2, the conductor 160_2, and the insulator 280_2 (see FIG. 25A to FIG. 25D). For the formation method of the insulator 2222, the description of the formation method of the insulator 2222 performed after FIG. 16A to FIG. 16D can be referred to.

Through the above process, the semiconductor device including the memory cell MCa or the memory cell MCb illustrated in FIG. 22 can be manufactured. As illustrated in FIG. 25A to FIG. 31D, with the use of the method for manufacturing a semiconductor device described in this embodiment, the capacitor C1 and the transistor M1 can be manufactured in the same process. This can reduce the number of manufacturing steps of the semiconductor device including the capacitor C1 and the transistor M1.

In the semiconductor device including the memory cell MCa or the memory cell MCb illustrated in FIG. 22, the area occupied by the memory cell can be small. In other words, the recording density of the semiconductor device can be increased.

Note that the method for manufacturing a semiconductor device of one embodiment of the present invention is not limited to that illustrated in FIG. 26A to FIG. 31D. The materials and steps in the method for manufacturing a semiconductor device may be changed depending on circumstances.

For example, as in FIG. 7A to FIG. 12D and FIG. 17A to FIG. 21D, which illustrate the methods for manufacturing the semiconductor device DEV in FIG. 2, the method for manufacturing the semiconductor device DEV in FIG. 22 may be as follows: the opening 258 is formed in advance; the insulator 253, the insulator 254, and the conductor 260 (the conductor 260a and the conductor 260b) are formed in the opening 258; after that, the opening 158 is formed; and then, the insulator 153_2, the insulator 154_2, and the conductor 160_2 (the conductor 160a_2 and the conductor 160b_2) are formed in the opening 158. In addition, the following formation order may be employed in the method for manufacturing the semiconductor device DEV in FIG. 22: the opening 158 is formed in advance; the insulator 153_2, the insulator 154_2, and the conductor 160_2 (the conductor 160a_2 and the conductor 160b_2) are formed in the opening 158; after that, the opening 258 is formed; and then the insulator 253, the insulator 254, and the conductor 260 (the conductor 260a and the conductor 260b) are formed in the opening 258.

Note that this embodiment can be combined with any of the other embodiments described in this specification as appropriate.

### Embodiment 2

In this embodiment, a structure example of a memory device including the semiconductor device described in the foregoing embodiment will be described.

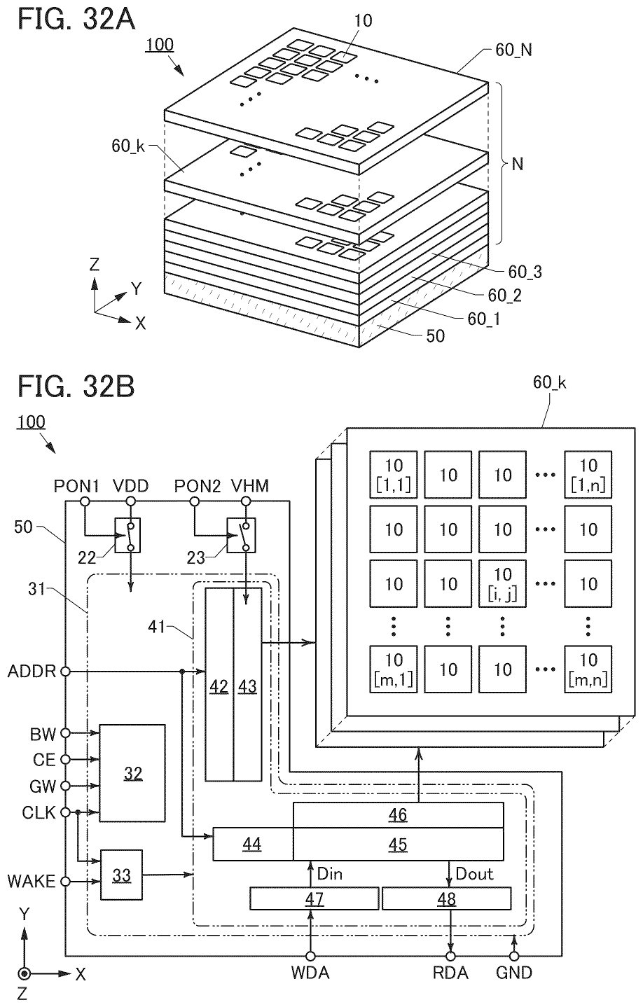

FIG. 32A is a schematic perspective view illustrating a structure example of a memory device 100. FIG. 32B is a block diagram illustrating the structure example of the memory device 100. The memory device 100 includes a driver circuit layer 50 and N(Nis a integer of 1 or more) memory layers 60. One memory layer 60 includes a plurality of memory cells 10 arranged in a matrix of m rows and n columns. Note that FIG. 32B illustrates an example where a memory cell 10[1,1], a memory cell 10[m,1] (here, m is an integer of 1 or more), a memory cell 10[1,n] (here, n is an integer of 1 or more), a memory cell 10[m,n], and a memory cell 10[i,j] (here, i is an integer greater than or equal to 1 and less than or equal to m, and j is an integer greater than or equal to 1 and less than or equal to n) are provided in a memory layer 60_k.

Note that the memory layer 60 corresponds to the memory layer ALYa or the memory layer ALYb described in Embodiment 1. The memory cell 10 corresponds to the memory cell MCa or the memory cell MCb described in Embodiment 1.

The N memory layers 60 are provided over the driver circuit layer 50. Provision of the N memory layers 60 over the driver circuit layer 50 can reduce the area occupied by the memory device 100. Furthermore, memory capacity per unit area can be increased.

In this embodiment and the like, the first memory layer 60 is denoted by a memory layer 60_1, the second memory layer 60 is denoted by a memory layer 60_2, and the third memory layer 60 is denoted by a memory layer 60_3. Furthermore, the k-th memory layer 60 (k is an integer greater than or equal to 1 and less than or equal to N) is denoted by a memory layer 60_k, and the N-th memory layer 60 is denoted by a memory layer 60_N. Note that in this embodiment and the like, the simple term “memory layer 60” is sometimes used in the case of describing a matter related to all the N memory layers 60 or showing a matter common to the N memory layers 60.

### Structure Example of Driver Circuit Layer 50

The driver circuit layer 50 includes a PSW 22 (power switch), a PSW 23, and a peripheral circuit 31. The peripheral circuit 31 includes a peripheral circuit 41, a control circuit 32, and a voltage generation circuit 33.

In the memory device 100, each circuit, each signal, and each voltage can be appropriately selected as needed. Alternatively, another circuit or another signal may be added. A signal BW, a signal CE, a signal GW, a signal CLK, a signal WAKE, a signal ADDR, a signal WDA, a signal PON1, and a signal PON2 are signals input from the outside, and a signal RDA is a signal output to the outside. The signal CLK is a clock signal.

The signal BW, the signal CE, and the signal GW are control signals. The signal CE is a chip enable signal, the signal GW is a global write enable signal, and the signal BW is a byte write enable signal. The signal ADDR is an address signal. The signal WDA is write data, and the signal RDA is read data. The signal PON1 and the signal PON2 are power gating control signals. Note that the signal PON1 and the signal PON2 may be generated in the control circuit 32.

The control circuit 32 is a logic circuit having a function of controlling the entire operation of the memory device 100. For example, the control circuit performs a logical operation on the signal CE, the signal GW, and the signal BW to determine an operation mode (e.g., a writing operation or a reading operation) of the memory device 100. Alternatively, the control circuit 32 generates a control signal for the peripheral circuit 41 so that the operation mode is executed.

The voltage generation circuit 33 has a function of generating a negative voltage. The signal WAKE has a function of controlling the input of the signal CLK to the voltage generation circuit 33. For example, when an H-level signal is supplied as the signal WAKE, the signal CLK is input to the voltage generation circuit 33, and the voltage generation circuit 33 generates a negative voltage.

The peripheral circuit 41 is a circuit for writing and reading data to/from the memory cells 10. The peripheral circuit 41 includes a row decoder 42, a column decoder 44, a row driver 43, a column driver 45, an input circuit 47, an output circuit 48, and a sense amplifier 46.

The row decoder 42 and the column decoder 44 have a function of decoding the signal ADDR. The row decoder 42 is a circuit for specifying a row to be accessed, and the column decoder 44 is a circuit for specifying a column to be accessed.

The row driver 43 has a function of selecting a wiring WL (write and read word line) specified by the row decoder 42.

The column driver 45 has a function of writing data to the memory cells 10, a function of reading data from the memory cells 10, and a function of retaining the read data. The column driver 45 has a function of selecting a wiring BL (write and read bit line) specified by the column decoder 44.

The input circuit 47 has a function of retaining the signal WDA. Data retained by the input circuit 47 (first data in the above embodiment) is output to the column driver 45. Data output from the input circuit 47 is data (Din) to be written to the memory cells 10. Data (Dout) read from the memory cells 10 by the column driver 45 is output to the output circuit 48. Note that in the above embodiment, the read data (Dout) is treated as arithmetic operation result data.

The output circuit 48 has a function of retaining Dout. In addition, the output circuit 48 has a function of outputting Dout to the outside of the memory device 100. Data output from the output circuit 48 is the signal RDA.

The PSW 22 has a function of controlling supply of VDD to the peripheral circuit 31. The PSW 23 has a function of controlling supply of VHM to the row driver 43. Here, in the memory device 100, a high power supply voltage is VDD and a low power supply voltage is GND (a ground potential). VHM is a high power supply voltage used to set a word line at a high level and is higher than VDD. The on state and the off state of the PSW 22 are switched by the signal PON1, and the on state and the off state of the PSW 23 is switched by the signal PON2. The number of power domains to which VDD is supplied is one in the peripheral circuit 31 in FIG. 32B but can be more than one. In that case, a power switch is provided for each power domain.

Next, electrical connection between the peripheral circuit 41 and the memory layer 60 is described.

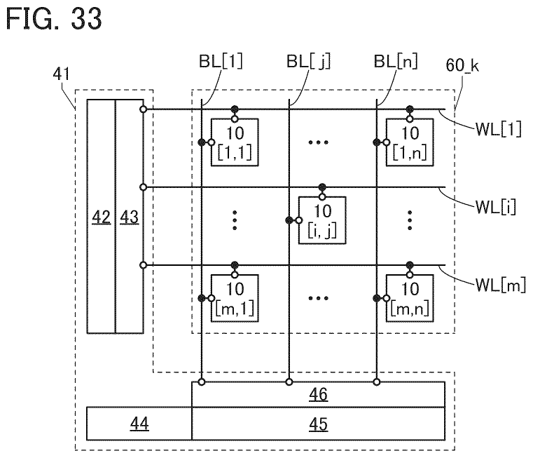

FIG. 33 is a block diagram illustrating a structure example of the peripheral circuit 41 and the memory layer 60_k. In FIG. 33, the row decoder 42 and the row driver 43 are electrically connected to each of a wiring WL[1] to a wiring WL[m], and the column decoder 44, the column driver 45, and the sense amplifier 46 are electrically connected to each of a wiring BL[1] to a wiring BL[n].

Note that the wiring WL[1] to the wiring WL[m] are wirings corresponding to the wiring WLa[1] to the wiring WLa[m] or the wiring WLb[1] to the wiring WLb[m] described in Embodiment 1. That is, the wiring WL[1] to the wiring WL[m] function as word lines.

The wiring BL[1] to the wiring BL[n] are wirings corresponding to the wiring BLa[1] to the wiring BLa[n] or the wiring BLb[1] to the wiring BLb[n] described in Embodiment 1. That is, the wiring BL[1] to the wiring BL[n] function as bit lines.

The memory cell 10[i,j] placed in the i-th row and the j-th column is electrically connected to the wiring WL[i] and the wiring BL[j].

As illustrated in FIG. 33, the memory layer 60_k is electrically connected to the peripheral circuit 41, whereby data can be written and read to/from the memory layer 60_k.

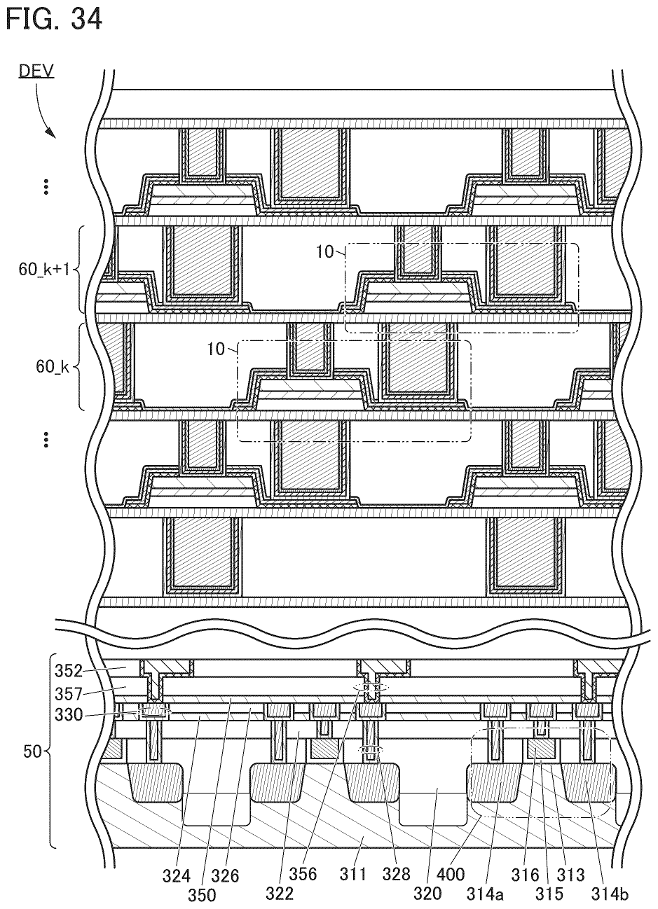

Next, FIG. 34 illustrates a cross-sectional structure example of the memory device 100 of one embodiment of the present invention. The memory device 100 illustrated in FIG. 34 includes a plurality of memory layers 60 (the memory layers ALYa or the memory layers ALYb) above the driver circuit layer 50. The description of the memory layers 60 in this embodiment is omitted in order to reduce repeated description.

FIG. 34 illustrates a transistor 400 included in the driver circuit layer 50 as an example. The transistor 400 is provided on a substrate 311 and includes a conductor 316 functioning as a gate, an insulator 315 functioning as a gate insulator, a semiconductor region 313 including part of the substrate 311, a low-resistance region 314a functioning as one of a source region and a drain region, and a low-resistance region 314b functioning as the other of the source region and the drain region. The transistor 400 may be a p-channel transistor or an n-channel transistor. As the substrate 311, a single crystal silicon substrate can be used, for example.

Here, in the transistor 400 illustrated in FIG. 34, the semiconductor region 313 (part of the substrate 311) where a channel is formed has a protruding shape. The conductor 316 is provided to cover a side surface and a top surface of the semiconductor region 313 with the insulator 315 therebetween. Note that a material for adjusting the work function may be used as the conductor 316. Such a transistor 400 is also referred to as a FIN-type transistor because it utilizes a protruding portion of a semiconductor substrate. Note that an insulator functioning as a mask for forming the protruding portion may be included in contact with an upper portion of the protruding portion. Furthermore, although the case where the protruding portion is formed by processing part of the semiconductor substrate is described here, a semiconductor film having a protruding shape may be formed by processing an SOI (Silicon On Insulator) substrate.

Note that the transistor 400 illustrated in FIG. 34 is an example and the structure is not limited thereto; an appropriate transistor can be used in accordance with a circuit structure or a driving method.

A wiring layer provided with an interlayer film, a wiring, and a plug may be provided between the components. A plurality of wiring layers can be provided in accordance with design. Furthermore, in this specification and the like, a wiring and a plug electrically connected to the wiring may be a single component. That is, part of a conductor may function as a wiring and part of the conductor may function as a plug.

For example, an insulator 320, an insulator 322, an insulator 324, and an insulator 326 are stacked in this order over the transistor 400 as interlayer films. A conductor 328 or the like is embedded in the insulator 320 and the insulator 322. A conductor 330 or the like is embedded in the insulator 324 and the insulator 326. Note that the conductor 328 and the conductor 330 function as a contact plug or a wiring.

The insulators functioning as the interlayer films may also function as planarization films that cover an uneven shape thereunder. For example, the top surface of the insulator 322 may be planarized by planarization treatment using a chemical mechanical polishing (CMP) method or the like to improve planarity.

A wiring layer may be provided over the insulator 326 and the conductor 330. For example, in FIG. 34, an insulator 350, an insulator 357, and an insulator 352 are stacked in this order over the insulator 326 and the conductor 330. A conductor 356 is formed in the insulator 350, the insulator 357, and the insulator 352. The conductor 356 functions as a contact plug or a wiring. For example, the conductor corresponding to the wiring WL (any one of the wiring WL[1] to the wiring WL[m]) or the wiring BL (any one of the wiring BL[1] to the wiring BL[n]) in FIG. 33 and the transistor 400 are electrically connected to each other through the conductor 356, the conductor 330, and the like.

This embodiment can be combined as appropriate with any of the other embodiments and the like described in this specification.

### Embodiment 3

In this embodiment, examples of a semiconductor wafer where the memory device or the like described in the above embodiment is formed and electronic components incorporating the memory device will be described.

### <Semiconductor Wafer>

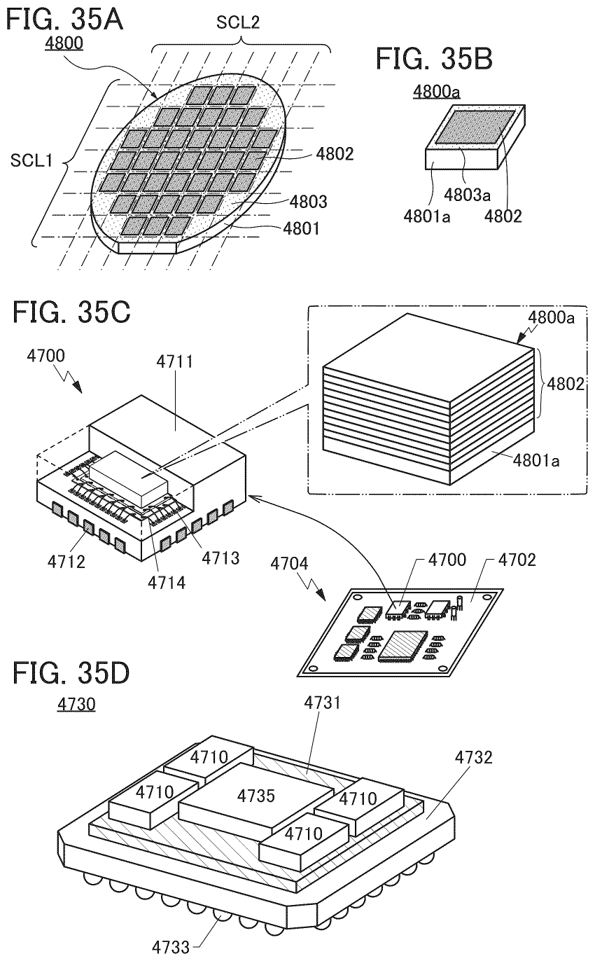

First, an example of a semiconductor wafer where a memory device or the like is formed is described with reference to FIG. 35A.

A semiconductor wafer 4800 illustrated in FIG. 35A includes a wafer 4801 and a plurality of circuit portions 4802 provided on the top surface of the wafer 4801. Note that a portion without the circuit portion 4802 on the top surface of the wafer 4801 is a spacing 4803 that is a region for dicing.

The semiconductor wafer 4800 can be fabricated by forming the plurality of circuit portions 4802 on the surface of the wafer 4801 by a pre-process. After that, a surface of the wafer 4801 opposite to the surface provided with the plurality of circuit portions 4802 may be ground to thin the wafer 4801. Through this process, warpage or the like of the wafer 4801 is reduced and the size of the component can be reduced.

A dicing process is performed as a next process. The dicing is performed along scribe lines SCL1 and scribe lines SCL2 (referred to as dicing lines or cutting lines in some cases) indicated by dashed-dotted lines. Note that to perform the dicing process easily, it is preferable that the spacing 4803 be provided so that the plurality of scribe lines SCL1 are parallel to each other, the plurality of scribe lines SCL2 are parallel to each other, and the scribe lines SCL1 are perpendicular to the scribe lines SCL2.

With the dicing process, a chip 4800a as illustrated in FIG. 35B can be cut out from the semiconductor wafer 4800. The chip 4800a includes a wafer 4801a, the circuit portion 4802, and a spacing 4803a. Note that it is preferable to make the spacing 4803a small as much as possible.

In this case, the width of the spacing 4803 between adjacent circuit portions 4802 is substantially the same as a cutting allowance of the scribe line SCL1 or a cutting allowance of the scribe line SCL2.

Note that the shape of the element substrate of one embodiment of the present invention is not limited to the shape of the semiconductor wafer 4800 illustrated in FIG. 35A. The element substrate may be a rectangular semiconductor wafer, for example. The shape of the element substrate can be changed as appropriate, depending on a fabrication process of an element and an apparatus for fabricating the element.

### <Electronic Component>

FIG. 35C is a perspective diagram of an electronic component 4700 and a substrate (a mounting board 4704) on which the electronic component 4700 is mounted. The electronic component 4700 illustrated in FIG. 35C includes the chip 4800a in a mold 4711. Note that the chip 4800a illustrated in FIG. 35C is shown to have a structure where the circuit portions 4802 are stacked. That is, the memory device described in the above embodiment can be used for the circuit portion 4802. To illustrate the inside of the electronic component 4700, some portions are omitted in FIG. 35C. The electronic component 4700 includes a land 4712 outside the mold 4711.

The land 4712 is electrically connected to an electrode pad 4713, and the electrode pad 4713 is electrically connected to the chip 4800a through a wire 4714. The electronic component 4700 is mounted on a printed circuit board 4702, for example. A plurality of such electronic components are combined and electrically connected to each other on the printed circuit board 4702, so that the mounting board 4704 is completed.

FIG. 35D is a perspective diagram of an electronic component 4730. The electronic component 4730 is an example of a SiP (System in Package) or an MCM (Multi Chip Module). In the electronic component 4730, an interposer 4731 is provided on a package substrate 4732 (a printed circuit board), and a semiconductor device 4735 and a plurality of semiconductor devices 4710 are provided on the interposer 4731.

The electronic component 4730 includes the semiconductor devices 4710. Examples of the semiconductor device 4710 include the memory device described in the above embodiment and a high bandwidth memory (HBM). In addition, an integrated circuit (a semiconductor device) such as a CPU, a GPU, an FPGA, or a memory device can be used as the semiconductor device 4735, for example.

As the package substrate 4732, a ceramic substrate, a plastic substrate, or a glass epoxy substrate can be used. As the interposer 4731, a silicon interposer, or a resin interposer can be used.

The interposer 4731 includes a plurality of wirings and has a function of electrically connecting a plurality of integrated circuits with different terminal pitches. The plurality of wirings are provided in a single layer or multiple layers. In addition, the interposer 4731 has a function of electrically connecting an integrated circuit provided on the interposer 4731 to an electrode provided on the package substrate 4732. Accordingly, the interposer is sometimes referred to as a “redistribution substrate” or an “intermediate substrate”. Furthermore, a through electrode is provided in the interposer 4731 and the through electrode is used to electrically connect an integrated circuit and the package substrate 4732 in some cases. Moreover, for a silicon interposer, a TSV (Through Silicon Via) can also be used as the through electrode.

A silicon interposer is preferably used as the interposer 4731. A silicon interposer can be fabricated at lower cost than an integrated circuit because it is not necessary to provide an active element. Meanwhile, since wirings of a silicon interposer can be formed through a semiconductor process, formation of minute wirings, which is difficult for a resin interposer, is easy.

In order to achieve a wide memory bandwidth, many wirings need to be connected to HBM. Therefore, formation of minute and high-density wirings is required for an interposer on which HBM is mounted. For this reason, a silicon interposer is preferably used as the interposer on which HBM is mounted.

In a SiP, an MCM, or the like using a silicon interposer, a decrease in reliability due to a difference in the coefficient of expansion between an integrated circuit and the interposer is less likely to occur. Furthermore, a silicon interposer has high surface flatness, so that a poor connection between the silicon interposer and an integrated circuit provided on the silicon interposer is less likely to occur. It is particularly preferable to use a silicon interposer for a 2.5D package (2.5-dimensional mounting) in which a plurality of integrated circuits are arranged side by side on an interposer.

In addition, a heat sink (a radiator plate) may be provided to overlap with the electronic component 4730. In the case of providing a heat sink, the heights of integrated circuits provided on the interposer 4731 are preferably equal to each other. For example, in the electronic component 4730 described in this embodiment, the heights of the semiconductor devices 4710 and the semiconductor device 4735 are preferably equal to each other.

To mount the electronic component 4730 on another substrate, an electrode 4733 may be provided on a bottom portion of the package substrate 4732. FIG. 35D illustrates an example where the electrode 4733 is formed of a solder ball. Solder balls are provided in a matrix on the bottom portion of the package substrate 4732, so that BGA (Ball Grid Array) mounting can be achieved. Alternatively, the electrode 4733 may be formed of a conductive pin. When conductive pins are provided in a matrix on the bottom portion of the package substrate 4732, PGA (Pin Grid Array) mounting can be achieved.

The electronic component 4730 can be mounted on another substrate by various mounting methods other than BGA and PGA. For example, a mounting method such as SPGA (Staggered Pin Grid Array), LGA (Land Grid Array), QFP (Quad Flat Package), QFJ (Quad Flat J-leaded package), or QFN (Quad Flat Non-leaded package) can be used.

Note that this embodiment can be combined with any of the other embodiments in this specification as appropriate.

### Embodiment 4

In this embodiment, a CPU that can include the memory device of the above embodiment will be described.

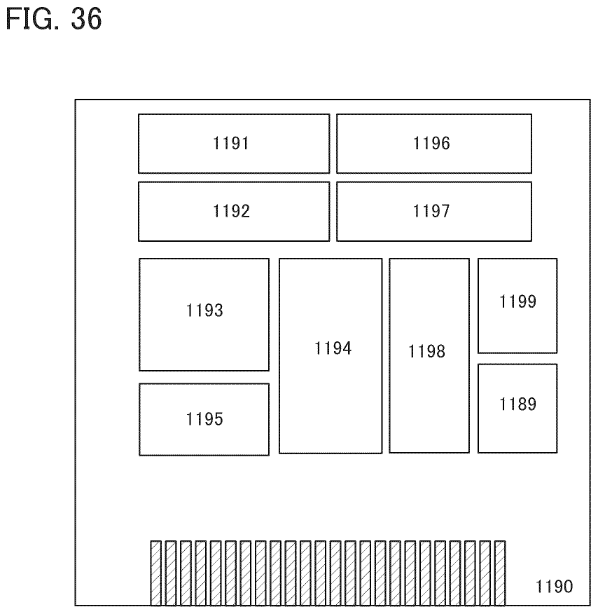

FIG. 36 is a block diagram illustrating a structure example of a CPU in part of which the memory device described in the above embodiment is used.

The CPU illustrated in FIG. 36 includes an ALU 1191 (ALU: Arithmetic logic unit), an ALU controller 1192, an instruction decoder 1193, an interrupt controller 1194, a timing controller 1195, a register 1196, a register controller 1197, a bus interface 1198 (Bus I/F), a rewritable ROM 1199, and a ROM interface 1189 (ROM I/F) over a substrate 1190. A semiconductor substrate, an SOI substrate, a glass substrate, or the like is used as the substrate 1190. The ROM 1199 and the ROM interface 1189 may be provided over separate chips. Needless to say, the CPU illustrated in FIG. 36 is just an example of a simplified structure, and an actual CPU may have a variety of structures depending on the usage. For example, the CPU may have a structure where a plurality of cores each including the CPU illustrated in FIG. 36 or an arithmetic circuit are included and the cores operate in parallel, i.e., a GPU-like structure. The number of bits that the CPU can process in an internal arithmetic circuit, a data bus, or the like can be 8, 16, 32, or 64 or more, for example.

An instruction that is input to the CPU through the bus interface 1198 is input to the instruction decoder 1193 and decoded therein, and then, input to the ALU controller 1192, the interrupt controller 1194, the register controller 1197, and the timing controller 1195.

The ALU controller 1192, the interrupt controller 1194, the register controller 1197, and the timing controller 1195 conduct various controls in accordance with the decoded instruction. Specifically, the ALU controller 1192 generates signals for controlling the operation of the ALU 1191. While the CPU is executing a program, the interrupt controller 1194 judges an interrupt request from an external input/output device, a peripheral circuit, or the like on the basis of its priority or a mask state, and processes the request. The register controller 1197 generates an address of the register 1196, and reads or writes data from/to the register 1196 in accordance with the state of the CPU.

The timing controller 1195 generates signals for controlling operation timings of the ALU 1191, the ALU controller 1192, the instruction decoder 1193, the interrupt controller 1194, and the register controller 1197. For example, the timing controller 1195 includes an internal clock generator for generating an internal clock signal on the basis of a reference clock signal, and supplies the internal clock signal to the above various circuits.

In the CPU illustrated in FIG. 36, a memory cell is provided in the register 1196. The register 1196 may include the memory device described in the above embodiment, for example.

In the CPU illustrated in FIG. 36, the register controller 1197 selects a retention operation in the register 1196 in accordance with an instruction from the ALU 1191. That is, the register controller 1197 selects whether data retention by a flip-flop is performed or data retention by a capacitor is performed in the memory cell included in the register 1196. When data retention by the flip-flop is selected, power supply voltage is supplied to the memory cell in the register 1196. When data retention by the capacitor is selected, the data is rewritten into the capacitor, and supply of power supply voltage to the memory cell in the register 1196 can be stopped.

Note that this embodiment can be combined with any of the other embodiments in this specification as appropriate.

### Embodiment 5

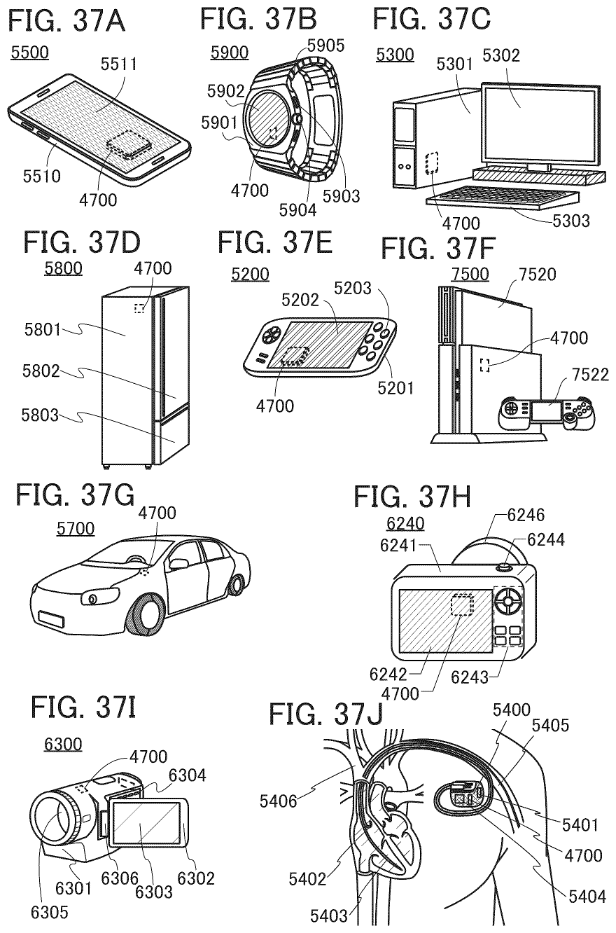

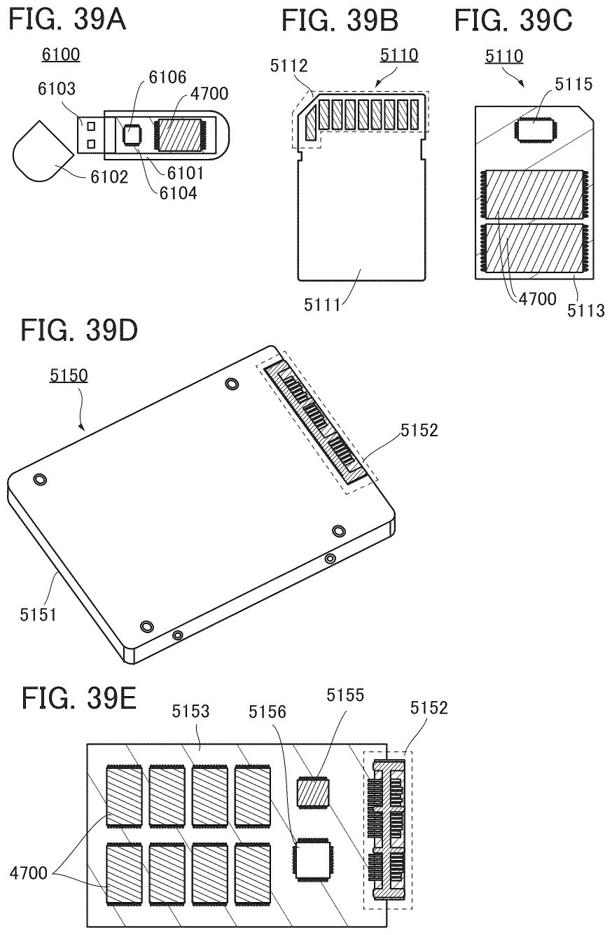

In this embodiment, examples of electronic devices each including the memory device described in the above embodiment will be described. FIG. 37A to FIG. 37J and FIG. 39A to FIG. 39E illustrate electronic devices each of which includes the electronic component 4700 including the memory device.

### [Mobile Phone]

An information terminal 5500 illustrated in FIG. 37A is a mobile phone (smartphone), which is a type of information terminal. The information terminal 5500 includes a housing 5510 and a display portion 5511, and as input interfaces, a touch panel is provided in the display portion 5511 and a button is provided in the housing 5510.

By using the memory device described in the above embodiment, the information terminal 5500 can retain a temporary file generated at the time of executing an application (e.g., a web browser's cache).

### [Wearable Terminal]

FIG. 37B illustrates an information terminal 5900 that is an example of a wearable terminal. The information terminal 5900 includes a housing 5901, a display portion 5902, an operation button 5903, an crown 5904, and a band 5905, for example.

Like the information terminal 5500 described above, the wearable terminal can retain a temporary file generated at the time of executing an application by using the memory device described in the above embodiment.

### [Information Terminal]

FIG. 37C illustrates a desktop information terminal 5300. The desktop information terminal 5300 includes a main body 5301 of the information terminal, a display 5302, and a keyboard 5303.

Like the information terminal 5500 described above, the desktop information terminal 5300 can retain a temporary file generated at the time of executing an application by using the memory device described in the above embodiment.

Note that although the smartphone, the wearable terminal, and the desktop information terminal are respectively illustrated in FIG. 37A to FIG. 37C as examples of the electronic device, one embodiment of the present invention can be applied to an information terminal other than a smartphone, a wearable information terminal, and a desktop information terminal. Examples of information terminals other than a smartphone, a wearable terminal, and a desktop information terminal include a PDA (Personal Digital Assistant), a laptop information terminal, and a workstation.

### [Household Appliance]

FIG. 37D illustrates an electric refrigerator-freezer 5800 as an example of a household appliance. The electric refrigerator-freezer 5800 includes a housing 5801, a refrigerator door 5802, and a freezer door 5803, for example.

When the memory device described in the above embodiment is used in the electric refrigerator-freezer 5800, the electric refrigerator-freezer 5800 can be used for IoT (Internet of Things), for example. When used for IoT, the electric refrigerator-freezer 5800 can send and receive information on food stored in the electric refrigerator-freezer 5800 and food expiration dates, for example, to/from the above-described information terminal and the like via the Internet. When sending the information, the electric refrigerator-freezer 5800 can retain the information as a temporary file in the memory device.

Although the electric refrigerator-freezer is described in this example as a household appliance, examples of other household appliances include a vacuum cleaner, a microwave oven, an electric oven, a rice cooker, a water heater, an IH cooker, a water server, a heating-cooling combination appliance such as an air conditioner, a washing machine, a drying machine, and an audiovisual appliance.

### [Game Machine]

FIG. 37E illustrates a portable game machine 5200 that is an example of a game machine. The portable game machine 5200 includes a housing 5201, a display portion 5202, and a button 5203, for example.

FIG. 37F illustrates a stationary game machine 7500 that is another example of a game machine. The stationary game machine 7500 includes a main body 7520 and a controller 7522. Note that the controller 7522 can be connected to the main body 7520 with or without a wire. Furthermore, although not illustrated in FIG. 37F, the controller 7522 can include one or two or more selected from a display portion that displays a game image, and an input interface besides a button, such as a touch panel, a stick, a rotating knob, and a sliding knob, for example. The shape of the controller 7522 is not limited to that illustrated in FIG. 37F, and can be changed variously in accordance with the genres of games. For example, for a shooting game such as an FPS (First Person Shooter) game, a gun-shaped controller having a trigger button can be used. As another example, for a music game or the like, a controller having a shape of a musical instrument, audio equipment, or the like can be used. Furthermore, the stationary game machine may include a camera, a depth sensor, a microphone, and the like so that the game player can play a game using one or both of a gesture and a voice instead of a controller.

In addition, videos displayed on the game machine can be output with a display device provided in a television device, a personal computer display, a game display, or a head-mounted display.

When the memory device described in the above embodiment is used in the portable game machine 5200 and the stationary game machine 7500, the portable game machine 5200 with low power consumption can be achieved. Moreover, heat generation from a circuit can be reduced owing to low power consumption; thus, the influence of heat generation on the circuit itself, a peripheral circuit, and a module can be reduced.

Moreover, with the use of the memory device described in the above embodiment, the portable game machine 5200 and the stationary game machine 7500 can retain a temporary file necessary for arithmetic operation that occurs during game play.

Although FIG. 37E and FIG. 37F illustrate a portable game machine and a stationary game machine, respectively, as examples of game machines, the electronic device of one embodiment of the present invention is not limited thereto. Examples of the electronic device of one embodiment of the present invention include an arcade game machine installed in entertainment facilities (e.g., a game center and an amusement park), and a throwing machine for batting practice installed in sports facilities.

### [Moving Vehicle]

The memory device described in the above embodiment can be used for an automobile, which is a moving vehicle, and around the driver's seat in an automobile.

FIG. 37G illustrates an automobile 5700 that is an example of a moving vehicle.

An instrument panel that displays various kinds of information such as a speedometer, a tachometer, a mileage, a fuel meter, a gearshift state, and air-conditioning settings is provided around the driver's seat in the automobile 5700. In addition, a display device showing the above information may be provided around the driver's seat.

In particular, the display device can compensate for the view obstructed by the pillar or the like, the blind areas for the driver's seat, and the like by displaying a video taken by an imaging device (not illustrated) provided for the automobile 5700, thereby providing a high level of safety.

The memory device described in the above embodiment can temporarily retain data; thus, the memory device can be used to retain temporary data necessary in an automatic driving system for the automobile 5700 and a system for navigation and risk prediction, for example. The display device may be configured to display temporary information regarding navigation, risk prediction, or the like. Moreover, the memory device may be configured to retain a video of a driving recorder provided in the automobile 5700.

Although an automobile is described above as an example of a moving vehicle, the moving vehicle is not limited to an automobile. Examples of moving vehicles include a train, a monorail train, a ship, and a flying object (e.g., a helicopter, an unmanned aircraft (a drone), an airplane, and a rocket).

### [Camera]

The memory device described in the above embodiment can be used for a camera.

FIG. 37H illustrates a digital camera 6240 that is an example of an imaging device. The digital camera 6240 includes a housing 6241, a display portion 6242, operation buttons 6243, and a shutter button 6244, and a detachable lens 6246 is attached to the digital camera 6240. Although the digital camera 6240 is configured here such that the lens 6246 is detachable from the housing 6241 for replacement, the lens 6246 may be integrated with the housing 6241. In addition, the digital camera 6240 can be additionally equipped with a stroboscope or a viewfinder.

When the memory device described in the above embodiment is used for the digital camera 6240, the digital camera 6240 with low power consumption can be achieved. Moreover, heat generation from a circuit can be reduced owing to low power consumption; thus, the influence of heat generation on the circuit itself, a peripheral circuit, and a module can be reduced.

### [Video Camera]

The memory device described in the above embodiment can be used for a video camera.

FIG. 37I illustrates a video camera 6300 that is an example of an imaging device. The video camera 6300 includes a first housing 6301, a second housing 6302, a display portion 6303, operation keys 6304, a lens 6305, and a joint 6306. The operation keys 6304 and the lens 6305 are provided in the first housing 6301, and the display portion 6303 is provided in the second housing 6302. The first housing 6301 and the second housing 6302 are connected to each other with the joint 6306, and an angle between the first housing 6301 and the second housing 6302 can be changed with the joint 6306. Images displayed on the display portion 6303 may be changed in accordance with the angle at the joint 6306 between the first housing 6301 and the second housing 6302.

When images taken by the video camera 6300 are recorded, the images need to be encoded in accordance with a data recording format. By using the above memory device, the video camera 6300 can retain a temporary file generated in encoding.

### [ICD]

The memory device described in the above embodiment can be used for an implantable cardioverter-defibrillator (ICD).

FIG. 37J is a schematic cross-sectional view illustrating an example of an ICD. An ICD main unit 5400 includes at least a battery 5401, the electronic component 4700, a regulator, a control circuit, an antenna 5404, a wire 5402 reaching a right atrium, and a wire 5403 reaching a right ventricle.

The ICD main unit 5400 is implanted in the body by surgery, and the two wires pass through a subclavian vein 5405 and a superior vena cava 5406 of the human body, with an end of one of the wires placed in the right ventricle and an end of the other wire placed in the right atrium.

The ICD main unit 5400 functions as a pacemaker and paces the heart when the heart rate is not within a predetermined range. In addition, when the heart rate is not recovered by pacing (e.g., when ventricular tachycardia or ventricular fibrillation occurs), treatment with an electrical shock is performed.

The ICD main unit 5400 needs to monitor the heart rate all the time in order to perform pacing and deliver electrical shocks as appropriate. For that reason, the ICD main unit 5400 includes a sensor for measuring the heart rate. In the ICD main unit 5400, data on the heart rate obtained by the sensor or the like, the number of times the treatment with pacing is performed, and the time taken for the treatment, for example, can be stored in the electronic component 4700.

The antenna 5404 can receive power, and the battery 5401 is charged with the power. Furthermore, when the ICD main unit 5400 includes a plurality of batteries, safety can be increased. Specifically, even when some of the batteries in the ICD main unit 5400 are dead, the other batteries can function properly; thus, the batteries also function as an auxiliary power source.

In addition to the antenna 5404 capable of receiving power, an antenna that can transmit physiological signals may be included to construct, for example, a system that monitors cardiac activity by checking physiological signals such as a pulse, a respiratory rate, a heart rate, and body temperature with an external monitoring device.

### [Head-Mounted Display]

The memory device described in the above embodiment can be used for an electronic device for XR (Extended Reality or Cross Reality), such as AR (augmented reality) or VR (virtual reality).

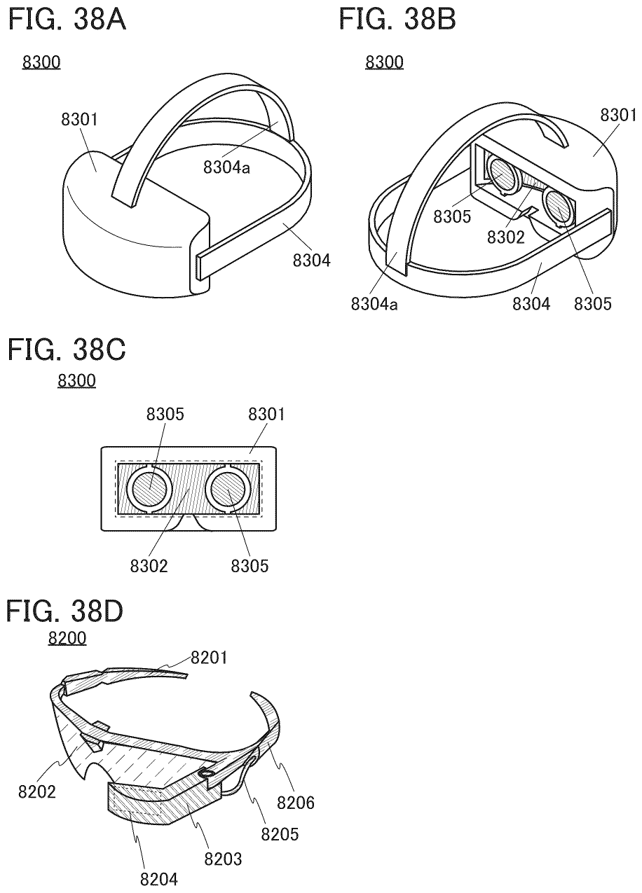

FIG. 38A to FIG. 38C are diagrams illustrating the appearance of an electronic device 8300 that is ahead-mounted display. The electronic device 8300 illustrated in FIG. 38A to FIG. 38C includes a housing 8301, a display portion 8302, a band-like fixing member 8304, a fixing member 8304a worn on a head, and a pair of lenses 8305. Note that the electronic device 8300 may include an operation button.

A user can see display on the display portion 8302 through the lenses 8305. Note that the display portion 8302 is preferably curved and placed because the user can feel a high realistic sensation. Another image displayed in another region of the display portion 8302 is seen through the lenses 8305, so that three-dimensional display using parallax or the like can be performed. Note that the structure is not limited to the structure where one display portion 8302 is provided; two display portions 8302 may be provided and one display portion may be provided per eye of the user.

For the display portion 8302, a display device with an extremely high resolution is preferably used, for example. When a high-resolution display device is used for the display portion 8302, it is possible to display a more realistic video that does not allow the user to perceive pixels even when the displayed image is magnified using the lenses 8305 as illustrated in FIG. 38C.

The head-mounted display, which is an electronic device of one embodiment of the present invention, may be an electronic device 8200 illustrated in FIG. 38D, which is a glasses-type head-mounted display.

The electronic device 8200 includes a wearing portion 8201, a lens 8202, a main body 8203, a display portion 8204, and a cable 8205. A battery 8206 is incorporated in the wearing portion 8201.

The cable 8205 supplies electric power from the battery 8206 to the main body 8203. The main body 8203 includes a wireless receiver or the like to receive video data and display it on the display portion 8204. The main body 8203 includes a camera, and data on the movement of eyeballs or eyelids of the user can be used as an input means.

The wearing portion 8201 may be provided with a plurality of electrodes capable of detecting current flowing in response to the movement of the user's eyeball in a position in contact with the user to have a function of recognizing the user's sight line. Furthermore, the wearing portion 8201 may have a function of monitoring the user's pulse with use of current flowing through the electrodes. The wearing portion 8201 may include a variety of sensors such as a temperature sensor, a pressure sensor, and an acceleration sensor to have a function of displaying the user's biological information on the display portion 8204, a function of changing a video displayed on the display portion 8204 in accordance with the movement of the user's head, and the like.

### [Expansion Device for PC]

The memory device described in the above embodiment can be used for a calculator such as a PC (Personal Computer) and an expansion device for an information terminal.

FIG. 39A illustrates, as an example of the expansion device, a portable expansion device 6100 that includes a chip capable of retaining information and is externally provided on a PC. The expansion device 6100 can store information using the chip when connected to a PC with a USB (Universal Serial Bus) or the like, for example. Note that FIG. 39A illustrates the portable expansion device 6100; however, the expansion device of one embodiment of the present invention is not limited thereto and may be a comparatively large expansion device including a cooling fan or the like, for example.

The expansion device 6100 includes a housing 6101, a cap 6102, a USB connector 6103, and a substrate 6104. The substrate 6104 is held in the housing 6101. The substrate 6104 is provided with a circuit for driving the memory device or the like described in the above embodiment. For example, the substrate 6104 is provided with the electronic component 4700 and a controller chip 6106. The USB connector 6103 functions as an interface for connection to an external device.

### [SD Card]

The memory device described in the above embodiment can be used for an SD card that can be attached to an electronic device such as an information terminal or a digital camera.

FIG. 39B is a schematic external diagram of an SD card, and FIG. 39C is a schematic diagram of the internal structure of the SD card. An SD card 5110 includes a housing 5111, a connector 5112, and a substrate 5113. The connector 5112 functions as an interface for connection to an external device. The substrate 5113 is held in the housing 5111. The substrate 5113 is provided with a memory device and a circuit for driving the memory device. For example, electronic components 4700 and a controller chip 5115 are attached to the substrate 5113. Note that the circuit structures of the electronic components 4700 and the controller chip 5115 are not limited to those described above, and can be changed as appropriate according to circumstances. For example, a write circuit, a row driver, a read circuit, and the like that are provided in an electronic component may be incorporated into the controller chip 5115 instead of the electronic component 4700.

When the electronic components 4700 are provided also on a rear surface side (a side opposite to a side where the memory device and the circuit for driving the memory device is provided) of the substrate 5113, the capacitance of the SD card 5110 can be increased. In addition, a wireless chip with a wireless communication function may be provided on the substrate 5113. This allows wireless communication between an external device and the SD card 5110 and enables data reading and writing from and to the electronic components 4700.

### [SSD]

The memory device described in the above embodiment can be used for an SSD (Solid State Drive) that can be attached to an electronic device such as an information terminal.

FIG. 39D is a schematic external view of an SSD, and FIG. 39E is a schematic view of the internal structure of the SSD. An SSD 5150 includes a housing 5151, a connector 5152, and a substrate 5153. The connector 5152 functions as an interface for connection to an external device. The substrate 5153 is held in the housing 5151. The substrate 5153 is provided with a memory device and a circuit for driving the memory device. For example, the electronic components 4700, a memory chip 5155, and a controller chip 5156 are attached to the substrate 5153. When the electronic components 4700 are also provided on a rear surface side (a side opposite to a side where the memory device and the circuit for driving the memory device are provided) of the substrate 5153, the capacity of the SSD 5150 can be increased. A work memory is incorporated in the memory chip 5155. For example, a DRAM chip is used as the memory chip 5155. A processor, an ECC circuit, and the like are incorporated in the controller chip 5156. Note that the circuit structures of the electronic components 4700, the memory chip 5155, and the controller chip 5156 are not limited to those described above, and the circuit structures can be changed as appropriate according to circumstances. For example, a memory functioning as a work memory may also be provided in the controller chip 5156.

The memory device described in the above embodiment is used as each of the memory devices included in the above electronic devices, whereby novel electronic devices can be provided.

Note that this embodiment can be combined with any of the other embodiments in this specification as appropriate.

### REFERENCE NUMERALS

DEV: semiconductor device, ALYa: memory layer, ALYb: memory layer, MC: memory cell, MCa: memory cell, MCb: memory cell, M1: transistor, C1: capacitor, BLa: wiring, BLb: wiring, WLa: wiring, WLb: wiring, CLa: wiring, CLb: wiring, 10: memory cell, 22: PSW, 23: PSW, 31: peripheral circuit, 32: control circuit, 33: voltage generation circuit, 41: peripheral circuit, 42: row decoder, 43: row driver, 44: column decoder, 45: column driver, 46: sense amplifier, 47: input circuit, 48: output circuit, 50: driver circuit layer, 60: memory layer, 100: memory device, 153_1: insulator, 153_2: insulator, 153A: insulating film, 154_1: insulator, 154_2: insulator, 154A: insulating film, 158: opening, 160_1: conductor, 160a_1: conductor, 160b_1: conductor, 160_2: conductor, 160a_2: conductor, 160b_2: conductor, 160A: conductive film, 160B: conductive film, 222_1: insulator, 222_2: insulator, 224: insulator, 224Af: insulating film, 224A: insulating layer, 230: oxide, 230a: oxide, 230Af: oxide film, 230A: oxide layer, 230b: oxide, 230Bf: oxide film, 230B: oxide layer, 242a: conductor, 242al: conductor, 242a2: conductor, 242Af: conductive film, 242A: conductive layer, 242b: conductor, 242b1: conductor, 242b2: conductor, 242Bf: conductive film, 242B: conductive layer, 242c: conductor, 253: insulator, 253A: insulating film, 254: insulator, 254A: insulating film, 258: opening, 260: conductor, 260a: conductor, 260b: conductor, 260A: 5 conductive film, 260B: conductive film, 270: conductor, 275: insulator, 280_1: insulator, 280_2: insulator, 311: substrate, 315: insulator, 316: conductor, 320: insulator, 322: insulator, 324: insulator, 326: insulator, 328: conductor, 330: conductor, 350: insulator, 352: insulator, 356: conductor, 357: insulator, 400: transistor, 1189: ROM interface, 1190: substrate, 1192: ALU controller, 1193: instruction decoder, 1194: interrupt controller, 1195: timing controller, 1196: register, 1197: register controller, 1198: bus interface, 1199: ROM, 4700: electronic component, 4702: printed circuit board, 4710: semiconductor device, 4711: mold, 4712: land, 4714: wire, 4730: electronic component, 4735: semiconductor device, 4800: semiconductor wafer, 4801: wafer, 4801a: wafer, 4802: circuit portion, 4803: spacing, 4803a: spacing, 5110: SD card, 5111: housing, 5112: connector, 5113: substrate, 5115: controller chip, 5151: housing, 5152: connector, 5153: substrate, 5156: controller chip, 5200: portable game machine, 5201: housing, 5202: display portion, 5203: button, 5300: desktop information terminal, 5301: main body, 5302: display, 5303: keyboard, 5400: ICD main unit, 5401: battery, 5402: wire, 5403: wire, 5404: antenna, 5500: information terminal, 5510: housing, 5511: display portion, 5700: automobile, 5800: electric refrigerator-freezer, 5801: housing, 5802: refrigerator door, 5803: freezer door, 5900: information terminal, 5901: housing, 5902: display portion, 5903: operation button, 5904: crown, 5905: band, 6100: expansion device, 6101: housing, 6102: cap, 6103: USB connector, 6104: substrate, 6106: controller chip, 6240: digital camera, 6241: housing, 6243: operation button, 6246: lens, 6242: display portion, 6301: first housing, 6302: second housing, 6303: display portion, 6304: operation key, 6305: lens, 6306: joint, 7500: stationary game machine, 7520: main body, 7522: controller, 8200: electronic device, 8201: wearing portion, 8202: lens, 8203: main body, 8204: display portion, 8205: cable, 8206: battery, 8300: electronic device, 8301: housing, 8302: display portion, 8304: fixing member, 8304a: fixing member, 8305: lens

1. A semiconductor device comprising:
a first memory layer and a second memory layer,
wherein the second memory layer is located over the first memory layer,
wherein each of the first memory layer and the second memory layer comprises a first insulator, a second insulator, a third insulator, a fourth insulator, a fifth insulator, a sixth insulator, an oxide, a first conductor, a second conductor, a third conductor, and a fourth conductor,
wherein the oxide comprises one or two or more selected from indium, zinc, and an element M,
wherein the element Mis one or more kinds selected from gallium, aluminum, silicon, boron, yttrium, tin, copper, vanadium, beryllium, titanium, iron, nickel, germanium, zirconium, molybdenum, lanthanum, cerium, neodymium, hafnium, tantalum, tungsten, cobalt, and magnesium,
wherein in each of the first memory layer and the second memory layer:
the second insulator is located over the first insulator;
the oxide is located over the second insulator;
the first conductor is located over the first insulator, the second insulator, and the oxide;
the second conductor is located over the first insulator, the second insulator, and the oxide;
the third insulator is located over the first conductor, the second conductor, and the first insulator;
the fourth insulator is located over the third insulator;
the fourth insulator comprises a first opening reaching the oxide, in a region not overlapping with the first conductor, the second conductor, or the third insulator;
the fifth insulator is located over the oxide and a side surface of the fourth insulator in the first opening;
the third conductor is located over the fifth insulator;
the fourth insulator comprises a second opening reaching the second conductor, in a region not overlapping with the second insulator or the oxide;
the sixth insulator is located over the second conductor and the side surface of the fourth insulator in the second opening; and
the fourth conductor is located over the sixth insulator, and
wherein the fourth conductor of the first memory layer overlaps with the second insulator of the second memory layer and the oxide of the second memory layer.

2. The semiconductor device according to claim 1,
wherein the fifth insulator and the sixth insulator comprise the same insulating material, and
wherein the third conductor and the fourth conductor comprise the same conductive material.

3. A semiconductor device comprising:
a first memory layer and a second memory layer,
wherein the second memory layer is located over the first memory layer,
wherein each of the first memory layer and the second memory layer comprises a first insulator, a second insulator, a third insulator, a fourth insulator, a fifth insulator, a sixth insulator, an oxide, a first conductor, a second conductor, a third conductor, and a fourth conductor,
wherein the oxide comprises one or two or more selected from indium, zinc, and an element M,
wherein the element Mis one or more kinds selected from gallium, aluminum, silicon, boron, yttrium, tin, copper, vanadium, beryllium, titanium, iron, nickel, germanium, zirconium, molybdenum, lanthanum, cerium, neodymium, hafnium, tantalum, tungsten, cobalt, and magnesium,
wherein in each of the first memory layer and the second memory layer:
the second insulator is located over the first insulator;
the oxide is located over the second insulator;
the first conductor is located over the oxide;
the second conductor is located over the oxide,
the third insulator is located over the first conductor, the second conductor, and the first insulator;
the fourth insulator is located over the third insulator;
the fourth insulator comprises a first opening reaching the oxide, in a region not overlapping with the first conductor, the second conductor, or the third insulator;
the fifth insulator is located over the oxide and a side surface of the fourth insulator in the first opening;
the third conductor is located over the fifth insulator;
the fourth insulator comprises a second opening reaching the second conductor, in a region overlapping with the second insulator and the oxide;
the sixth insulator is located over the second conductor and the side surface of the fourth insulator in the second opening; and
the fourth conductor is located over the sixth insulator, and
wherein the fourth conductor of the first memory layer overlaps with the second insulator of the second memory layer and the oxide of the second memory layer.

4. The semiconductor device according to claim 3,
wherein the fifth insulator and the sixth insulator comprise the same insulating material, and
wherein the third conductor and the fourth conductor comprise the same conductive material.

5. A memory device comprising the semiconductor device according to claim 1 and a driver circuit,
wherein the first memory layer and the second memory layer are located above the driver circuit.

6. An electronic device comprising the memory device according claim 5 and a housing.
